(19) United States
(12) Patent Application Publication
(10) Pub. No.: US 2025/0338717 A1
(43) Pub. Date: Oct. 30, 2025

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Masami JINTYOU, Shimotsuga (JP); Masataka NAKADA, Tochigi (JP); Yukinori SHIMA, Tatebayashi (JP); Masayoshi DOBASHI, Shimotsuga (JP); Junichi KOEZUKA, Tochigi (JP); Daisuke KUROSAKI, Utsunomiya (JP)

(21) Appl. No.: 18/998,211

(22) PCT Filed: Jul. 27, 2023
(86) PCT No.: PCT/IB2023/057609

§ 371 Date: Jan. 24, 2025

(30) Foreign Application Priority Data
Aug. 9, 2022 (JP) 2022-127241

(51) Int. Cl. H10K 59/121; H10K 59/12

(52) U.S. Cl. CPC H10K 59/1213; H10K 59/1201

(57) ABSTRACT

A semiconductor device including a transistor having a minute size is provided. The semiconductor device includes a first transistor and a second transistor. The first transistor includes first to third conductive layers, an insulating layer, and first and second semiconductor layers. The second conductive layer over the first conductive layer includes an opening overlapping with the first conductive layer. The first semiconductor layer is in contact with a top surface of the first conductive layer and a top surface and a side surface of the second conductive layer. The second semiconductor layer is in contact with a top surface of the first semiconductor layer. The insulating layer is in contact with a top surface of the second semiconductor layer. The third conductive layer overlaps with the first and second semiconductor layers in the opening. The second transistor includes the insulating layer, a third semiconductor layer, and fourth to sixth conductive layers. The fourth and fifth conductive layers are in contact with different top surfaces of the third semiconductor layer. Between the fourth semiconductor layer and the fifth semiconductor layer, the insulating layer is in contact with a top surface of the third semiconductor layer. The sixth conductive layer is in contact with a top surface of the insulating layer. The first and second semiconductor layers contain different materials. The second and third semiconductor layer contain the same material.

### TECHNICAL FIELD

One embodiment of the present invention relates to a semiconductor device, a display apparatus, a display module, and an electronic device. One embodiment of the present invention relates to a method for manufacturing a semiconductor device and a method for manufacturing a display apparatus.

Note that one embodiment of the present invention is not limited to the above technical field. Examples of the technical field of one embodiment of the present invention include a semiconductor device, a display apparatus, a light-emitting apparatus, a power storage device, a memory device, a lighting device, an input device (e.g., a touch sensor), and an input/output device (e.g., a touch panel), an electronic device including any of them, a driving method of any of them, and a manufacturing method of any of them.

### BACKGROUND ART

Semiconductor devices including transistors have been widely used in display apparatuses and electronic devices, and the semiconductor devices have been required increasingly to achieve high integration and high-speed operation. In the case where semiconductor devices are used for high-definition display apparatuses, highly integrated semiconductor devices are required, for example. The development of transistors having minute sizes is ongoing as one way of increasing the degree of integration of transistors.

In recent years, there has been a need for display apparatuses applicable to virtual reality (VR), augmented reality (AR), substitutional reality (SR), or mixed reality (MR). VR, AR, SR, and MR are collectively referred to as extended reality (XR). Display apparatuses for XR have been desired to have higher definition and higher color reproducibility so that realistic feeling and the sense of immersion can be enhanced. Examples of devices applicable to such display apparatuses include a liquid crystal display apparatus and a light-emitting apparatus including a light-emitting device (also referred to as a light-emitting element) such as an organic EL (Electro Luminescence) device or a light-emitting diode (LED).

Patent Document 1 discloses a display apparatus using an organic EL device (also referred to as organic EL element) for VR.

### REFERENCE

### Patent Document

[Patent Document 1] PCT International Publication No. 2018/087625 Solved by the Invention

### SUMMARY OF THE INVENTION

### Problems to be Solved by the Invention

An object of one embodiment of the present invention is to provide a semiconductor device including a transistor having a minute size and a manufacturing method thereof. Another object of one embodiment of the present invention is to provide a small semiconductor device and a manufacturing method thereof. Another object of one embodiment of the present invention is to provide a semiconductor device including a transistor with a high on-state current and a manufacturing method thereof. Another object of one embodiment of the present invention is to provide a high-performance semiconductor device and a manufacturing method thereof. Another object of one embodiment of the present invention is to provide a semiconductor device with high reliability and a manufacturing method thereof. Another object of one embodiment of the present invention is to provide a method for manufacturing a semiconductor device with high productivity. Another object of one embodiment of the present invention is to provide a novel semiconductor device and a manufacturing method thereof.

Note that the description of these objects does not preclude the presence of other objects. One embodiment of the present invention does not need to achieve all of these objects. Other objects can be derived from the description of the specification, the drawings, and the claims.

### Means for Solving the Problems

One embodiment of the present invention is a semiconductor device including a first transistor and a second transistor. The first transistor includes a first conductive layer, a second conductive layer, a third conductive layer, a first insulating layer, a first semiconductor layer, and a second semiconductor layer. The second conductive layer is provided over the first conductive layer and includes an opening in a region overlapping with the first conductive layer. The first semiconductor layer is provided in contact with a top surface of the first conductive layer and a top surface and a side surface of the second conductive layer to cover the opening. The second semiconductor layer is provided in contact with a top surface of the first semiconductor layer. A first region of the first insulating layer is provided in contact with a top surface of the second semiconductor layer. The third conductive layer is provided in the opening to overlap with the first semiconductor layer and the second semiconductor layer with the first region therebetween. The second transistor includes the first insulating layer, a third semiconductor layer, a fourth conductive layer, a fifth conductive layer, and a sixth conductive layer. The fourth conductive layer and the fifth conductive layer are provided in contact with different top surfaces of the third semiconductor layer. A second region of the first insulating layer is provided in contact with a top surface of the third semiconductor layer between the fourth conductive layer and the fifth conductive layer. The sixth conductive layer is provided in contact with a top surface of the second region. The first semiconductor layer and the second semiconductor layer contain different materials. The second semiconductor layer and the third semiconductor layer contain the same material.

Another embodiment of the present invention is a semiconductor device including a first transistor and a second transistor. The first transistor includes a first conductive layer, a second conductive layer, a third conductive layer, a first insulating layer, a first semiconductor layer, and a second semiconductor layer. The second transistor includes a fourth conductive layer, a fifth conductive layer, a sixth conductive layer, the first insulating layer, and a third semiconductor layer. The second conductive layer is provided over the first conductive layer and includes a first opening in a region overlapping with the first conductive layer. The first semiconductor layer is provided in contact with a top surface of the first conductive layer and a top surface and a side surface of the second conductive layer to cover the first opening. The second semiconductor layer is provided in contact with a top surface of the first semiconductor layer. A first region of the first insulating layer is provided in contact with a top surface of the second semiconductor layer. The third conductive layer is provided in the first opening to overlap with the first semiconductor layer and the second semiconductor layer with the first region therebetween. The fifth conductive layer is provided over the fourth conductive layer and includes a second opening in a region overlapping with the fourth conductive layer. The third semiconductor layer is provided in contact with a top surface of the fourth conductive layer and a top surface and a side surface of the fifth conductive layer to cover the second opening. A second region of the first insulating layer is provided in contact with a top surface of the third semiconductor layer. The sixth conductive layer is provided in the second opening to overlap with the third semiconductor layer with the second region therebetween. The first semiconductor layer and the second semiconductor layer contain different materials. The second semiconductor layer and the third semiconductor layer contain a same material.

In the above, the first semiconductor layer, the second semiconductor layer, and the third semiconductor layer each preferably contain a metal oxide.

In the above, a second insulating layer is preferably provided over the first conductive layer. The second insulating layer preferably includes a first layer, a second layer over the first layer, and a third layer over the second layer. The first layer preferably includes a region having a higher film density than the second layer. The third layer preferably includes a region having a higher film density than the second layer.

In the above, a second insulating layer is preferably provided over the first conductive layer. The second insulating layer preferably includes a first layer, a second layer over the first layer, and a third layer over the second layer. The first layer preferably includes a region having a higher nitrogen content than the second layer. The third layer preferably includes a region having a higher nitrogen content than the second layer.

In the above, the second transistor preferably includes a third insulating layer. The third semiconductor layer is preferably provided over the third insulating layer.

In the above, the second transistor preferably includes a seventh conductive layer and a second insulating layer over the seventh conductive layer. The seventh conductive layer is preferably provided to overlap with the sixth conductive layer with the second insulating layer and the third semiconductor layer therebetween.

In the above, the third semiconductor layer preferably includes a pair of regions including a region interposed between the second region of the first insulating layer and the fourth conductive layer and a region interposed between the second region of the first insulating layer and the fifth conductive layer in a plan view. The pair of regions preferably have lower resistance than a region of the third semiconductor layer overlapping with the sixth conductive layer.

In the above, a second insulating layer is preferably provided over the first conductive layer and the fourth conductive layer. The second insulating layer preferably includes a first layer, a second layer over the first layer, and a third layer over the second layer. The first layer preferably includes a region having a higher film density than the second layer. The third layer preferably includes a region having a higher film density than the second layer.

In the above, a second insulating layer is preferably provided over the first conductive layer and the fourth conductive layer. The second insulating layer preferably includes a first layer, a second layer over the first layer, and a third layer over the second layer. The first layer preferably includes a region having a higher nitrogen content than the second layer. The third layer preferably includes a region having a higher nitrogen content than the second layer.

Another embodiment of the present invention is a method for manufacturing a semiconductor device including the following steps: forming a first conductive film; processing the first conductive film to form a first conductive layer and a second conductive layer; forming a first insulating film over the first conductive layer and the second conductive layer; forming a second insulating film over the first insulating film; processing the second insulating film to form a first insulating layer overlapping with the second conductive layer; forming a second conductive film over the first insulating layer and the first insulating film; processing the first insulating film and the second conductive film to form a second insulating layer and a third conductive layer each including an opening in a region overlapping with the first conductive layer; forming a first metal oxide film over the first conductive layer, the second insulating layer, the third conductive layer, and the first insulating layer to cover the opening; processing the first metal oxide film to form a first semiconductor layer in contact with a top surface of the first conductive layer, a side surface of the second insulating layer, and a top surface and a side surface of the third conductive layer; forming a second metal oxide film over the first semiconductor layer, the third conductive layer, the first insulating layer, and the second insulating layer; processing the second metal oxide film to form a second semiconductor layer overlapping with the first semiconductor layer and a third semiconductor layer overlapping with the second conductive layer and the first insulating layer; forming a third insulating film over the first semiconductor layer, the second semiconductor layer, the third conductive layer, the third semiconductor layer, the first insulating layer, and the second insulating layer; processing the third insulating film to form a third insulating layer including a region overlapping with the first conductive layer, the first semiconductor layer, the second semiconductor layer, and the third conductive layer, and a fourth insulating layer including a region overlapping with the second conductive layer and the third semiconductor layer; forming a third conductive film over the third insulating layer and the fourth insulating layer; processing the third conductive film to form a fourth conductive layer overlapping with the first semiconductor layer and the second semiconductor layer, a fifth conductive layer overlapping with the second conductive layer and the third semiconductor layer, and a sixth conductive layer and a seventh conductive layer that are in contact with a top surface of the third semiconductor layer and between which the fifth conductive layer is interposed in a plan view; and performing a treatment for supplying an impurity to the third semiconductor layer with the use of the fifth conductive layer as a mask.

In the above, the impurities are preferably one or more selected from boron, phosphorus, aluminum, magnesium, and silicon.

Another embodiment of the present invention is a method for manufacturing a semiconductor device including the following steps: processing a first conductive film to form a first conductive layer and a second conductive layer; forming a first insulating film over the first conductive layer and the second conductive layer; forming a second conductive film over the first insulating film; processing the first insulating film and the second conductive film to form a first insulating layer and a third conductive layer including a first opening in a region overlapping with the first conductive layer, and the first insulating layer and a fourth conductive layer including a second opening in a region overlapping with the second conductive layer; forming a first metal oxide film over the first conductive layer, the second conductive layer, the third conductive layer, the fourth conductive layer, and the first insulating layer to cover the first opening and the second opening; processing the first metal oxide film to form a first semiconductor layer in contact with a top surface of the first conductive layer, a side surface of the first insulating layer, and a top surface and a side surface of the third conductive layer; forming a second metal oxide film over the first semiconductor layer, the second conductive layer, the third conductive layer, the fourth conductive layer, and the first insulating layer; processing the second metal oxide film to form a second semiconductor layer overlapping with the first semiconductor layer and a third semiconductor layer in contact with a top surface of the second conductive layer, a side surface of the first insulating layer, and a top surface and a side surface of the fourth conductive layer; forming a second insulating layer over the first semiconductor layer, the second semiconductor layer, the third conductive layer, the third semiconductor layer, the fourth conductive layer, and the first insulating layer; forming a third conductive film over the second insulating layer; and processing the third conductive film to form a fifth conductive layer overlapping with the first semiconductor layer and the second semiconductor layer and a sixth conductive layer overlapping with the third semiconductor layer.

### Effect of the Invention

One embodiment of the present invention can provide a semiconductor device including a transistor having a minute size and a manufacturing method thereof. Another embodiment of the present invention can provide a small semiconductor device and a manufacturing method thereof. Another embodiment of the present invention can provide a semiconductor device including a transistor with a high on-state current and a manufacturing method thereof. Another embodiment of the present invention can provide a high-performance semiconductor device and a manufacturing method thereof. Another embodiment of the present invention can provide a semiconductor device with high reliability and a manufacturing method thereof. Another embodiment of the present invention can provide a method for manufacturing a semiconductor device with high productivity. Another embodiment of the present invention can provide a novel semiconductor device and a manufacturing method thereof.

Note that the description of these effects does not preclude the presence of other effects. One embodiment of the present invention does not necessarily have all of these effects. Note that effects other than these can be derived from the description of the specification, the drawings, the claims, and the like.

### BRIEF DESCRIPTION OF THE DRAWINGS

FIG. 1A is a plan view illustrating an example of a semiconductor device. FIG. 1B and FIG. 1C are cross-sectional views illustrating the example of the semiconductor device.

FIG. 2A is a plan view illustrating an example of a semiconductor device. FIG. 2B is a cross-sectional view illustrating the example of the semiconductor device.

FIG. 3A is a plan view illustrating an example of a semiconductor device. FIG. 3B and FIG. 3C are cross-sectional views illustrating the example of the semiconductor device.

FIG. 4A and FIG. 4B are cross-sectional views illustrating examples of a semiconductor device.

FIG. 5A is a plan view illustrating an example of a semiconductor device. FIG. 5B and FIG. 5C are cross-sectional views illustrating the example of the semiconductor device.

FIG. 6A is a plan view illustrating an example of a semiconductor device. FIG. 6B and FIG. 6C are cross-sectional views illustrating the example of the semiconductor device.

FIG. 7A is a plan view illustrating an example of a semiconductor device. FIG. 7B and FIG. 7C are cross-sectional views illustrating the example of the semiconductor device.

FIG. 8A is a plan view illustrating an example of a semiconductor device. FIG. 8B and FIG. 8C are cross-sectional views illustrating the example of the semiconductor device.

FIG. 9A is a plan view illustrating an example of a semiconductor device. FIG. 9B and FIG. 9C are cross-sectional views illustrating the example of the semiconductor device.

FIG. 10A is a plan view illustrating an example of a semiconductor device. FIG. 10B and FIG. 10C are cross-sectional views illustrating the example of the semiconductor device.

FIG. 11A is a plan view illustrating an example of a semiconductor device. FIG. 11B and FIG. 11C are cross-sectional views illustrating the example of the semiconductor device.

FIG. 12A is a plan view illustrating an example of a semiconductor device. FIG. 12B and FIG. 12C are cross-sectional views illustrating the example of the semiconductor device.

FIG. 13A is a plan view illustrating an example of a semiconductor device. FIG. 13B and FIG. 13C are cross-sectional views illustrating the example of the semiconductor device.

FIG. 14A to FIG. 14E are cross-sectional views illustrating an example of a method for manufacturing a semiconductor device.

FIG. 15A to FIG. 15D are cross-sectional views illustrating an example of a method for manufacturing a semiconductor device.

FIG. 16A to FIG. 16C are cross-sectional views illustrating an example of a method for manufacturing a semiconductor device.

FIG. 17A to FIG. 17C are cross-sectional views illustrating an example of a method for manufacturing a semiconductor device.

FIG. 18A and FIG. 18B are cross-sectional views illustrating an example of a method for manufacturing a semiconductor device.

FIG. 19A to FIG. 19E are cross-sectional views illustrating the example of the method for manufacturing the semiconductor device.

FIG. 20A to FIG. 20C are cross-sectional views illustrating an example of a method for manufacturing a semiconductor device.

FIG. 21A to FIG. 21C are cross-sectional views illustrating an example of a method for manufacturing a semiconductor device.

FIG. 22 is a cross-sectional view illustrating an example of a method for manufacturing a semiconductor device.

FIG. 23A is a perspective view illustrating an example of a display apparatus. FIG. 23B is a block diagram of the display apparatus.

FIG. 24A is a circuit diagram of a latch circuit. FIG. 24B is a circuit diagram of an inverter circuit.

FIG. 25A and FIG. 25B are circuit diagrams of pixel circuits. FIG. 25C is a cross-sectional view illustrating an example of the pixel circuit.

FIG. 26 is a cross-sectional view illustrating an example of a display apparatus.

FIG. 27 is a cross-sectional view illustrating an example of a display apparatus.

FIG. 28 is a cross-sectional view illustrating an example of a display apparatus.

FIG. 29A to FIG. 29C are cross-sectional views illustrating examples of a display apparatus.

FIG. 30 is a cross-sectional view illustrating an example of a display apparatus.

FIG. 31 is a cross-sectional view illustrating an example of a display apparatus.

FIG. 32 is a cross-sectional view illustrating an example of a display apparatus.

FIG. 33A to FIG. 33F are cross-sectional views illustrating an example of a method for manufacturing a display apparatus.

FIG. 34A to FIG. 34D are diagrams illustrating examples of electronic devices.

FIG. 35A to FIG. 35F are diagrams illustrating examples of electronic devices.

FIG. 36A to FIG. 36G are diagrams illustrating examples of electronic devices.

FIG. 37A and FIG. 37B are diagrams showing the Id-Vg characteristics of the transistors.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, and the like disclosed in the drawings.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device manufactured using a metal mask or an FMM (fine metal mask, high-definition metal mask) may be referred to as a device having an MM (metal mask) structure. In this specification and the like, a device manufactured without using a metal mask or an FMM may be referred to as a device having an MML (metal maskless) structure.

In this specification and the like, a structure where at least light-emitting layers of light-emitting devices having different emission wavelengths are separately formed is sometimes referred to as an SBS (Side By Side) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be distinguished from each other on the basis of the cross-sectional shape or properties in some cases. One layer may have two or three functions of the carrier-injection layer, the carrier-transport layer, and the carrier-blocking layer in some cases.

In this specification and the like, a light-emitting device includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving device (also referred to as a light-receiving element) includes at least an active layer functioning as a photoelectric conversion layer between a pair of electrodes.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In this specification and the like, a tapered shape refers to a shape such that at least part of a side surface of a component is inclined with respect to a substrate surface or a formation surface. For example, a tapered shape refers to a shape including a region where the angle formed by the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

In this specification and the like, a sacrificial layer (may be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

In this specification and the like, the expression “having substantially the same shape in a plan view” means that at least outlines of stacked layers partly overlap each other. For example, the case of processing an upper layer and a lower layer with the use of the same mask pattern or mask patterns that are partly the same is included. Note that in some cases, the outlines do not exactly overlap with each other and the upper layer is positioned inward from the lower layer or the upper layer is positioned outward from the lower layer; such cases are also represented by the expression “having substantially the same shape in a plan view”.

### Embodiment 1

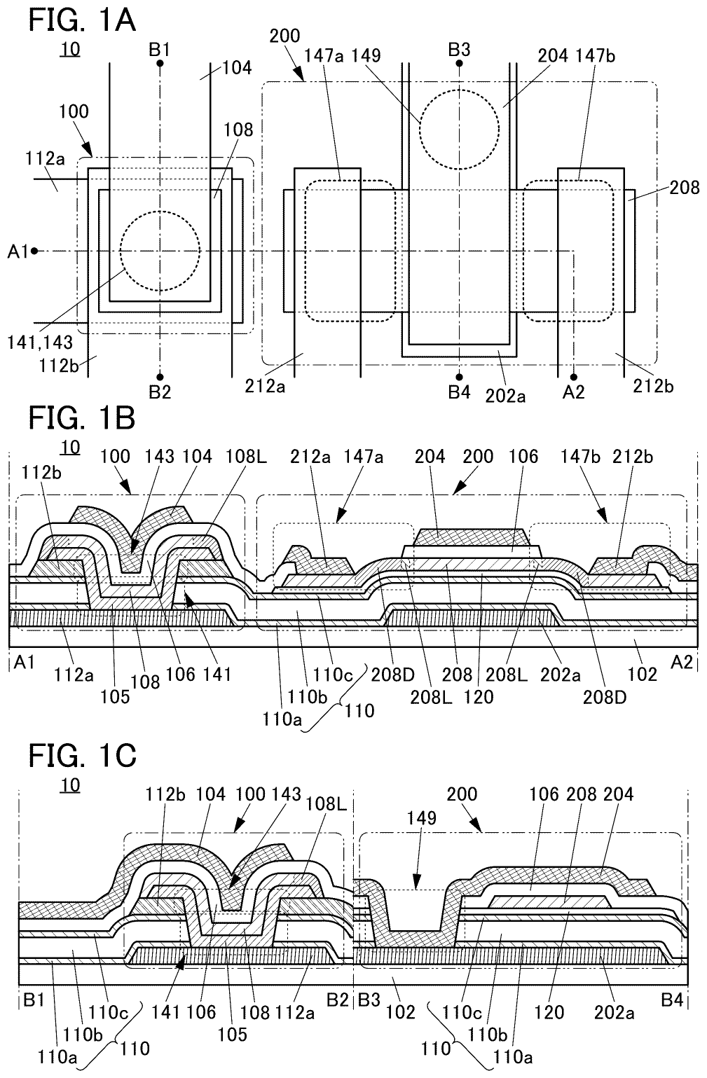

In this embodiment, structure examples of semiconductor devices of one embodiment of the present invention will be described with reference to FIG. 1A to FIG. 13C.

### Structure Example 1

A semiconductor device of one embodiment of the present invention is described. FIG. 1A is a plan view (also referred to as a top view) of a semiconductor device 10. FIG. 1B is a cross-sectional view along the dashed-dotted line A1-A2 in FIG. 1A, and FIG. 1C is a cross-sectional view along the dashed-dotted line B1-B2 and the dashed-dotted line B3-B4 in FIG. 1A. Note that in FIG. 1A, some components (e.g., an insulating layer) of the semiconductor device 10 are not illustrated. Some components are not illustrated in plan views of semiconductor devices in the following drawings, as in FIG. 1A.

The semiconductor device 10 includes a transistor 100 and a transistor 200. The transistor 100 and the transistor 200 are provided over a substrate 102.

The transistor 100 includes a conductive layer 104, an insulating layer 106, a semiconductor layer 108, a semiconductor layer 105, a conductive layer 112a, and a conductive layer 112b. The conductive layer 104 functions as a gate electrode. Part of a region of the insulating layer 106 functions as a gate insulating layer. The conductive layer 112a functions as one of a source electrode and a drain electrode, and the conductive layer 112b functions as the other of the source electrode and the drain electrode. In the semiconductor layer 105 and the semiconductor layer 108, the whole region that is between the source electrode and the drain electrode and overlaps with the gate electrode with the gate insulating layer therebetween functions as a channel formation region. In the semiconductor layer 105, a region in contact with the source electrode functions as a source region, and a region in contact with the drain electrode functions as a drain region.

The conductive layer 112a is provided over the substrate 102. An insulating layer 110 (an insulating layer 110a, an insulating layer 110b, and an insulating layer 110c) is provided over the conductive layer 112a. The conductive layer 112b is provided over the insulating layer 110. The insulating layer 110 includes a region interposed between the conductive layer 112a and the conductive layer 112b. The conductive layer 112a includes a region overlapping with the conductive layer 112b with the insulating layer 110 therebetween. The insulating layer 110 has an opening 141 in a region overlapping with the conductive layer 112a. The top surface of the conductive layer 112a is exposed in the opening 141. The conductive layer 112b has an opening 143 in a region overlapping with the conductive layer 112a. The opening 143 is provided in a region overlapping with the opening 141.

The semiconductor layer 105 is provided to cover the opening 141 and the opening 143. The semiconductor layer 105 includes a region in contact with the top surface and a side surface of the conductive layer 112b, a side surface of the insulating layer 110, and the top surface of the conductive layer 112a. The semiconductor layer 108 is provided to cover the semiconductor layer 105. The semiconductor layer 108 includes a region in contact with the top surface and the side surface of the semiconductor layer 105 and the top surface of the conductive layer 112b. The semiconductor layer 105 and the semiconductor layer 108 are electrically connected to the conductive layer 112a through the opening 141 and the opening 143. The semiconductor layer 105 and the semiconductor layer 108 has a shape along the top surface and the side surface of the conductive layer 112b, the side surface of the insulating layer 110, and the top surface of the conductive layer 112a.

Although FIG. 1B and the like illustrate an example in which the end portion of the semiconductor layer 108 is positioned outward from the end portion of the semiconductor layer 105, one embodiment of the present invention is not limited thereto. In one embodiment of the present invention, the position of the end portion of the semiconductor layer 108 and the position of the end portion of the semiconductor layer 105 may substantially aligned with each other. Alternatively, the end portion of the semiconductor layer 108 may be positioned inward from the end portion of the semiconductor layer 105.

The transistor 100 includes two stacked semiconductor layers (the semiconductor layer 105 and the semiconductor layer 108). A material used in the semiconductor layer 105 and a material used in the semiconductor layer 108 preferably have different compositions or different film quality. For example, the first semiconductor layer (the semiconductor layer 105) is preferably formed using a material having higher mobility than that for the second semiconductor layer (the semiconductor layer 108). Thus, a transistor can achieve high on-state current as compared with the case of using only the semiconductor layer 108. Note that the number of semiconductor layers included in the transistor 100 is not limited to two and the transistor 100 may have a stacked-layer structure of three or more layers.

The part of the region of the insulating layer 106 functions as a gate insulating layer of the transistor 100. The insulating layer 106 is provided to cover the opening 141 and the opening 143 through the semiconductor layer 105 and the semiconductor layer 108. The insulating layer 106 is provided over the semiconductor layer 105, the semiconductor layer 108, the conductive layer 112b, and the insulating layer 110. The insulating layer 106 includes a region in contact with the top surface of the semiconductor layer 108, the side surface of the conductive layer 112b, and a top surface of the insulating layer 110. The insulating layer 106 has a shape along the top surface of the insulating layer 110, the side surface of the conductive layer 112b, and the top surface of the semiconductor layer 108.

The conductive layer 104 functioning as the gate electrode of the transistor 100 is provided in contact with a top surface of the insulating layer 106. The conductive layer 104 includes a region overlapping with the semiconductor layer 105 and the semiconductor layer 108 with the insulating layer 106 therebetween. The conductive layer 104 has a shape along the top surface of the insulating layer 106.

The transistor 100 is what is called a top-gate transistor including the gate electrode above the semiconductor layer 108. Furthermore, since the bottom surface of the semiconductor layer 105 (the surface on the substrate 102 side) is in contact with the source electrode and the drain electrode, the transistor 100 can be referred to as a TGBC (Top Gate Bottom Contact) transistor.

In the transistor 100, the source electrode and the drain electrode are positioned at different heights from the substrate surface, so that a drain current flows in the height direction (vertical direction). Accordingly, the transistor 100 can also be referred to as a vertical transistor, a vertical-channel transistor, VFET (vertical field-effect transistor), or the like.

The channel length of the transistor 100 can be controlled by the thickness of the insulating layer 110 provided between the conductive layer 112a and the conductive layer 112b. Accordingly, a transistor with a channel length smaller than the resolution limit of a light exposure apparatus used for manufacturing the transistor can be manufactured with high accuracy. In addition, since an extremely small channel length can be formed, a transistor having a high on-state current can be achieved. The transistor 100 includes two stacked semiconductor layers (the semiconductor layer 105 and the semiconductor layer 108). As described above, when the semiconductor layer of the transistor 100 has a two-layer stacked structure, the on-state current can be increased as compared with the case where the semiconductor layer has a single-layer structure in some cases. Thus, when materials for the semiconductor layer 105 and the semiconductor layer 108 are selected appropriately, the transistor can have a higher on-state current.

Furthermore, since the channel length of the transistor 100 can be controlled only by adjusting the thickness of the insulating layer 110 that is being formed characteristic variation among the transistors can be reduced in manufacture of a plurality of transistors 100. Accordingly, the operation of the semiconductor device including the transistor 100 can be stabilized and the reliability thereof can be improved. When the variations in characteristics are reduced, the circuit design flexibility is increased and the operation voltage of the semiconductor device can be reduced. Thus, power consumption of the semiconductor device can be reduced.

The transistor 200 includes a conductive layer 204, the insulating layer 106, a semiconductor layer 208, a conductive layer 212a, a conductive layer 212b, an insulating layer 120, the insulating layer 110 (the insulating layer 110a, the insulating layer 110b, and the insulating layer 110c), and a conductive layer 202a. The conductive layer 204 functions as a first gate electrode (also referred to as a top gate electrode). Part of the region of the insulating layer 106 (a region different from the region functioning as the gate insulating layer of the transistor 100) functions as a first gate insulating layer. The conductive layer 212a functions as one of a source electrode and a drain electrode, and the conductive layer 212b functions as the other of the source electrode and the drain electrode. Part of the insulating layer 120 and part of the insulating layer 110 functions as a second gate insulating layer. The conductive layer 202a functions as a second gate electrode (also referred to as a bottom gate electrode and a back gate electrode).

In the semiconductor layer 208, a portion that is between a region in contact with the source electrode and a region in contact with the drain electrode and overlap with at least one of the conductive layer 204 and the conductive layer 202a functions as a channel formation region. Note that for easy explanation, the portion of the semiconductor layer 208 overlapping with the conductive layer 204 is sometimes referred to as a channel formation region; however, a channel can be actually formed in a portion not overlapping with the conductive layer 204 and overlapping with the conductive layer 202a.

The semiconductor layer 208 includes a pair of regions 208D composed of a region interposed between the first gate insulating layer and the source electrode and a region interposed between the first gate insulating layer and the drain electrode in the plan view, and includes a pair of regions 208L each of which is a region interposed between the channel formation region (the portion of the semiconductor layer 208 overlapping with the conductive layer 204) and the region 208D. The region 208L can also be regarded as a region of the semiconductor layer 208 that overlaps with the first gate insulating layer and does not overlap with the first gate electrode. In the semiconductor layer 208, a region in contact with the source electrode functions as a source region, and a region in contact with the drain electrode functions as a drain region.

That is, the semiconductor layer 208 includes a channel formation region, the pair of regions 208L between which the channel formation region is interposed, the pair of regions 208D outside the pair of regions 208L, and the source region and the drain region outside the pair of regions 208D.

The region 208L and the region 208D each have a function of a buffer region that relieves a drain electric field. The region 208L and the region 208D are regions not overlapping with the conductive layer 204 and thus are regions where a channel is hardly formed even when a gate voltage is applied to the conductive layer 204. The region 208L and the region 208D preferably have a higher carrier concentration than the channel formation region. Thus, the region 208L and the region 208D can function as an LDD (Lightly Doped Drain) region.

The region 208L and the region 208D are regions containing an impurity element. Examples of the impurity element include one or more of hydrogen, boron, carbon, nitrogen, fluorine, phosphorus, sulfur, arsenic, aluminum, magnesium, silicon, and a noble gas. Note that typical examples of a noble gas include helium, neon, argon, krypton, and xenon. It is particularly preferable to use one or more of boron, phosphorus, aluminum, magnesium, and silicon as the impurity element.

The region 208L can be referred to as a region whose resistance is substantially equal to or lower than that of the channel formation region, a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region.

The region 208D can be referred to as a region whose resistance is substantially equal to or lower than that of the region 208L, a region whose carrier concentration is substantially equal to or higher than that of the region 208L, a region whose oxygen vacancy density is substantially equal to or higher than that of the region 208L, or a region whose impurity concentration is substantially equal to or higher than that of the region 208L.

In this manner, the region 208L and the region 208D functioning as the LDD region are provided between the channel formation region and the source region and between the channel formation region and the drain region, whereby the transistor 200 can have a high source-drain breakdown voltage, a high on-state current, and high reliability.

When the region 208L and the region 208D are formed by adding the above-described impurity element to the semiconductor layer 208, the impurity element may be supplied to the semiconductor layer 108 through the insulating layer 106 with use of the conductive layer 104 as a mask. Consequently, a region 108L is formed in the region of the semiconductor layer 108 not overlapping with the conductive layer 104 as illustrated in the FIG. 1B and the like. The region 108L is not necessarily formed. For example, in the case where the conductive layer 104 is extended to cover the end portion of the semiconductor layer 108, the conductive layer 104 masks the whole the semiconductor layer 108 to preclude the supply of the impurity element to the semiconductor layer 108, and the region 108L is not formed.

The conductive layer 202a is provided in a region over the substrate 102 which is different from the region where the conductive layer 112a is provided. The conductive layer 202a and the conductive layer 112a can be formed using the same material and in the same step. The insulating layer 110 is provided over the conductive layer 202a. The insulating layer 120 is provided over the insulating layer 110. The semiconductor layer 208 is provided over the insulating layer 120 to include a region overlapping with the conductive layer 202a. The semiconductor layer 208 and the semiconductor layer 108 can be formed using the same material and in the same step. The insulating layer 106, the conductive layer 212a, and the conductive layer 212b are provided over the semiconductor layer 208.

The part of the region (different from the region functioning as the gate insulating layer of the transistor 100) of the insulating layer 106 functioning as the first gate insulating layer of the transistor 200 is provided in contact with a top surface of the semiconductor layer 208 and between the conductive layer 212a and the conductive layer 212b to include a region overlapping with the conductive layer 202a.

Over the semiconductor layer 208, an opening 147a and an opening 147b are provided in the insulating layer 106 so that the conductive layer 204 is interposed therebetween. The opening 147a and the opening 147b are openings reaching the source region or the drain region and the region 208D of the semiconductor layer 208. In the opening 147a, the conductive layer 212a functioning as one of the source electrode and the drain electrode of the transistor 200 is in contact with a top surface of the semiconductor layer 208 (one of the source region and the drain region). In the opening 147b, the conductive layer 212b functioning as the other of the source electrode and the drain electrode of the transistor 200 is in contact with a top surface of the semiconductor layer 208 (the other of the source region and the drain region).

The conductive layer 204 functioning as the first gate electrode of the transistor 200 is provided in contact with a top surface of the insulating layer 106. The conductive layer 204 includes a region overlapping with the conductive layer 202a with the insulating layer 106 and the semiconductor layer 208 therebetween. The conductive layer 204, the conductive layer 212a, the conductive layer 212b, and the conductive layer 104 can be formed using the same material and in the same step.

Note that as illustrated in FIG. 1A and FIG. 1C, the conductive layer 204 may be electrically connected to the conductive layer 202a through an opening 149 provided in the insulating layer 110, the insulating layer 120, and the insulating layer 106. In that case, the conductive layer 204 and the conductive layer 202a can be supplied with the same potential. When the same potential is applied to the conductive layer 204 and the conductive layer 202a, the amount of current that can flow in the transistor 200 in an on state (on-state current) can be increased. Furthermore, leakage current between the source and the drain of the transistor 200 in an off state (also referred to as off-state current) can be reduced. The conductive layer 204 is provided to cover the opening 149 and includes a region in contact with the conductive layer 202a.

As illustrated in FIG. 1A and FIG. 1C, the conductive layer 204 and the conductive layer 202a preferably extend beyond the end portion of the semiconductor layer 208 in the channel width direction of the transistor 200. In that case, as shown in FIG. 1C, the whole of the semiconductor layer 208 in the channel width direction is covered with the conductive layer 204 with the insulating layer 106 therebetween and also covered with the conductive layer 202a with the insulating layer 110 and the insulating layer 120 therebetween. In such a structure, the semiconductor layer 208 can be electrically surrounded by electric fields generated by the pair of gate electrodes. In that case, it is particularly preferable that the same potential be supplied to the conductive layer 204 and the conductive layer 202a. In that case, electric fields for inducing a channel can be effectively applied to the semiconductor layer 208, whereby the on-state current of the transistor 200 can be increased. Thus, the transistor 200 can also be miniaturized.

Note that a structure where the conductive layer 204 and the conductive layer 202a are not connected to each other may be employed. In that case, a constant potential may be applied to one of the pair of gate electrodes, and a signal for driving the transistor 200 may be applied to the other of the pair of gate electrodes. In this case, the potential applied to one of the gate electrodes can control the threshold voltage at the time of driving the transistor 200 with the other gate electrode.

The conductive layer 202a may be electrically connected to the conductive layer 212a or the conductive layer 212b. In that case, the conductive layer 212a or the conductive layer 212b and the conductive layer 202a are electrically connected to each other through an opening provided in the insulating layer 106, the insulating layer 120, and the insulating layer 110.

The transistor 200 is a transistor including the first gate electrode and the second gate electrode over and below the semiconductor layer 208. For example, when an impurity element is added to the semiconductor layer 208 with the use of the conductive layer 204 having a function of the first gate electrode as a mask, the region 208D and the region 208L functioning as the LDD region can be formed in a self-aligned manner. Thus, the transistor 200 can be referred to as a TGSA (Top Gate Self-Aligned) transistor.

The channel length of the transistor 200 can be controlled by the length of the conductive layer 204. Accordingly, the channel length of the transistor 200 is larger than or equal to the resolution limit of a light exposure apparatus used for manufacturing the transistor. The transistor with a long channel length can have favorable saturation characteristics.

The transistor 100 with a short channel length and the transistor 200 with a long channel length can be formed over the same substrate by the formation steps some of which are shared, as described above. For example, the transistor 100 is used as the transistor required to have a high on-state current and the transistor 200 is used as the transistor required to have favorable saturation characteristics, thereby providing the semiconductor device 10 with high performance can be achieved.

For example, in the case where the semiconductor device 10 of one embodiment of the present invention is used for a display apparatus, the transistor 100 can be used as a selection transistor included in a pixel circuit included in the display apparatus, and the transistor 200 can be used as a driving transistor included in the pixel circuit included in the display apparatus. The transistor 100 can be used as a transistor included in a driver circuit (e.g., a gate line driver circuit or a source line driver circuit) included in the display apparatus, and the transistor 200 can be used as a transistor included in a pixel circuit included in the display apparatus.

In the plain view of FIG. 1A, the shapes of the opening 141, the opening 143, and the opening 149 are illustrated as a circle and the shapes of the opening 147a and the opening 147b are illustrated as a quadrangle with rounded corners, one embodiment of the present invention is not limited thereto. The shape of each opening in the plan view can be a circle or an ellipse, for example. Examples of the shape of each opening in the plan view include polygons such as a triangle, a tetragon (including a rectangle, a rhombus, and a square), and a pentagon; and polygons with rounded corners. In particular, the shapes of the opening 141 and the opening 143 in the plan view are preferably circles as illustrated in FIG. 1A.

Next, components of the transistor 100 and the transistor 200 are described in detail.

An end portion of the conductive layer 112b on the opening 143 side is preferably aligned or substantially aligned with an end portion of the insulating layer 110 on the opening 141 side. In other words, the opening 143 and the opening 141 have the same or substantially the same shape in the plan view. Note that in this specification and the like, the end portion of the conductive layer 112b on the opening 143 side refers to the end portion of the bottom surface of the conductive layer 112b on the opening 143 side. The bottom surface of the conductive layer 112b refers to the surface thereof on the insulating layer 110 side. The end portion of the insulating layer 110 on the opening 141 side refers to the end portion of the top surface of the insulating layer 110 on the opening 141 side. The top surface of the insulating layer 110 refers to the surface thereof on the conductive layer 112b side. The shape of the opening 143 in the plan view refers to the shape of the end portion of the bottom surface of the conductive layer 112b on the opening 143 side. The shape of the opening 141 in the plan view refers to the shape of the end portion of the top surface of the insulating layer 110 on the opening 141 side.

The opening 141 can be formed using the resist mask used for the formation of the opening 143, for example. Specifically, an insulating film to be the insulating layer 110, a conductive film to be the conductive layer 112b over the insulating film, and a resist mask over the conductive film are formed. Then, the opening 143 is formed in the conductive film to be the conductive layer 112b using the resist mask and then the opening 141 is formed in the insulating film to be the insulating layer 110 using the resist mask, whereby the end portion of the opening 141 and the end portion of the opening 143 can be aligned or substantially aligned with each other. With such a structure, processes can be simplified.

After the opening 143 is formed, the opening 141 may be formed in a step different from that of the opening 143. There is no particular limitation on the formation order of the opening 141 and the opening 143. For example, after the opening 141 is formed in the insulating film to be the insulating layer 110, the conductive film to be the conductive layer 112b may be formed, and the opening 143 may be formed in the conductive film.

The end portion of the conductive layer 112b on the opening 143 side is not necessarily aligned with the end portion of the insulating layer 110 on the opening 141 side. That is, the opening 143 and the opening 141 not necessarily have the same shape in the plan view. In the plan view, the opening 143 preferably covers the opening 141. The end portion of the conductive layer 112b on the opening 143 side may be located outward from the end portion of the insulating layer 110 on the opening 141 side. In that case, the semiconductor layer 105 includes a region in contact with the top surface and the side surface of the conductive layer 112b, the top surface and the side surface of the insulating layer 110, and the top surface of the conductive layer 112a. With such a structure, a step on the formation surface of a layer (e.g., the semiconductor layer 105) which is formed over the conductive layer 112a, the insulating layer 110, and the conductive layer 112b is reduced. Accordingly, the coverage with layers formed over the conductive layer 112a, the insulating layer 110, and the conductive layer 112b can be improved, which can inhibit defects such as step disconnection or a void from being generated in the layer.

Although this embodiment describes the structure in which the opening 141 and the opening 143 are provided in the insulating layer 110 and the conductive layer 112b, respectively, and the semiconductor layer 105 and the semiconductor layer 108 are provided to cover the opening 141 and the opening 143, one embodiment of the present invention is not limited thereto. The transistor 100 of one embodiment of the present invention includes a first region where the insulating layer 110 is provided over the conductive layer 112a and a second region where the insulating layer 110 is not provided over the conductive layer 112a. In the transistor 100, the semiconductor layer 105 and the semiconductor layer 108 are provided at a step generated by the first region and the second region. The insulating layer 106 is provided over the semiconductor layer 105 and the semiconductor layer 108, and the conductive layer 104 is provided to overlap with the semiconductor layer 105 and the semiconductor layer 108 with the insulating layer 106 therebetween.

The semiconductor layer 105 preferably covers the end portion of the conductive layer 112b on the opening 143 side. FIG. 1B and the like illustrates a structure where the end portion of the semiconductor layer 105 is positioned over the conductive layer 112b. That is, the end portion of the semiconductor layer 105 is in contact with the top surface of the conductive layer 112b. Note that the semiconductor layer 105 may extend to and cover an end portion of the conductive layer 112b that does not face the opening 143. The end portion of the semiconductor layer 105 may be in contact with the top surface of the insulating layer 110.

The semiconductor layer 105 is provided to cover the opening 141 and the opening 143. As illustrated in FIG. 1B and the like, the semiconductor layer 105 includes a region in contact with the top surface of the conductive layer 112a in the opening 141.

The semiconductor layer 108 is provided to cover the semiconductor layer 105. FIG. 1B and the like illustrate a structure in which the semiconductor layer 108 is in contact with the top surface and the side surface of the semiconductor layer 105 and the top surface of the conductive layer 112b. Note that the end portion of the semiconductor layer 108 is not necessarily positioned on the top surface of the conductive layer 112b. The end portion of the semiconductor layer 108 may be positioned on the side surface of the semiconductor layer 105 or on the top surface of the semiconductor layer 105.

The semiconductor layer 208 can be formed in the same step as the semiconductor layer 108. As illustrated in FIG. 1B and the like, the semiconductor layer 208 is provided over the insulating layer 120. Note that the semiconductor layer 108 and the semiconductor layer 208 may be formed in different steps. The material used for the semiconductor layer 108 may be different from the material used for the semiconductor layer 208.

Although the semiconductor layer 108 and the semiconductor layer 208 each have a single-layer structure in FIG. 1B and the like, one embodiment of the present invention is not limited thereto. The semiconductor layer 108 and the semiconductor layer 208 may each have a stacked-layer structure of two or more layers.

One of regions of the insulating layers 106 is provided over the semiconductor layer 108, and another region is provided over the semiconductor layer 208.

The conductive layer 104 is provided to cover the opening 141 and the opening 143 with the insulating layer 106 therebetween. The conductive layer 204 is provided over the insulating layer 106 to include a region overlapping with the semiconductor layer 208. The conductive layer 204 can be formed in the same step as the conductive layer 104.

As illustrated in FIG. 1B and the like, the conductive layer 104 includes a region overlapping with the semiconductor layer 105 and the semiconductor layer 108 with the insulating layer 106 therebetween in the opening 141 and the opening 143. The conductive layer 104 includes a region overlapping with the conductive layer 112a and a region overlapping with the conductive layer 112b with the insulating layer 106, the semiconductor layer 108, and the semiconductor layer 105 therebetween. The conductive layer 104 preferably covers the end portion of the conductive layer 112b on the opening 143 side. With such a structure, in the semiconductor layer 105 and the semiconductor layer 108, the whole region that is between the source electrode and the drain electrode and overlaps with the gate electrode with the gate insulating layer therebetween can function as a channel formation region. Note that the conductive layer 104 may extend to and cover the end portion of the conductive layer 112b that does not face the opening 143. The conductive layer 104 may extend to and cover the end portion of the semiconductor layer 108.

The conductive layer 112a, the conductive layer 112b, and the conductive layer 104 can each also function as a wiring. The transistor 100 can be provided in a region where these wirings overlap with each other, and the area occupied by the transistor 100 and the wirings can be reduced in the circuit including the transistor 100 and the wirings. Accordingly, the area occupied by the circuit can be reduced, which makes it possible to provide a small semiconductor device. When the semiconductor device 10 of one embodiment of the present invention is used for a pixel circuit of a display apparatus, the area occupied by the pixel circuit can be reduced and a high-definition display apparatus can be provided, for example. When the semiconductor device 10 of one embodiment of the present invention is used for a driver circuit (e.g., a gate line driver circuit and a source line driver circuit) of a display apparatus, the area occupied by the driver circuit can be reduced and the display apparatus can have a narrow bezel.

In the semiconductor device 10 of one embodiment of the present invention, the conductive layer 112a, the conductive layer 112b, the conductive layer 104, and the conductive layer 204 functioning as wirings are provided in different layers. Accordingly, the wirings can be placed in their respective layers, leading to high layout flexibility and a reduction in the area occupied by the circuit.

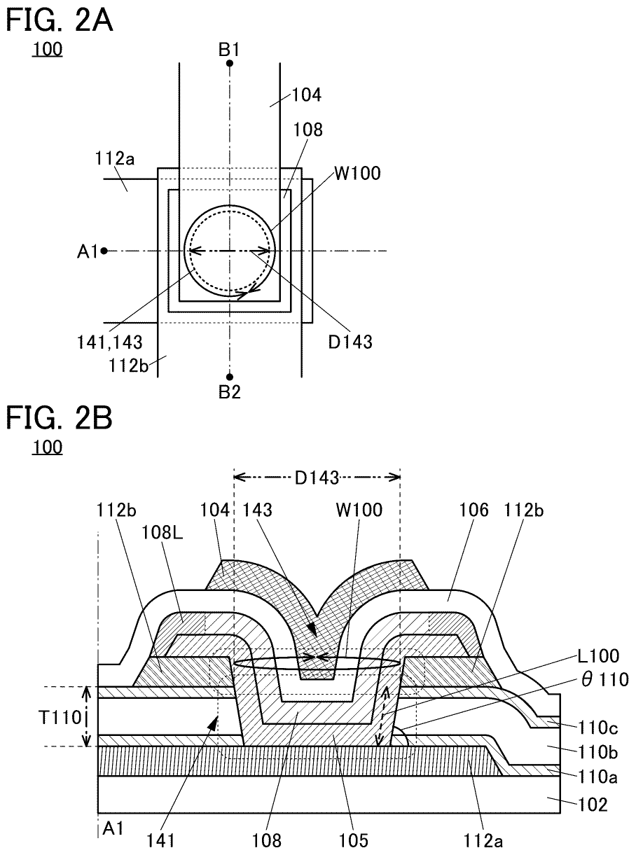

Here, the channel length and channel width of the transistor 100 are described with reference to FIG. 2A and FIG. 2B. FIG. 2A is a plan view of the transistor 100. FIG. 2B is an enlarged view of the transistor 100 in FIG. 1B.

In the semiconductor layer 105, a region in contact with the conductive layer 112a functions as one of the source region and the drain region, and a region in contact with the conductive layer 112b functions as the other of the source region and the drain region. In the semiconductor layer 105 and the semiconductor layer 108, a region between the source region and the drain region functions as a channel formation region.

The channel length of the transistor 100 is a distance between the source region and the drain region. In FIG. 2B, a channel length L100 of the transistor 100 is indicated by a dashed double-headed arrow. In the cross-sectional view, the channel length L100 is the distance between an end portion of the region where the semiconductor layer 105 is in contact with the conductive layer 112a and an end portion of the region where the semiconductor layer 105 is in contact with the conductive layer 112b.

Here, the channel length L100 of the transistor 100 corresponds to the length of the side surface of the insulating layer 110 on the opening 141 side in the cross-sectional view. That is, the channel length L100 is determined depending on a thickness T110 of the insulating layer 110 and an angle θ110 formed by the side surface of the insulating layer 110 on the opening 141 side and the formation surface of the insulating layer 110 (here, the top surface of the conductive layer 112a), and is not affected by the performance of a light exposure apparatus used for manufacturing the transistor. Thus, the channel length L100 can be a value smaller than that of the resolution limit of the light exposure apparatus, which enables the transistor to have a minute size. For example, the length L100 is preferably larger than or equal to 0.010 μm and smaller than 3.0 μm, further preferably larger than or equal to 0.050 μm and smaller than 3.0 μm, further preferably larger than or equal to 0.10 μm and smaller than 3.0 μm, still further preferably larger than or equal to 0.15 μm and smaller than 3.0 μm, yet still further preferably larger than or equal to 0.20 μm and smaller than 3.0 μm, yet still further preferably larger than or equal to 0.20 μm and smaller than or equal to 2.5 μm, yet still further preferably larger than or equal to 0.20 μm and smaller than or equal to 2.0 μm, yet still further preferably larger than or equal to 0.20 μm and smaller than or equal to 1.5 μm, yet still further preferably larger than or equal to 0.30 μm and smaller than or equal to 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. In FIG. 2B, the thickness T110 of the insulating layer 110 is indicated by a dashed-dotted double-headed arrow.

The reduction in the channel length L100 can increase the on-state current of the transistor 100. With the use of the transistor 100, a circuit capable of high-speed operation can be manufactured. Furthermore, the area occupied by the circuit can be reduced. Therefore, a small semiconductor device can be obtained. The application of the semiconductor device 10 of one embodiment of the present invention to a large display apparatus or a high-definition display apparatus can reduce signal delay in wirings and reduce display unevenness even if the number of wirings is increased, for example. In addition, since the area occupied by the circuit can be reduced, the bezel of the display apparatus can be narrowed.

By adjusting the thickness T110 and the angle θ110 of the insulating layer 110, the channel length L100 can be controlled.

The thickness T110 of the insulating layer 110 is preferably larger than or equal to 0.010 μm and smaller than 3.0 μm, further preferably larger than or equal to 0.050 μm and smaller than or equal to 2.5 μm, still further preferably larger than or equal to 0.10 μm and smaller than or equal to 2.0 μm, yet still further preferably larger than or equal to 0.15 μm and smaller than or equal to 1.5 μm, yet still further preferably larger than or equal to 0.20 μm and smaller than or equal to 1.2 μm, yet still further preferably larger than or equal to 0.30 μm and smaller than or equal to 1.0 μm, yet still further preferably larger than or equal to 0.40 μm and smaller than or equal to 1.0 μm, yet still further preferably larger than or equal to 0.50 μm and smaller than or equal to 1.0 μm.

The side surface of the insulating layer 110 on the opening 141 side preferably has a tapered shape. The angle θ110 formed by the side surface of the insulating layer 110 on the opening 141 side and the formation surface of the insulating layer 110 (here, the top surface of the conductive layer 112a) is preferably smaller than 90°. By reducing the angle θ110, the coverage with a layer (e.g., the semiconductor layer 105) provided over the insulating layer 110 can be improved. However, reducing the angle θ110 might reduce the contact area between the semiconductor layer 105 and the conductive layer 112a to increase the contact resistance between the semiconductor layer 105 and the conductive layer 112a. The angle θ110 can be, for example, greater than or equal to 30° and less than 90°, greater than or equal to 35° and less than or equal to 85°, greater than or equal to 40° and less than or equal to 80°, greater than or equal to 45° and less than or equal to 80°, greater than or equal to 50° and less than or equal to 80°, greater than or equal to 55° and less than or equal to 80°, greater than or equal to 60° and less than or equal to 80°, greater than or equal to 65° and less than or equal to 80°, or greater than or equal to 70° and less than or equal to 80°. The angle θ110 may be less than or equal to 75°, less than or equal to 70°, less than or equal to 65°, or less than or equal to 60°. When the angle θ110 is in the above range, the coverage with the layer (e.g., the semiconductor layer 105) formed over the conductive layer 112a and the insulating layer 110 can be improved, which can inhibit defects such as step disconnection or a void from being generated in the layer. In addition, the contact resistance between the semiconductor layer 105 and the conductive layer 112a can be reduced.

Although FIG. 2B and the like illustrate the structure in which the side surface of the insulating layer 110 on the opening 141 side is linear in the cross-sectional view, one embodiment of the present invention is not limited thereto. In the cross-sectional view, the side surface of the insulating layer 110 on the opening 141 side may be curved, or the side surface may include both a linear region and a curved region.

It is preferable that the conductive layer 112b not be provided in the opening 141. Specifically, it is preferable that the conductive layer 112b not include a region in contact with the side surface of the insulating layer 110 on the opening 141 side. If the conductive layer 112b is also provided inside the opening 141, the channel length L100 of the transistor 100 is shorter than the length of the side surface of the insulating layer 110 on the opening 141 side and the channel length L100 is difficult to control in some cases. Accordingly, it is preferable that the opening 143 and the opening 141 have the same shape in the plan view, or the opening 143 cover the opening 141 in the plan view.

The channel width of the transistor 100 is a width (length) of the source region or a width (length) of the drain region in a direction orthogonal to the channel length direction. That is, the channel width is a width (length) of a region where the semiconductor layer 105 is in contact with the conductive layer 112a or a width (length) of a region where the semiconductor layer 105 is in contact with the conductive layer 112b in the direction orthogonal to the channel length direction. Here, the channel width of the transistor 100 is described as the width (length) of the region where the semiconductor layer 105 is in contact with the conductive layer 112b in the direction orthogonal to the channel length direction. In FIG. 2A and FIG. 2B, a channel width W100 of the transistor 100 is indicated by a solid double-headed arrow. The channel width W100 is the length of the perimeter of the opening 143 in the plan view. Specifically, the channel width W100 is the length of the end portion of the bottom surface (the surface on the insulating layer 110 side) of the conductive layer 112b on the opening 143 side in the plan view.

The channel width W100 is determined by the shape of the opening 143 in the plan view. In FIG. 2A and FIG. 2B, a width D143 of the opening 143 is indicated by the dashed-two dotted double-headed arrow. In the plan view, the width D143 refers to the length of the short side of the smallest rectangle that is circumscribed around the opening 143. In the case where the opening 143 is formed by a photolithography method, the width D143 of the opening 143 is larger than or equal to the resolution limit of a light exposure apparatus. For example, the width D143 is preferably larger than or equal to 0.01 μm and smaller than 5.0 μm, further preferably larger than or equal to 0.01 μm and smaller than 4.5 μm, still further preferably larger than or equal to 0.01 μm and smaller than 4.0 μm, yet still further preferably larger than or equal to 0.01 μm and smaller than 3.5 μm, yet still further preferably larger than or equal to 0.01 μm and smaller than 3.0 μm, yet still further preferably larger than or equal to 0.01 μm and smaller than or equal to 2.5 μm, yet still further preferably larger than or equal to 0.01 μm and smaller than or equal to 2.0 μm, yet still further preferably larger than or equal to 0.01 μm and smaller than or equal to 1.5 μm, yet still further preferably larger than or equal to 0.30 μm and smaller than or equal to 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. In the case where the shape of the opening 143 is a circle in the plan view, the width D143 corresponds to the diameter of the opening 143, and the channel width W100 can be calculated to be “D143×π”.

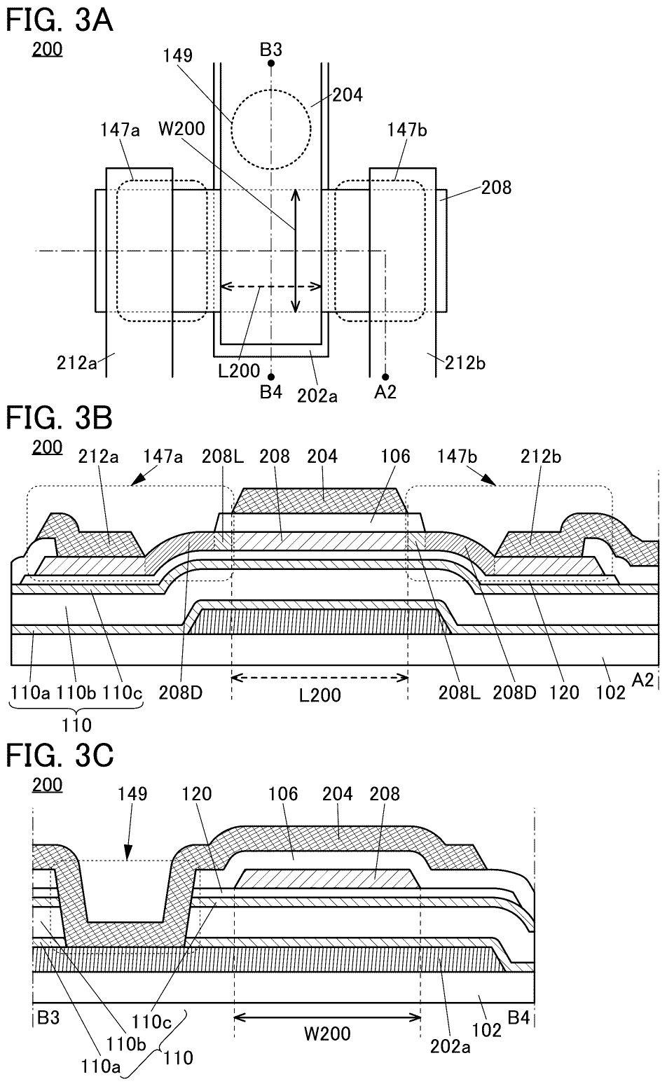

Next, the channel length and the channel width of the transistor 200 will be described with reference to FIG. 3A to FIG. 3C. FIG. 3A is the plan view of the transistor 200. FIG. 3B is an enlarged view of the transistor 200 illustrated in FIG. 1B. FIG. 3C is an enlarged view of the transistor 200 illustrated in FIG. 1C.

In the semiconductor layer 208, a region in contact with the conductive layer 212a functions as one of the source region and the drain region, and a region in contact with the conductive layer 212b functions as the other of the source region and the drain region. In the plan view, the pair of regions 208D is positioned inside the source region and the drain region, and the pair of regions 208L is positioned inside the regions 208D. The region 208D and the region 208L function as the LDD region. In the plan view, the portion inwardly from the pair of regions 208L, i.e., the region overlapping with the conductive layer 204, functions as a channel formation region.

The channel length of the transistor 200 is the length of a region between the pair of regions 208L where the semiconductor layer 208 and the conductive layer 204 overlap with each other (that is, the channel formation region). In FIG. 3A and FIG. 3B, a channel length L200 of the transistor 200 is indicated by a dashed double-headed arrow. The channel length L200 of the transistor 200 is determined by the length of the conductive layer 204, which is larger than or equal to the resolution limit of a light exposure apparatus used for manufacturing the display apparatus. For example, the channel length L200 can be larger than or equal to 1.5 μm. The transistor with a long channel length can have favorable saturation characteristics.

Here, the channel width of the transistor 200 is described as the width (length) of the region where the semiconductor layer 208 and the conductive layer 204 overlap with each other in the direction orthogonal to the channel length direction. In FIG. 3A and FIG. 3C, a channel width W200 of the transistor 200 is indicated by a solid double-headed arrow.

As described above, the channel length L100 of the transistor 100 can have a smaller value than the resolution limit of the light exposure apparatus and the channel length L200 of the transistor 200 can have a value larger than or equal to the resolution limit of the light exposure apparatus. For example, the transistor 100 is used as the transistor required to have a high on-state current and the transistor 200 is used as the transistor required to have favorable saturation characteristics, thereby providing the high-performance semiconductor device 10 utilizing the advantages of the transistors.

In the semiconductor device 10 of one embodiment of the present invention, some of steps can be shared for forming the transistor 100 and the transistor 200 having different structures and different channel lengths over the substrate 102. Specifically, the conductive layer 112a and the conductive layer 202a can be formed in the same step. The semiconductor layer 108 can be formed in the same step as the semiconductor layer 208. The conductive layer 104 can be formed in the same step as the conductive layer 204, the conductive layer 212a, and the conductive layer 212b. Thus, the manufacturing cost of the semiconductor device 10 can be made low.

Components included in the semiconductor device of this embodiment will be described below.

### <Components of Semiconductor Device>

### [Semiconductor Layer 105, Semiconductor Layer 108, Semiconductor Layer 208]

A semiconductor material that can be used for each of the semiconductor layer 105, the semiconductor layer 108, and the semiconductor layer 208 is not particularly limited. For example, a single-element semiconductor or a compound semiconductor can be used. As the single-element semiconductor, silicon or germanium can be used, for example. As the compound semiconductor, gallium arsenide and silicon germanium can be used, for example. As the compound semiconductor, an organic substance having semiconductor characteristics or a metal oxide having semiconductor characteristics (also referred to as an oxide semiconductor) can be used. These semiconductor materials may contain an impurity as a dopant.

There is no particular limitation on the crystallinity of a semiconductor material used for each of the semiconductor layer 105, the semiconductor layer 108, and the semiconductor layer 208, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case degradation of the transistor characteristics can be inhibited.

For each of the semiconductor layer 105, the semiconductor layer 108, and the semiconductor layer 208, silicon can be used. Examples of silicon include single crystal silicon, polycrystalline silicon, microcrystalline silicon, and amorphous silicon. An example of polycrystalline silicon is low-temperature polysilicon (LTPS).

A transistor including amorphous silicon in its semiconductor layer can be formed over a large glass substrate, and can be manufactured at low cost. A transistor including polycrystalline silicon in its semiconductor layer has high field-effect mobility and enables high-speed operation. A transistor including microcrystalline silicon in its semiconductor layer has higher field-effect mobility and enables higher speed operation than the transistor including amorphous silicon.

The semiconductor layer 105, the semiconductor layer 108, and the semiconductor layer 208 may each include a layered material functioning as a semiconductor. The layered material generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered material include graphene, silicene, and chalcogenide.

Chalcogenide is a compound containing chalcogen (an element belonging to Group 16). Examples of chalcogenide include transition metal chalcogenide and chalcogenide of Group 13 elements. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

Each of the semiconductor layer 105, the semiconductor layer 108, and the semiconductor layer 208 preferably contains a metal oxide (also referred to as an oxide semiconductor). Examples of the metal oxide that can be used for the semiconductor layer 105, the semiconductor layer 108, and the semiconductor layer 208 include indium oxide, gallium oxide, and zinc oxide. The metal oxide preferably contains at least indium (In) or zinc (Zn). The metal oxide preferably contains two or three selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, for each of the semiconductor layer 105, the semiconductor layer 108, and the semiconductor layer 208, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (also referred to as Ga—Zn oxide or GZO), aluminum zinc oxide (Al—Zn oxide), indium aluminum zinc oxide (also referred to as In—Al—Zn oxide or IAZO), indium tin zinc oxide (In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO) can be used. Alternatively, indium tin oxide containing silicon, gallium tin oxide (Ga—Sn oxide), aluminum tin oxide (Al—Sn oxide), or the like can be used.

Here, the compositions of the metal oxide in the semiconductor layer 105, the semiconductor layer 108, and the semiconductor layer 208 greatly affect the electrical characteristics and reliability of the transistor 100 and the transistor 200.

For example, by increasing the proportion of the number of indium atoms in the total number of atoms of all the metal elements contained in the metal oxide, a transistor having a high on-state current or high field-effect mobility can be provided. By using such a transistor as a transistor requiring a high on-state current, a semiconductor device having excellent electrical characteristics can be provided.

Note that the metal oxide may contain, instead of or in addition to indium, one or more kinds selected from metal elements belonging to a period of a higher number in the periodic table. The larger the overlap between orbits of metal elements is, the more likely it is that the metal oxide will have high carrier conductivity. Thus, when the transistor includes metal elements with larger period numbers, the field-effect mobility of the transistor can be increased in some cases. As examples of the metal element with a large period number, the metal elements belonging to Period 5 and those belonging to Period 6 are given. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

In the case of using In—Zn oxide for the semiconductor layer, a metal oxide in which the atomic proportion of indium is higher than or equal to that of zinc is preferably used. For example, a metal oxide in which the atomic ratio of metal elements is In:Zn=1:1, In:Zn=2:1, In:Zn=3:1, In:Zn=4:1, In:Zn=5:1, In:Zn=7:1, In:Zn=10:1, or the neighborhood thereof can be used.

In the case where an In—Sn oxide is used for the semiconductor layer, a metal oxide in which the atomic proportion of indium is higher than or equal to that of tin is preferably used. For example, a metal oxide in which the atomic ratio of metal elements is In:Sn=1:1, In:Sn=2:1, In:Sn=3:1, In:Sn=4:1, In:Sn=5:1, In:Sn=7:1, In:Sn=10:1, or the neighborhood thereof can be used.

In the case of using In-M-Zn oxide for the semiconductor layer, a metal oxide in which the atomic proportion of indium with respect to the total number of atoms of all the contained metal elements is higher than the atomic proportion of the element M can be used. It is further preferable to use a metal oxide in which the atomic proportion of zinc is higher than the atomic proportion of the element M. For example, a metal oxide with metal elements in any of the following atomic ratios can be used for the semiconductor layer: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the neighborhood thereof.

In the case where a plurality of metal elements are contained as the element M, the sum of the proportions of the numbers of atoms of the metal elements can be the proportion of the number of the element M atoms. In the case of In—Ga—Al—Zn oxide in which gallium and aluminum are contained as the element M, for example, the sum of the proportion of the number of gallium atoms and the proportion of the number of aluminum atoms can be the proportion of the number of the element M atoms. The atomic ratio between indium, the element M, and zinc is preferably within the ranges described above. In the case of In—Ga—Sn—Zn oxide in which gallium and tin are contained as the element M, for example, the sum of the proportion of the number of gallium atoms and the proportion of the number of tin atoms can be the proportion of the number of the element M atoms. The atomic ratio between indium, the element M, and zinc is preferably within the ranges described above.

It is preferable to use a metal oxide in which the atomic proportion of indium with respect to the total number of atoms of all the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, in the case of using In—Ga—Zn oxide for the semiconductor layer, the proportion of the number of indium atoms in the sum of the numbers of atoms of indium, the element M, and zinc is preferably within the ranges given above.

In this specification and the like, the proportion of the number of indium atoms in the total number of atoms of all the metal elements contained is sometimes referred to as indium content percentage. The same applies to other metal elements.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A composition in the neighborhood in this specification and the like includes the range of ±30% of an intended atomic ratio. For example, in the case of describing an atomic ratio of In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. In the case of describing an atomic ratio of In:M:Zn=5:1:6 or a composition in the neighborhood thereof, the case is included where the atomic ratio of M is greater than 0.1 and less than or equal to 2 and the atomic ratio of zinc is greater than or equal to 5 and less than or equal to 7 with the atomic ratio of indium being 5. In the case of describing an atomic ratio of In:M:Zn=1:1:1 or a composition in the neighborhood thereof, the case is included where the atomic ratio of M is greater than 0.1 and less than or equal to 2 and the atomic ratio of zinc is greater than 0.1 and less than or equal to 2 with the atomic ratio of indium being 1.

For the formation of a metal oxide, a sputtering method or an atomic layer deposition (ALD) method can be suitably used. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

Here, the reliability of a transistor is described. One of indexes for evaluating the reliability of a transistor is a GBT (Gate Bias Temperature) stress test in which the transistor is kept at a high temperature with an electric field applied to its gate. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation with light is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state (a state where a current flows); thus, the amount of change in the threshold voltage in the PBTS test is one important item to be focused on as an indicator of the reliability of the transistor.

With use of a metal oxide that does not contain gallium or has a low gallium content percentage in the semiconductor layer, the transistor can be highly reliable against positive bias application. In other words, the amount of change in the threshold voltage of the transistor in the PBTS test can be small. In the case of using a metal oxide that contains gallium, the gallium content percentage is preferably lower than the indium content percentage. Thus, a highly reliable transistor can be achieved.

One of the factors of changing the threshold voltage in the PBTS test is carrier (here, electron) trapping by defect states at the interface between a semiconductor layer and a gate insulating layer or in the vicinity of the interface. As the density of defect states increases, the number of carriers that are trapped at the above-described interface increases; thus, degradation in the PBTS test becomes more significant. Generation of the defect states can be inhibited and thus change in the threshold voltage in the PBTS test can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, trap sites of carriers (here, electrons) are probably generated easily. This might cause the change in the threshold voltage when a positive potential is supplied to a gate and carriers are trapped at the interface between the semiconductor layer and the gate insulating layer.

Specifically, in the case where an In—Ga—Zn oxide is used for the semiconductor layer, a metal oxide in which the atomic proportion of indium is higher than that of gallium can be used as the semiconductor layer. It is further preferable to use a metal oxide in which the atomic proportion of zinc is higher than the atomic proportion of gallium. In other words, a metal oxide in which the atomic ratios of metal elements satisfy In>Ga and Zn>Ga is preferably used as the semiconductor layer.

For example, a metal oxide with metal elements in any of the following atomic ratios can be used for the semiconductor layer: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

The semiconductor layer is preferably formed using a metal oxide having the following compositions; the atomic proportion of gallium with respect to the total number of atoms of all the contained metal elements is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content percentage in the semiconductor layer enables the transistor to be highly resistant to the PBTS test. Note that an oxygen vacancy (Vo) is less likely to be generated in the metal oxide when the metal oxide contains gallium.

A metal oxide not containing gallium may be used as the semiconductor layer. For example, an In—Zn oxide can be used as the semiconductor layer. In this case, when the atomic proportion of indium with respect to the total number of atoms of all the metal elements contained in the metal oxide is increased, the field-effect mobility of the transistor can be increased. By contrast, when the atomic proportion of zinc with respect to the total number of atoms of all the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used as the semiconductor layer. The use of a metal oxide not containing gallium can make a change in the threshold voltage particularly in the PBTS test extremely small. For example, an oxide containing indium and zinc can be used as the semiconductor layer. At that time, for example, a metal oxide with metal elements in an atomic ratio of In:Zn=2:3, In:Zn=4:1, or the neighborhood thereof can be used.

Although the case of using gallium is described as a typical example, the same applies to the case where the element M is used instead of gallium. A metal oxide in which the atomic proportion of indium is higher than the atomic proportion of the element Mis preferably used as the semiconductor layer. Furthermore, a metal oxide in which the atomic proportion of zinc is higher than the atomic proportion of the element Mis preferably used.

The use of a metal oxide having a low content percentage of the element M for the semiconductor layer enables the transistor to be highly reliable against positive bias application. With the use of the transistor as a transistor that is required to have high reliability against positive bias application, a highly reliable semiconductor device can be provided.

Next, the reliability of a transistor against light is described.

Light incidence on a transistor may change electrical characteristics of the transistor. In particular, a transistor provided in a region on which light can be incident preferably exhibits a small change in electrical characteristics under light irradiation and has high reliability against light. The reliability against light can be evaluated with the amount of change in threshold voltage in an NBTIS test, for example.

The high content percentage of the element M in the metal oxide enables the transistor to be highly reliable against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide in the semiconductor layer is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, a metal oxide with metal elements in any of the following atomic ratios can be used for the semiconductor layer: In:M:Zn=1:1:1, In:M:Zn=1:1:1.2, In:M:Zn=1:3:2, In:M:Zn=1:3:3, In:M:Zn=1:3:4, and the neighborhood thereof.

For the semiconductor layer, in particular, it is preferable to use a metal oxide in which the atomic proportion of the element M with respect to the total number of atoms of all the contained metal elements is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic %.

The use of a metal oxide having a high content percentage of the element M for the semiconductor layer enables the transistor to be highly reliable against light. With the use of the transistor as a transistor that is required to have high reliability against light, a highly reliable semiconductor device can be provided.

An increase in the content percentage of the element M can inhibit the formation of oxygen vacancies (Vo) in the metal oxide. Accordingly, when a metal oxide with a high content percentage of the element M is used for the semiconductor layer, generation of carriers due to oxygen vacancies (Vo) is inhibited, so that the transistor can have a low off-state current. Furthermore, a change in electrical characteristics of the transistor can be inhibited, and the reliability of the transistor can be improved.

Furthermore, a metal oxide having a high zinc content percentage has high crystallinity, whereby diffusion of impurities can be inhibited. Accordingly, when a metal oxide with a high zinc content percentage is used for the semiconductor layer, a change in electrical characteristics of the transistor can be inhibited and the reliability can be increased.

As described above, electrical characteristics and reliability of a transistor depend on the composition of the metal oxide used for the semiconductor layer. Thus, by changing the composition of the metal oxide in accordance with the electrical characteristics and reliability required for the transistor, the semiconductor device can have both excellent electrical characteristics and high reliability.

The semiconductor layer may have a stacked-layer structure including two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being formed over the first metal oxide layer can be suitably employed. In particular, gallium or aluminum is preferably used as the element M. A stacked-layer structure of one selected from indium oxide, indium gallium oxide, and IGZO, and one selected from IAZO, IAGZO, and ITZO (registered trademark) may be employed, for example.

The two or more metal oxide layers included in the semiconductor layer may have a stacked-layer structure of a metal oxide layer not containing the element M and a metal oxide containing the element M. For example, a stacked-layer structure of a first metal oxide layer having a composition of In:M:Zn=4:0:1 [atomic ratio] or in the neighborhood thereof and a second metal oxide layer having a composition of In:M:Zn=1:1:1 [atomic ratio] or in the neighborhood thereof and being formed over the first metal oxide layer can be suitably employed. Note that a structure where a metal oxide not containing the element M is stacked over the metal oxide layer containing the element M may be employed.

For example, a metal oxide layer having a composition of In:M:Zn=4:0:1 [atomic ratio] or in the neighborhood thereof can be used as the semiconductor layer 105, and a metal oxide layer having a composition of In:M:Zn=1:1:1 [atomic ratio] or in the neighborhood thereof can be used as each of the semiconductor layer 108 and the semiconductor layer 208. In this case, the transistor 100 includes two semiconductor layers having different compositions, that is, the semiconductor layer 105 and the semiconductor layer 108, and the transistor 200 includes a single semiconductor layer having the same composition as the semiconductor layer 108.

As described above, a transistor including a metal oxide layer having a high proportion of indium as a semiconductor layer can have a high on-state current. Accordingly, the transistor 100 which includes the semiconductor layer 105 having a higher proportion of indium than (that of) the semiconductor layer 208 can have a higher on-state current than the transistor 200.

A metal oxide layer having a composition used only for the transistor 100 is used as the semiconductor layer 105, and a metal oxide layer used common in the transistor 100 and the transistor 200 is used as each of the semiconductor layer 108 and the semiconductor layer 208. Thus, the compositions of the semiconductor layer 105 and the metal oxide layers used for the semiconductor layer 108 and the semiconductor layer 208 can be selected as appropriate depending on the electrical characteristics required for the transistor 100 and the transistor 200.

Although an example in which a metal oxide layer having a higher proportion of indium than those of the semiconductor layer 108 and the semiconductor layer 208 is used as the semiconductor layer 105 is described above, one embodiment of the present invention is not limited thereto. In accordance with electrical characteristics required for each of the transistor 100 and the transistor 200, a metal oxide having a higher proportion of indium than that of the semiconductor layer 105 may be used for each of the semiconductor layer 108 and the semiconductor layer 208.

It is preferable to use a metal oxide layer having crystallinity as the semiconductor layer. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer, the density of defect states in the semiconductor layer can be reduced, which enables the semiconductor device to have high reliability.

The higher the crystallinity of the metal oxide layer used as the semiconductor layer is, the lower the density of defect states in the semiconductor layer can be. By contrast, the use of a metal oxide layer having low crystallinity enables a transistor to flow a large amount of current.

In the case where the metal oxide layer is formed by a sputtering method, the higher the substrate temperature (the stage temperature) in the formation is, the higher the crystallinity of the metal oxide layer can be. The crystallinity of the metal oxide layer can be increased as the proportion of a flow rate of an oxygen gas to the whole deposition gas (also referred to as oxygen flow rate ratio) used in formation is higher.

The semiconductor layer may have a stacked-layer structure of two or more metal oxide layers having different crystallinities. For example, a stacked-layer structure of a first metal oxide layer and a second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with the use of the same sputtering target and different oxygen flow rate ratios, a stacked-layer structure of two or more metal oxide layers having different crystallinities can be formed. The two or more metal oxide layers included in the semiconductor layer may have different compositions.

The thickness of each of the semiconductor layer 105, the semiconductor layer 108, and the semiconductor layer 208 is preferably larger than or equal to 3 nm and smaller than or equal to 100 nm, further preferably larger than or equal to 5 nm and smaller than or equal to 100 nm, further preferably larger than or equal to 10 nm and smaller than or equal to 100 nm, further preferably larger than or equal to 10 nm and smaller than or equal to 70 nm, further preferably larger than or equal to 15 nm and smaller than or equal to 70 nm, further preferably larger than or equal to 15 nm and smaller than or equal to 50 nm, further preferably larger than or equal to 20 nm and smaller than or equal to 50 nm, further preferably larger than or equal to 20 nm and smaller than or equal to 40 nm, further preferably larger than or equal to 25 nm and smaller than or equal to 40 nm.

The substrate temperature at the time of forming each of the semiconductor layer 105, the semiconductor layer 108, and the semiconductor layer 208 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

Here, oxygen vacancies that might be formed in the semiconductor layer will be described.

In the case where an oxide semiconductor is used for the semiconductor layer, hydrogen contained in the oxide semiconductor reacts with oxygen bonded to a metal atom to be water, and thus sometimes forms oxygen vacancy (Vo) in the oxide semiconductor. In some cases, a defect that is an oxygen vacancy into which hydrogen enters (hereinafter referred to as VoH) functions as a donor and generates an electron serving as a carrier. In other cases, bonding of part of hydrogen to oxygen bonded to a metal atom generates electrons serving as carriers. Thus, a transistor using an oxide semiconductor that contains a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor includes a large amount of hydrogen.

VoH can function as a donor of the oxide semiconductor. However, it is difficult to evaluate the defect quantitatively. Thus, the oxide semiconductor is sometimes evaluated not by its donor concentration but by its carrier concentration. Therefore, in this specification and the like, the carrier concentration assuming the state where an electric field is not applied is sometimes used as the parameter of the oxide semiconductor, instead of the donor concentration. That is, “carrier concentration” described in this specification and the like can be replaced with “donor concentration” in some cases.

Accordingly, in the case where an oxide semiconductor is used as the semiconductor layer, the amount of VoH in the semiconductor layer is preferably reduced as much as possible so that the semiconductor layer becomes a highly purified intrinsic or substantially highly purified intrinsic semiconductor layer. In order to obtain such an oxide semiconductor with sufficiently reduced VoH, it is important to remove impurities (e.g., water and hydrogen) in the oxide semiconductor (this treatment is sometimes referred to as dehydration or dehydrogenation treatment) and supply oxygen to the oxide semiconductor to fill oxygen vacancy (Vo). When an oxide semiconductor with sufficiently reduced oxygen vacancy (Vo), VoH, impurities is used for a channel formation region of a transistor, the transistor can have stable electrical characteristics. Supplying oxygen to an oxide semiconductor to fill an oxygen vacancy (Vo) is sometimes referred to as oxygen adding treatment.

When an oxide semiconductor is used for the semiconductor layer, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1× 10-9 cm⁻³.

The electric resistance of the channel formation region in a state where the channel is not formed is preferably as high as possible. For example, the sheet resistance of the channel formation region is preferably higher than or equal to 1×10⁹ Ω/square, further preferably higher than or equal to 5×10⁹ Ω/square, still further preferably higher than or equal to 1×10¹⁰ Ω/square.

Since the electric resistance of the channel formation region in a state where the channel is not formed is preferably as high as possible, it is not necessary to set its upper limit. If the upper limit is set, the sheet resistance of the channel formation region is preferably higher than or equal to 1×10⁹ Ω/square and lower than or equal to 1×10¹² Ω/square, further preferably higher than or equal to 5×10⁹ Ω/square and lower than or equal to 1×10¹² Ω/square, still further preferably higher than or equal to 1×10¹⁰ Ω/square and lower than or equal to 1×10¹² Ω/square, for example.

A transistor including an oxide semiconductor (hereinafter referred to as an OS transistor) has much higher field-effect mobility than a transistor including amorphous silicon. In addition, an OS transistor has an extremely low leakage current between a source and a drain in an off state (hereinafter, also referred to as off-state current), and charge accumulated in a capacitor that is connected in series to the transistor can be retained for a long period. With the use of the OS transistor in a semiconductor device, the power consumption of the semiconductor device can be reduced.

The semiconductor device of one embodiment of the present invention can be used for a display apparatus, for example. To increase the emission luminance of a light-emitting device included in a pixel circuit in the display apparatus, it is necessary to increase the amount of a current flowing through the light-emitting device. To increase the current amount, the source-drain voltage of a driving transistor included in the pixel circuit needs to be increased. Since the OS transistor has a higher breakdown voltage between a source and a drain than a transistor using silicon (hereinafter, referred to as a Si transistor), a high voltage can be applied between the source and the drain of the OS transistor. Accordingly, when an OS transistor is used as the driving transistor included in the pixel circuit, the amount of a current flowing through the light-emitting device can be increased, so that the emission luminance of the light-emitting device can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of a current flowing between the source and the drain can be finely set by a change in gate-source voltage; thus, the amount of a current flowing through the light-emitting device can be controlled. Therefore, the number of gray levels in the pixel circuit can be increased.

Regarding saturation characteristics of a current flowing when a transistor operates in a saturation region, even in the case where the source-drain voltage of an OS transistor increases gradually, a more stable current (saturation current) can be made flow through the OS transistor than through a Si transistor. Thus, with the use of an OS transistor as a driving transistor, a current can be made flow stably to the light-emitting device, for example, even when a variation in current-voltage characteristics of the light-emitting device occurs. In other words, when the OS transistor operates in the saturation region, the source-drain current hardly changes even with an increase in the source-drain voltage; thus, the emission luminance of the light-emitting device can be stable.

As described above, by using an OS transistor as the driving transistor included in the pixel circuit, it is possible to achieve “inhibition of black floating”, “increase in emission luminance”, “increase in the number of gray levels”, “inhibition of variation in light-emitting devices”, and the like.

A change in electrical characteristics of an OS transistor due to irradiation with radiation is small, i.e., an OS transistor has high resistance to radiation; thus, an OS transistor can be suitably used even in an environment where radiation might enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

### [Insulating Layer 110 and Insulating Layer 120]

For the insulating layer 110, an inorganic insulating material or an organic insulating material can be used. The insulating layer 110 may have a stacked-layer structure of an inorganic insulating material and an organic insulating material.

For the insulating layer 110, an inorganic insulating material can be suitably used. As the inorganic insulating material, one or more of an oxide, an oxynitride, a nitride oxide, and a nitride can be used. For the insulating layer 110, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The oxygen content and the nitrogen content can be analyzed by secondary ion mass spectrometry (SIMS) or XPS. When the content percentage of a target element is high (e.g., higher than or equal to 0.5 atomic %, or higher than or equal to 1 atomic %), XPS is suitable. By contrast, when the content percentage of a target element is low (e.g., lower than or equal to 0.5 atomic %, or lower than or equal to 1 atomic %), SIMS is suitable. To compare the contents of elements, analysis with a combination of SIMS and XPS is preferably used.

The insulating layer 110 may have a stacked-layer structure of two or more layers. FIG. 1B and the like illustrate a structure in which the insulating layer 110 has a stacked-layer structure of the insulating layer 110a, the insulating layer 110b over the insulating layer 110a, and the insulating layer 110c over the insulating layer 110b. For each of the insulating layer 110a, the insulating layer 110b, and the insulating layer 110c, the material that can be used for the insulating layer 110 can be used. For the insulating layer 110a, the insulating layer 110b, and the insulating layer 110c, the same material or different materials may be used. Note that the insulating layer 110a, the insulating layer 110b, and the insulating layer 110c may each have a stacked-layer structure of two or more layers.

The thickness of the insulating layer 110b can be larger than the thickness of the insulating layer 110a. The thickness of the insulating layer 110b can be larger than the thickness of the insulating layer 110c. The formation speed of the insulating layer 110b is preferably high. In particular, the formation speed of the insulating layer 110b is preferably high in the case where the thickness of the insulating layer 110b is large. By increasing the formation speed of the insulating layer 110b, the productivity can be increased. For example, by increasing power at the time of forming the insulating layer 110b, the formation speed can be increased.

The insulating layer 110b may have a stacked-layer structure of two or more layers. For example, the insulating layer 110b has high stress when the insulating layer 110b has a large thickness, which might cause warpage of the substrate. In some cases, the formation of the insulating layer 110b in a plurality of steps can inhibit occurrence of problems during the process caused by stress. Note that in a cross-sectional transmission electron microscopy (TEM) image or the like, a boundary between the layers included in the insulating layer 110b is unclear in some cases.

The stress of the insulating layer 110b is preferably low. The insulating layer 110b has high stress when the insulating layer 110b has a large thickness, which might cause warpage of the substrate. The low stress of the insulating layer 110b can inhibit occurrence of problems during the process caused by stress such as warpage of the substrate.

The insulating layer 110a and the insulating layer 110c function as blocking films that inhibit release of gas from the insulating layer 110b. For each of the insulating layer 110a and the insulating layer 110c, a material in which gas is hardly diffused is preferably used. The insulating layer 110a and the insulating layer 110c each preferably include a region having a higher film density than the insulating layer 110b. The insulating layer 110a and the insulating layer 110c having high film densities can have a high blocking property against an impurity (e.g., oxygen and hydrogen). Note that the insulating layer 110a and the insulating layer 110c may have different film densities. For each of the insulating layer 110a and the insulating layer 110c, a material containing more nitrogen than the insulating layer 110b can be used, for example. The insulating layer 110a and the insulating layer 110c in each of which the nitrogen content is high can have a high blocking property against an impurity. Note that the insulating layer 110a and the insulating layer 110c may have different nitrogen contents.

The insulating layer 110a and the insulating layer 110c have thicknesses with which the insulating layers function as blocking films that inhibit release of gas from the insulating layer 110b, and can be thinner than the insulating layer 110b. Note that the insulating layer 110a and the insulating layer 110c may have different thicknesses. The formation speeds of the insulating layer 110a and the insulating layer 110c are preferably lower than the formation speed of the insulating layer 110b. Note that each of the insulating layer 110a and the insulating layer 110c formed at a low speed has a high film density and can have a high blocking property against an impurity. Similarly, each of the insulating layer 110a and the insulating layer 110c formed at a high substrate temperature has a high film density and can have a high blocking property against an impurity.

The film density can be evaluated by Rutherford backscattering spectrometry (RBS) or X-ray reflection (XRR), for example. A difference in film density can be evaluated with a cross-sectional TEM image in some cases. In TEM observation, a transmission electron (TE) image is dark-colored (dark) when the film density is high, and a transmission electron (TE) image is pale (bright) when the film density is low. Thus, in a transmission electron (TE) image, the insulating layer 110a and the insulating layer 110c are each sometimes shown as a dark-colored (dark) image compared to the insulating layer 110b. Note that since the insulating layer 110a, the insulating layer 110b, and the insulating layer 110c have different film densities even when including the same materials, it is sometimes possible to identify the boundary between the insulating layers by a difference in contrast in a TEM image of a cross section.

A difference in nitrogen content between the insulating layer 110a, the insulating layer 110b, and the insulating layer 110c can be confirmed by EDX, for example. In the case where silicon nitride is used for the insulating layer 110a and silicon oxynitride is used for the insulating layer 110b, for example, the ratio of the peak intensity of nitrogen to the peak intensity of silicon in the insulating layer 110a is higher than the ratio of the peak intensity of nitrogen to the peak intensity of silicon in the insulating layer 110b. In the case where silicon nitride is used for the insulating layer 110c and silicon oxynitride is used for the insulating layer 110b, the ratio of the peak intensity of nitrogen to the peak intensity of silicon in the insulating layer 110c is higher than the ratio of the peak intensity of nitrogen to the peak intensity of silicon in the insulating layer 110b. Note that in EDX, the peak of a certain element refers to a point at which the number of counts of the element reaches a local maximum value in a spectrum where the horizontal axis represents the energy of characteristic X-rays and the vertical axis represents the number of counts (the detected value) of characteristic X-rays. Alternatively, the number of counts at an energy of a characteristic X-ray unique to the element may be used to confirm a difference in nitrogen content with the ratio of the number of counts of nitrogen to the number of counts of silicon. For example, the number of counts at 1.739 keV (Si—Kα) can be used for silicon, and the number of counts at 0.392 keV (N—Kα) can be used for nitrogen. The ratio of the number of counts of nitrogen to the number of counts of silicon in the insulating layer 110a is higher than the ratio of the number of counts of nitrogen to the number of counts of silicon in the insulating layer 110b. The ratio of the number of counts of nitrogen to the number of counts of silicon in the insulating layer 110c is higher than the ratio of the number of counts of nitrogen to the number of counts of silicon in the insulating layer 110b.

The insulating layer 110a and the insulating layer 110c may each include a region having a lower hydrogen concentration in the film than the insulating layer 110b. The difference in hydrogen concentration between the insulating layer 110a, the insulating layer 110b, and the insulating layer 110c can be examined by SIMS, for example.

Here, the insulating layer 110 (the insulating layer 110a, the insulating layer 110b, and the insulating layer 110c) is specifically described using a structure in which a metal oxide is used for a semiconductor layer of a transistor as an example.

In the case where an oxide semiconductor is used for the semiconductor layer, an inorganic insulating material can be suitably used for each of the insulating layer 110a, the insulating layer 110b, and the insulating layer 110c.

It is preferable to use an oxide or an oxynitride for the insulating layer 110b. A film from which oxygen is released by heating is preferably used as the insulating layer 110b. For example, silicon oxide or silicon oxynitride can be suitably used for the insulating layer 110b.

Oxygen released from the insulating layer 110b can be supplied to the semiconductor layer. Supplying oxygen from the insulating layer 110b to the semiconductor layer, particularly to the channel formation region in the semiconductor layer, can allow the amount of oxygen vacancies (Vo) and VoH to be reduced in the semiconductor layer, so that a highly reliable transistor having favorable electrical characteristics can be obtained. The insulating layer 110b preferably has a high oxygen diffusion coefficient. When the insulating layer 110b has a high oxygen diffusion coefficient, oxygen is easily diffused in the insulating layer 110b, so that oxygen can be efficiently supplied from the insulating layer 110b to the semiconductor layer. Examples of treatment for supplying oxygen to the semiconductor layer include heat treatment in an oxygen-containing atmosphere and plasma treatment in an oxygen-containing atmosphere.

It is preferable that the amount of oxygen vacancies (Vo) and VoH be small in the channel formation region of the transistor. Particularly in the case where the channel length is short, an oxygen vacancy (Vo) and VoH in the channel formation region greatly affect the electrical characteristics and the reliability of the transistor. For example, diffusion of VoH from the source region or the drain region into the channel formation region increases the carrier concentration in the channel formation region, which might cause a change in the threshold voltage or a reduction in the reliability of the transistor. The shorter the channel length is, the more the electrical characteristics and reliability of the transistor are affected by such diffusion of VoH. Supplying oxygen from the insulating layer 110b to the semiconductor layer, particularly to the channel formation region in the semiconductor layer, can allow the amount of oxygen vacancies (Vo) and VoH to be reduced. Thus, the transistor with a short channel length can have favorable electrical characteristics and high reliability.

The amount of impurities (e.g., water and hydrogen) released from the insulating layer 110b itself is preferably small. With the insulating layer 110b from which a small amount of impurities is released, diffusion of the impurities into the semiconductor layer is inhibited, and the transistor can have favorable electrical characteristics and high reliability.

For example, silicon oxide or silicon oxynitride formed by a PECVD method can be suitably used for the insulating layer 110b. In that case, a mixed gas including a gas containing silicon and a gas containing oxygen is preferably used as a source gas. As the gas containing silicon, one or more of silane, disilane, trisilane, and silane fluoride can be used, for example. As the gas containing oxygen, one or more of oxygen (O₂), ozone (O₃), dinitrogen monoxide (N₂O), nitric oxide (NO), or nitrogen dioxide (NO₂) can be used, for example. Note that by increasing power at the time of forming the insulating layer 110b, the amount of impurities (e.g., water and hydrogen) released from the insulating layer 110b can be reduced.

The insulating layer 110a and the insulating layer 110c are preferably less likely to transmit oxygen. The insulating layer 110a and the insulating layer 110c function as blocking films that inhibit release of oxygen from the insulating layer 110b. Moreover, the insulating layer 110a and the insulating layer 110c are preferably less likely to transmit hydrogen. The insulating layer 110a and the insulating layer 110c function as blocking films that inhibit diffusion of hydrogen into the semiconductor layer from the outside of the transistor. The insulating layer 110a and the insulating layer 110c preferably have high film densities. The insulating layer 110a and the insulating layer 110c having high film densities can have a high blocking property against oxygen and hydrogen. The film densities of the insulating layer 110a and the insulating layer 110c are preferably higher than the film density of the insulating layer 110b. In the case where silicon oxide or silicon oxynitride is used for the insulating layer 110b, silicon nitride, silicon nitride oxide, or aluminum oxide can be suitably used for each of the insulating layer 110a and the insulating layer 110c, for example. The insulating layer 110a and the insulating layer 110c each preferably include a region containing more nitrogen than the insulating layer 110b. For each of the insulating layer 110a and the insulating layer 110c, a material containing more nitrogen than the insulating layer 110b can be used, for example. A nitride or a nitride oxide is preferably used for each of the insulating layer 110a and the insulating layer 110c. For example, silicon nitride or silicon nitride oxide can be suitably used for each of the insulating layer 110a and the insulating layer 110c.

When oxygen contained in the insulating layer 110b is diffused upward from a region of the insulating layer 110b that is not in contact with the semiconductor layer (e.g., the semiconductor layer 105), the amount of oxygen supplied from the insulating layer 110b to the semiconductor layer might be reduced. Provision of the insulating layer 110c over the insulating layer 110b can inhibit upward diffusion of oxygen contained in the insulating layer 110b from the region of the insulating layer 110 that is not in contact with the semiconductor layer. Similarly, provision of the insulating layer 110a under the insulating layer 110b can inhibit downward diffusion of oxygen contained in the insulating layer 110b from the region of the insulating layer 110 that is not in contact with the semiconductor layer. Accordingly, the amount of oxygen supplied from the insulating layer 110b to the semiconductor layer is increased, whereby the amount of oxygen vacancies (Vo) and VoH in the semiconductor layer can be reduced. Consequently, the transistor with favorable electrical characteristics and high reliability can be obtained.

The conductive layer 112a and the conductive layer 112b of the transistor 100 are oxidized by oxygen included in the insulating layer 110b and have high resistance in some cases. Moreover, when the conductive layer 112a and the conductive layer 112b are oxidized by oxygen contained in the insulating layer 110b, the amount of oxygen supplied from the insulating layer 110b to the semiconductor layer (the semiconductor layer 105 and the semiconductor layer 108) might be reduced. Providing the insulating layer 110a between the insulating layer 110b and the conductive layer 112a can inhibit the conductive layer 112a from being oxidized and having high resistance. Similarly, providing the insulating layer 110c between the insulating layer 110b and the conductive layer 112b can inhibit the conductive layer 112b from being oxidized and having high resistance. In addition, the amount of oxygen supplied from the insulating layer 110b to the semiconductor layer is increased and the amount of oxygen vacancies (Vo) and VoH in the semiconductor layer can be reduced, whereby the transistor can have favorable electric characteristics and high reliability.

Hydrogen diffusing into the semiconductor layer reacts with an oxygen atom contained in an oxide semiconductor to be water, and thus sometimes forms an oxygen vacancy (Vo). Furthermore, VoH is formed and the carrier concentration is increased in some cases. Provision of the insulating layer 110a and the insulating layer 110c can allow the amount of oxygen vacancies (Vo) and VoH to be reduced in the semiconductor layer, whereby the transistor can have favorable electric characteristics and high reliability.

The insulating layer 110a and the insulating layer 110c preferably have thicknesses with which the insulating layers function as blocking films against oxygen and hydrogen. When the insulating layer 110a and the insulating layer 110c are thin, the function of a blocking film might deteriorate. Meanwhile, when the insulating layer 110a and the insulating layer 110c are thick, a region where the semiconductor layer (e.g., the semiconductor layer 105) is in contact with the insulating layer 110b is narrowed and the amount of oxygen supplied from the insulating layer 110b to the semiconductor layer might be reduced. The insulating layer 110a and the insulating layer 110c may each be thinner than the insulating layer 110b. The thicknesses of the insulating layer 110a and the insulating layer 110c are each preferably larger than or equal to 5 nm and smaller than or equal to 100 nm, further preferably larger than or equal to 5 nm and smaller than or equal to 70 nm, further preferably larger than or equal to 10 nm and smaller than or equal to 70 nm, further preferably larger than or equal to 10 nm and smaller than or equal to 50 nm, further preferably larger than or equal to 20 nm and smaller than or equal to 50 nm, further preferably larger than or equal to 20 nm and smaller than or equal to 40 nm. The thicknesses of the insulating layer 110a and the insulating layer 110c in the above range can allow the amount of oxygen vacancies (Vo) and VoH to be reduced in the semiconductor layer, particularly in the channel formation region, whereby the transistor can have favorable electric characteristics and high reliability.

The amount of impurities (e.g., water and hydrogen) released from the insulating layer 110a and the insulating layer 110c themselves is preferably small. With the insulating layer 110a and the insulating layer 110c from which a small amount of impurities is released, diffusion of impurities into the semiconductor layer is inhibited, and the transistor can have favorable electrical characteristics and high reliability.

By reducing the amount of impurities (e.g., water and hydrogen) released from the insulating layer 110a and the insulating layer 110c, the semiconductor layer in a region in contact with the insulating layer 110a and the semiconductor layer in a region in contact with the insulating layer 110c can each also function as the channel formation region. Note that when a material that releases impurities (e.g., water and hydrogen) is used for the insulating layer 110a, the semiconductor layer in the region in contact with the insulating layer 110a can function as the source region or the drain region. The same applies to the insulating layer 110c.

Oxygen is supplied from the insulating layer 110b to the semiconductor layer, whereby the amount of oxygen vacancies (Vo) and VoH in the channel formation region is reduced. Consequently, the transistor with favorable electrical characteristics and high reliability can be obtained.

Due to heat applied in a step after the formation of the semiconductor layer, oxygen might be released from the semiconductor layer. However, supply of oxygen from the insulating layer 110 to the semiconductor layer can inhibit an increase in the amount of oxygen vacancies (Vo) and VoH in the semiconductor layer. Furthermore, in a step after the formation of the semiconductor layer, the flexibility of the treatment temperature can be increased. Specifically, also in a step after the formation of the semiconductor layer, the treatment temperature can be high. Consequently, the transistor with favorable electrical characteristics and high reliability can be obtained.

Note that one or both of the insulating layer 110a and the insulating layer 110c are not necessarily provided. A structure in which neither the insulating layer 110a nor the insulating layer 110c is provided may be employed.

For the insulating layer 120, a material that can be used for the insulating layer 110 can be used. Although the insulating layer 120 has a single-layer structure in FIG. 1B and the like, one embodiment of the present invention is not limited thereto. The insulating layer 120 may have a stacked-layer structure of two or more layers.

In the case where a metal oxide is used for the semiconductor layer 208, an insulating layer containing oxygen is preferably used as the insulating layer 120 in contact with the semiconductor layer 208. An oxide or an oxynitride is preferably used as the insulating layer 120. A film from which oxygen is released by heating is preferably used as the insulating layer 120. For the insulating layer 120, a silicon oxide or a silicon oxynitride can be suitably used, for example.

Note that a structure in which no the insulating layer 120 is provided may be employed.

### [Conductive Layer 112a, Conductive Layer 112b, Conductive Layer 104, Conductive Layer 202a, Conductive Layer 212a, Conductive Layer 212b, and Conductive Layer 204]

The conductive layer 112a, the conductive layer 112b, the conductive layer 104, the conductive layer 202a, the conductive layer 212a, the conductive layer 212b, and the conductive layer 204 each functioning as a source electrode, a drain electrode, or a gate electrode can each be formed using one or more of chromium, copper, aluminum, gold, silver, zinc, tantalum, titanium, tungsten, manganese, nickel, iron, cobalt, molybdenum, and niobium; or an alloy containing one or more of these metals as its components. For each of the conductive layer 112a, the conductive layer 112b, the conductive layer 104, the conductive layer 202a, the conductive layer 212a, the conductive layer 212b, and the conductive layer 204, a conductive material with low electrical resistance that contains one or more of copper, silver, gold, and aluminum can be suitably used. Copper or aluminum is particularly preferable because of its high mass-productivity.

As the conductive layer 112a, the conductive layer 112b, the conductive layer 104, the conductive layer 202a, the conductive layer 212a, the conductive layer 212b, and the conductive layer 204, metal oxide films (also referred to as oxide conductors) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 112a, the conductive layer 112b, the conductive layer 104, the conductive layer 202a, the conductive layer 212a, the conductive layer 212b, and the conductive layer 204 may have a stacked-layer structure of a conductive film the above-described oxide conductor (metal oxide) and a conductive film containing a metal or an alloy. The use of the conductive film containing a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, the conductive layer 104, the conductive layer 202a, the conductive layer 212a, the conductive layer 212b, and the conductive layer 204. The use of a Cu—X alloy film enables the manufacturing cost to be reduced because a wet etching process can be used in the processing.

Note that the conductive layer 112a, the conductive layer 112b, the conductive layer 104, the conductive layer 202a, the conductive layer 212a, the conductive layer 212b, and the conductive layer 204 may be formed using the same material or different materials.

Here, the conductive layer 112a and the conductive layer 112b will be described in detail in an example of a structure in which a metal oxide is used for the semiconductor layer 105.

When an oxide semiconductor is used for the semiconductor layer 105, the conductive layer 112a and the conductive layer 112b are oxidized by oxygen contained in the semiconductor layer 105 and have high resistance in some cases. The conductive layer 112a and the conductive layer 112b are oxidized by oxygen included in the insulating layer 110b and have high resistance in some cases. Moreover, when the conductive layer 112a and the conductive layer 112b are oxidized by oxygen contained in the semiconductor layer 105, the amount of oxygen vacancies (Vo) in the semiconductor layer 105 is increased in some cases. When the conductive layer 112a and the conductive layer 112b are oxidized by oxygen contained in the insulating layer 110b, the amount of oxygen supplied from the insulating layer 110b to the semiconductor layer 105 might be reduced.

Since the channel length of the transistor 100 is shorter than that of the transistor 200, oxygen vacancies (Vo) and VoH in the channel formation region greatly affect the electrical characteristics and reliability of the transistor. For example, diffusion of VoH from the source region or the drain region into the channel formation region increases the carrier concentration in the channel formation region, which might cause a change in the threshold voltage or a reduction in the reliability of the transistor 100. The shorter the channel length is, the more the electrical characteristics and reliability of the transistor are affected by such diffusion of VoH. Thus, a material that is less likely to be oxidized is preferably used for each of the conductive layer 112a and the conductive layer 112b in contact with the semiconductor layer 105. An oxide conductor is preferably used for each of the conductive layer 112a and the conductive layer 112b. For example, In—Sn oxide (ITO) or In—Sn—Si oxide (ITSO) can be suitably used. For the conductive layer 112a and the conductive layer 112b, a nitride conductor may be used. Examples of the nitride conductor include tantalum nitride and titanium nitride. The conductive layer 112a and the conductive layer 112b may each have a stacked-layer structure of the above-described materials. Note that the conductive layer 112a and the conductive layer 112b may be formed using the same material or different materials.

With the use of a material that is less likely to be oxidized, the conductive layer 112a and the conductive layer 112b can be inhibited from being oxidized by oxygen contained in the semiconductor layer 105 or oxygen contained in the insulating layer 110b and having high resistance. Furthermore, it is possible to increase the amount of oxygen supplied from the insulating layer 110b to the semiconductor layer 105 while an increase in the amount of oxygen vacancies (Vo) in the semiconductor layer 105 is inhibited. Accordingly, the amount of oxygen vacancies (Vo) and VoH in the semiconductor layer 105 can be reduced, whereby the transistor 100 can have favorable electric characteristics and high reliability.

Note that a material that is less likely to be oxidized may be used for the conductive layer 212a and the conductive layer 212b. The conductive layer 212a and the conductive layer 212b can be formed using a material that can be used for the conductive layer 112a and the conductive layer 112b.

One or more of an oxide conductor and a nitride conductor can be suitably used for the conductive layer 112a functioning as one of a source electrode and a drain electrode of the transistor 100 and the conductive layer 202a functioning as the second gate electrode of the transistor 200. The conductive layer 112a and the conductive layer 202a may each have a two-layer stacked structure. The above-described material may be used for the first layer and a material having lower resistance than that of the material may be used for the second layer. For the second layer, one or more of copper, aluminum, titanium, tungsten, and molybdenum or an alloy containing one or more of these metals as its components can be suitably used, for example. Specifically, in the case where the conductive layer 112a and the conductive layer 202a each have a two-layer stacked structure, it is preferable to use In—Sn—Si oxide (ITSO) for the first layer and tungsten for the second layer.

Note that the structure of the conductive layer 112a and the conductive layer 202a are determined in accordance with wiring resistance required for the conductive layer 112a and the conductive layer 202a. For example, when the wirings (the conductive layer 112a and the conductive layer 202a) are short and requires relatively high wiring resistance, the conductive layer 112a and the conductive layer 202a may have a single-layer structure using a material that is less likely to be oxidized. Meanwhile, when the wirings (the conductive layer 112a and the conductive layer 202a) are long and requires relatively low wiring resistance, the conductive layer 112a and the conductive layer 202a preferably have a stacked-layer structure using a material that is less likely to be oxidized and a low-resistance material.

Note that the structure of the conductive layer 112a and the conductive layer 202a can be employed for another conductive layer. For example, the conductive layer 112b has a stacked-layer structure of a first conductive layer and a second conductive layer over the first conductive layer, and part of the second conductive layer is removed so that a region where the first conductive layer is exposed is provided. In the region, the first conductive layer and the semiconductor layer 105 may be in contact with each other.

### [Insulating Layer 106]

The insulating layer 106 functioning as a gate insulating layer of each of the transistor 100 and the transistor 200 preferably has low defect density. With the insulating layer 106 having low defect density, the transistor 100 and the transistor 200 can have favorable electrical characteristics. In addition, the insulating layer 106 preferably has a high breakdown voltage. With the insulating layer 106 having high breakdown voltage, the transistor 100 and the transistor 200 can have high reliability.

For the insulating layer 106, one or more of an insulating oxide, an insulating oxynitride, an insulating nitride oxide, and an insulating nitride can be used, for example. For the insulating layer 106, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used. The insulating layer 106 may be either a single layer or a stacked layer. The insulating layer 106 may have a stacked-layer structure of an oxide and a nitride.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 106 itself is preferably small. With the insulating layer 106 from which a small amount of impurities is released, diffusion of impurities into the semiconductor layer 108 and the semiconductor layer 208 is inhibited, and the transistor 100 and the transistor 200 can have favorable electrical characteristics and high reliability.

The insulating layer 106 is formed over each of the semiconductor layer 108 and the semiconductor layer 208, and thus is preferably a film formed under conditions where damage to the semiconductor layer 108 and the semiconductor layer 208 is small. For example, the insulating layer 106 is preferably formed under conditions where the film formation speed (also referred to as film formation rate) is sufficiently low. For example, when the insulating layer 106 is formed by a PECVD method under a low-power condition, damage to the semiconductor layer 108 and the semiconductor layer 208 can be extremely small.

Here, the insulating layer 106 will be described in detail with use of a structure in which a metal oxide is used for each of the semiconductor layer 108 and the semiconductor layer 208 as an example.

In order to improve properties of the interface between the insulating layer 106 and the semiconductor layer 108 and the interface between the insulating layer 106 and the semiconductor layer 208, an oxide or an oxynitride is preferably used at least for the side of the insulating layer 106 that is in contact with the semiconductor layer 108 and the semiconductor layer 208. For example, one or more of silicon oxide and silicon oxynitride can be suitably used for the insulating layer 106. A film from which oxygen is released by heating is further preferably used as the insulating layer 106.

Note that the insulating layer 106 may have a stacked-layer structure. The insulating layer 106 can have a stacked-layer structure of an oxide film on the side in contact with the semiconductor layer 108 and the semiconductor layer 208 and a nitride film on the side in contact with the conductive layer 104 and the conductive layer 204. For example, one or more of silicon oxide and silicon oxynitride can be suitably used for the oxide film. Silicon nitride can be suitably used for the nitride film.

### [Substrate 102]

There is no particular limitation on the properties of the material of the substrate 102 as long as the material has heat resistance high enough to withstand at least heat treatment to be performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. Alternatively, any of these substrates over which a semiconductor element is provided may be used as the substrate 102. Note that the shape of the semiconductor substrate and an insulating substrate may be circular or square.

A flexible substrate may be used as the substrate 102, and the transistor 100 and the like may be formed directly on the flexible substrate. Alternatively, a separation layer may be provided between the substrate 102 and the transistor 100 and the like. The separation layer can be used for separation of part or the whole of a semiconductor device completed thereover from the substrate 102 and transferring the part or the whole of the semiconductor device onto another substrate. In that case, the transistor 100 and the like can be transferred onto a substrate having low heat resistance or a flexible substrate as well.

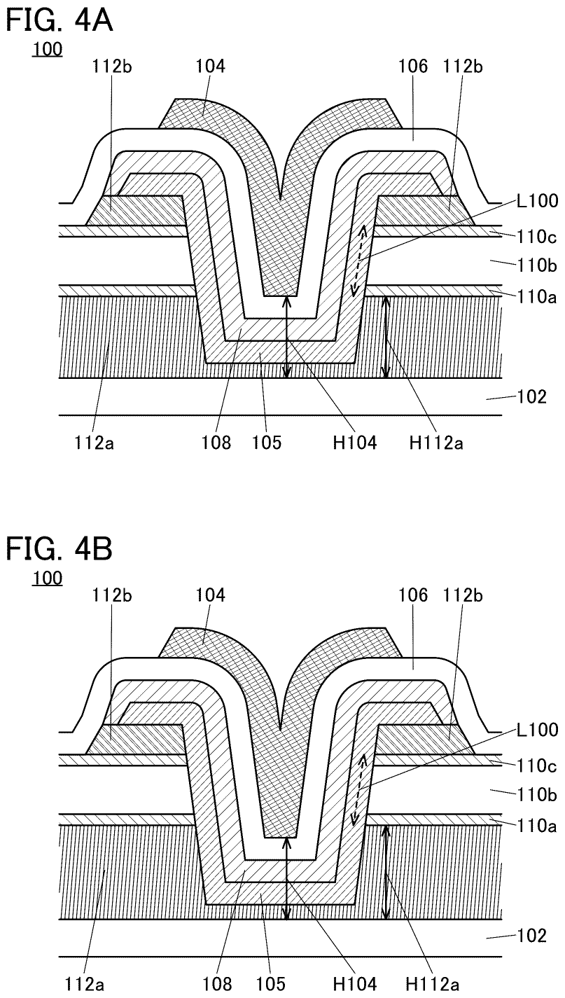

Note that FIG. 1B and the like illustrate the structure of the transistor 100 in which the thickness of the region in contact with the semiconductor layer 105 and the thickness of the region not in contact with the semiconductor layer 105 are equal to or substantially equal to each other in the conductive layer 112a; however, one embodiment of the present invention is not limited thereto. The thickness of the region in contact with the semiconductor layer 105 and the thickness of the region not in contact with the semiconductor layer 105 may be different from each other in the conductive layer 112a. As illustrated in FIG. 4A, the thickness of the region in contact with the semiconductor layer 105 is preferably smaller than the thickness of the region not in contact with the semiconductor layer 105 in the conductive layer 112a.

FIG. 4A shows a height H104 that is a distance from the formation surface of the conductive layer 112a (here, the top surface of the substrate 102) to the lowest position of the bottom surface of the conductive layer 104 (the surface on the insulating layer 106 side). FIG. 4A also illustrates a height H112a that is a distance from the formation surface of the conductive layer 112a (here, the top surface of the substrate 102) to the highest position of the region where the conductive layer 112a and the semiconductor layer 105 are in contact with each other. As illustrated in FIG. 4A, the height H104 is preferably equal to or substantially equal to the height H112a. Alternatively, as illustrated in FIG. 4B, the height H104 is preferably smaller (shorter) than the height H112a. When the height H104 is equal to or smaller (shorter) than the height H112a, the electric field of the gate electrode applied to the channel formation region in the vicinity of the conductive layer 112a can be increased, so that the on-state current of the transistor 100 can be increased.

When the height H104 is equal to or smaller (shorter) than the height H112a, the electric field of the gate electrode applied to the channel formation region can be more uniform. Here, in the case where the electric field of the gate electrode applied to the channel formation region is not uniform, the electrical characteristics in the case where the conductive layer 112a is the source electrode and the conductive layer 112b is the drain electrode and the electrical characteristics in the case where the conductive layer 112a is the drain electrode and the conductive layer 112b is the source electrode might be different from each other. By making the electric field of the gate electrode applied to the channel formation region of the transistor 100 more uniform, the electrical characteristics in the both cases can be made equivalent to each other. Thus, the transistor 100 can be suitably used in a circuit structure in which a source and a drain are interchanged with each other.

Note that the thickness of the conductive layer 112a is adjusted as appropriate so that the height H104 is equal to the height H112a or smaller (shorter) than the height H112a.

The above is the description of the components.

A structure example of a semiconductor device whose structure is partly different from that of <Structure example 1> shown above will be described below. Note that description of the same portions as those in <Structure example 1> shown above is omitted below in some cases. Furthermore, in drawings that are referred to later, the same hatching pattern is applied to portions having functions similar to those in <Structure example 1> shown above, and the portions are not denoted by reference numerals in some cases.

### Structure Example 2

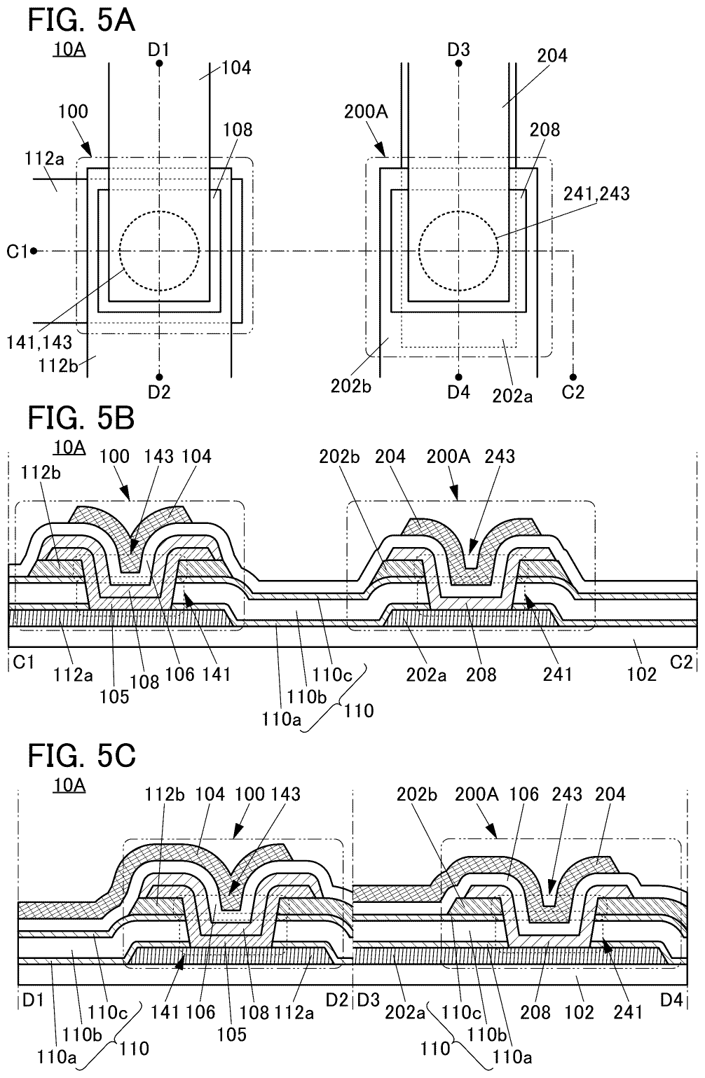

FIG. 5A is a plan view of a semiconductor device 10A. FIG. 5B is a cross-sectional view along the dashed-dotted line C1-C2 in FIG. 5A, and FIG. 5C is a cross-sectional view along the dashed-dotted line D1-D2 and the dashed-dotted line D3-D4 in FIG. 5A.

The semiconductor device 10A includes the transistor 100 and a transistor 200A. The transistor 200A is different from the transistor 200 (TGSA transistor) included in the semiconductor device 10 described in <Structure Example 1> shown above in being a vertical-channel transistor.

That is, the semiconductor device 10A is different from the semiconductor device 10 in that the transistor 100 and the transistor 200A are vertical-channel transistors.

The transistor 200A includes the conductive layer 204, the insulating layer 106, the semiconductor layer 208, the conductive layer 202a, the insulating layer 110 (the insulating layer 110a, the insulating layer 110b, and the insulating layer 110c), and a conductive layer 202b. The conductive layer 204 functions as a gate electrode. Part of the insulating layer 106 functions as a gate insulating layer. The conductive layer 202a functions as one of a source electrode and a drain electrode, and the conductive layer 202b functions as the other of the source electrode and the drain electrode. The insulating layer 110 functions as an interlayer film between the source electrode and the drain electrode. In the semiconductor layer 208 between the region in contact with the source electrode and the region in contact with the drain electrode, the whole region overlapping with the gate electrode with the gate insulating layer therebetween functions as a channel formation region. In the semiconductor layer 208, a region in contact with the source electrode functions as a source region, and a region in contact with the drain electrode functions as a drain region.

The conductive layer 202a is provided in a region over the substrate 102 and overlapping with the transistor 200A. The insulating layer 110 is provided over the conductive layer 202a. The conductive layer 202b is provided over the insulating layer 110. The insulating layer 110 includes a region interposed between the conductive layer 202a and the conductive layer 202b. The conductive layer 202a includes a region overlapping with the conductive layer 202b with the insulating layer 110 therebetween. The insulating layer 110 has an opening 241 in a region overlapping with the conductive layer 202a. The top surface of the conductive layer 202a is exposed in the opening 241. The conductive layer 202b includes an opening 243 in a region overlapping with the conductive layer 202a. The opening 243 is provided in a region overlapping with the opening 241.

The semiconductor layer 208 is provided to cover the opening 241 and the opening 243. The semiconductor layer 208 includes a region in contact with the top surface and the side surface of the conductive layer 202b, the side surface of the insulating layer 110, and the top surface of the conductive layer 202a. In the semiconductor layer 208, the whole region overlapping with the gate electrode with the gate insulating layer therebetween between the region in contact with the source electrode and the region in contact with the drain electrode functions as a channel formation region. The semiconductor layer 208 has a shape along the top surface and the side surface of the conductive layer 202b, the side surface of the insulating layer 110, and the top surface of the conductive layer 202a.

The transistor 200A is a vertical-channel transistor and has a structure similar to that of the transistor 100 except for including only one semiconductor layer. Thus, the description of the transistor 100 can also be applied to the transistor 200A other than the difference described above.

The description of <Structure example 1> can be referred to for the transistor 100; thus, the detailed description thereof is omitted.

As illustrated in FIG. 5A and FIG. 1A, the area occupied by the transistor 200A is smaller than the area occupied by the transistor 200 in the plan view. Thus, with the semiconductor device 10A including the transistor 100 and the transistor 200A, the area occupied by the whole semiconductor device can be smaller than the case of using the semiconductor device 10 including the transistor 100 and the transistor 200.

### Structure Example 3

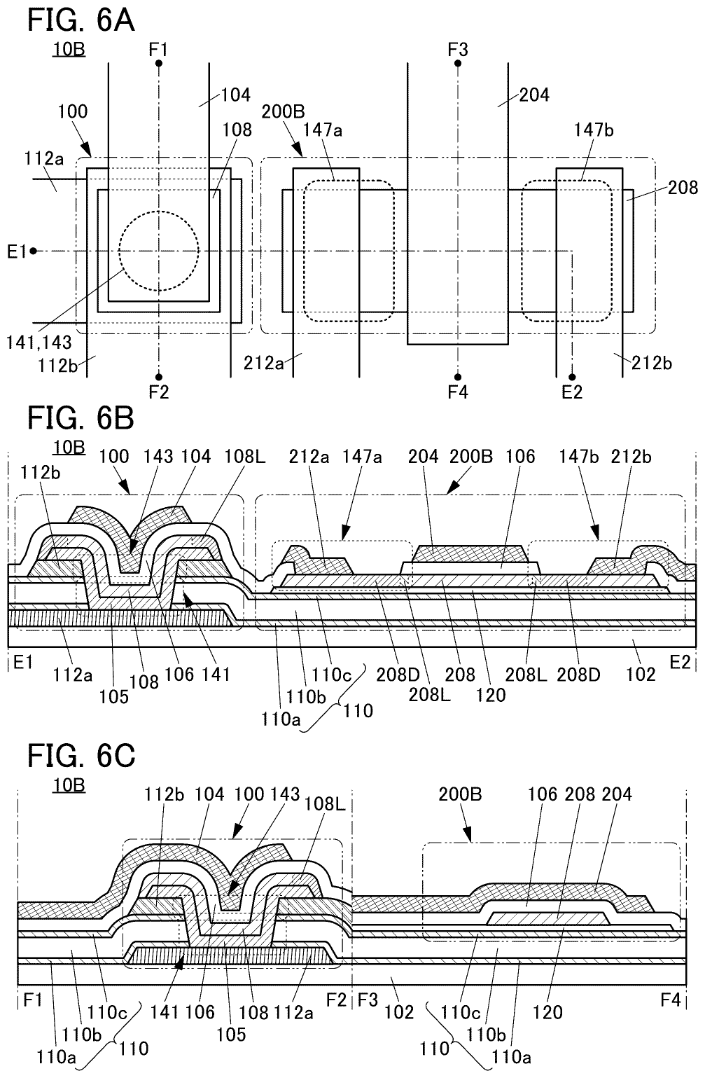

FIG. 6A is a plan view of a semiconductor device 10B. FIG. 6B is a cross-sectional view along the dashed-dotted line E1-E2 in FIG. 6A, and FIG. 6C is a cross-sectional view along the dashed-dotted line F1-F2 and the dashed-dotted line F3-F4 in FIG. 6A.

The semiconductor device 10B includes the transistor 100 and a transistor 200B. The transistor 200B is a TGSA transistor and different from the transistor 200 in not including the conductive layer 202a. The description of the transistor 200 can be referred to for the transistor 200B other than the difference described above.

The transistor 200B does not include the conductive layer 202a, which enables a structure body to be formed over the substrate 102 with high coverage as compared with the case of the transistor 200.

The description of <Structure example 1> can be referred to for the transistor 100; thus, the detailed description thereof is omitted.

### Structure Example 4

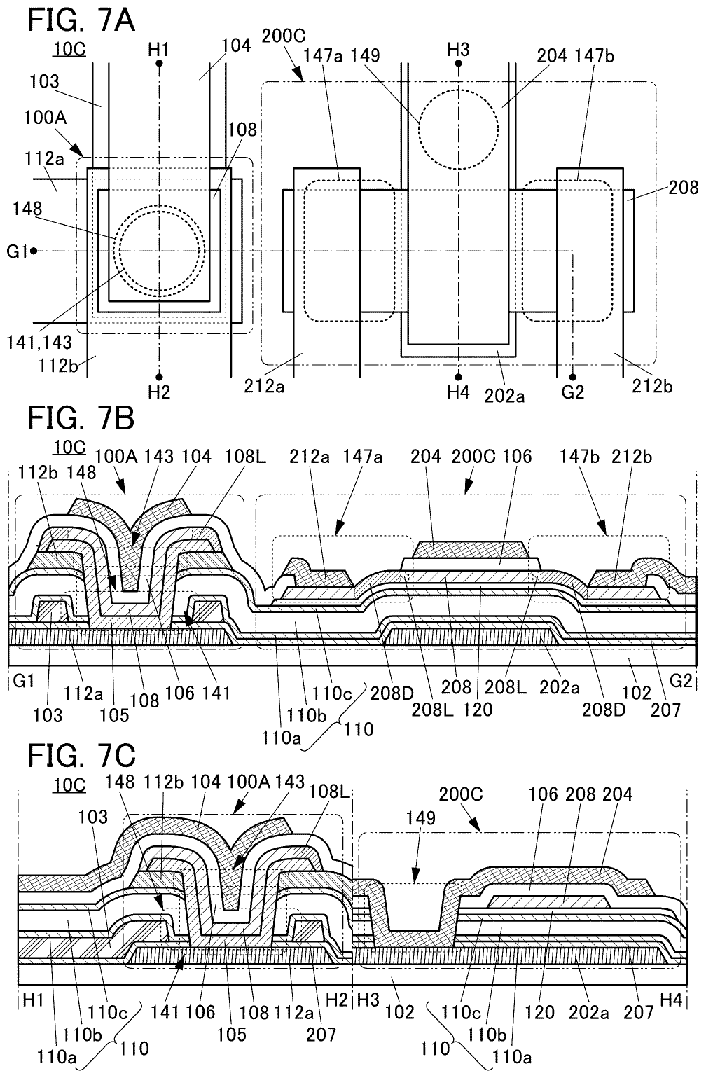

FIG. 7A is a plan view of a semiconductor device 10C. FIG. 7B is a cross-sectional view along the dashed-dotted line G1-G2 in FIG. 7A, and FIG. 7C is a cross-sectional view along the dashed-dotted line H1-H2 and the dashed-dotted line H3-H4 in FIG. 7A.

The semiconductor device 10C includes a transistor 100A and a transistor 200C. The transistor 100A is different from the transistor 100 in including an insulating layer 207 and a conductive layer 103 between the conductive layer 112a and the insulating layer 110a. The transistor 200C is different from the transistor 200 in including the insulating layer 207 between the conductive layer 202a and the insulating layer 110a.

The insulating layer 207 is provided to cover the top surface and the side surface of the conductive layer 112a, the top surface and the side surface of the conductive layer 202a, and the top surface of the substrate 102. The conductive layer 103 is provided in a region over the insulating layer 207 and overlapping with the conductive layer 112a. In the conductive layer 103, an opening 148 is provided in a region overlapping with the opening 141 and the opening 143. The insulating layer 110 is provided to cover the conductive layer 112a, the conductive layer 202a, the insulating layer 207, and the conductive layer 103.

In the transistor 100A, the conductive layer 103 has a function of a second gate electrode. Part of the insulating layer 110 (a region interposed between the semiconductor layer 105 and the conductive layer 103 in the plan view) functions as a second gate insulating layer. When the transistor 100A includes the conductive layer 103 having a function of the second gate electrode, electric fields can be applied to the semiconductor layer 105 and the semiconductor layer 108 from both the conductive layer 104 and the conductive layer 103, so that the controllability of carriers in the channel formation region can be increased. Thus, the transistor 100A can have higher saturation characteristics than the transistor 100.

The description of the transistor 100 and the transistor 200 can be referred to for the transistor 100A and the transistor 200C other than the points described above.

### Structure Example 5

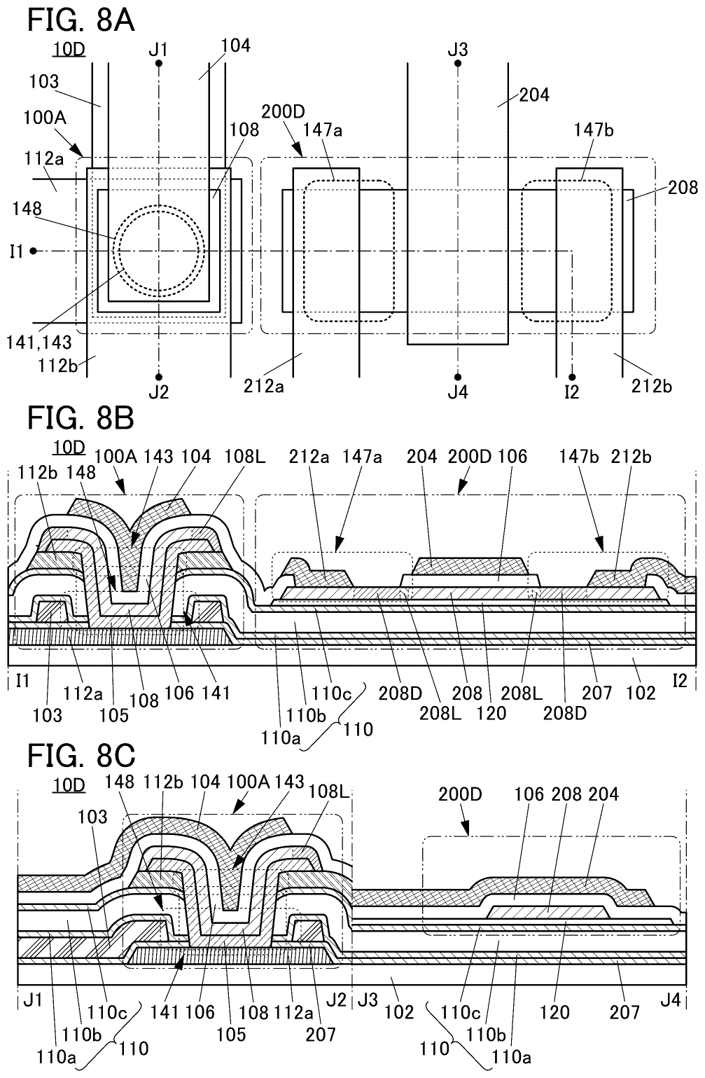

FIG. 8A is a plan view of a semiconductor device 10D. FIG. 8B is a cross-sectional view along the dashed-dotted line 11-12 in FIG. 8A, and FIG. 8C is a cross-sectional view along the dashed-dotted line J1-J2 and the dashed-dotted line J3-J4 in FIG. 8A.

The semiconductor device 10D includes the transistor 100A and a transistor 200D. The transistor 200D is different from the transistor 200B described in <Structure example 3> shown above in including the insulating layer 207.

The semiconductor device 10D including the transistor 100A and the transistor 200D can have both the effect obtained from the transistor 100A described in <Structure example 4> and the effect obtained from the transistor 200B described in <Structure example 3>.

### Structure Example 6

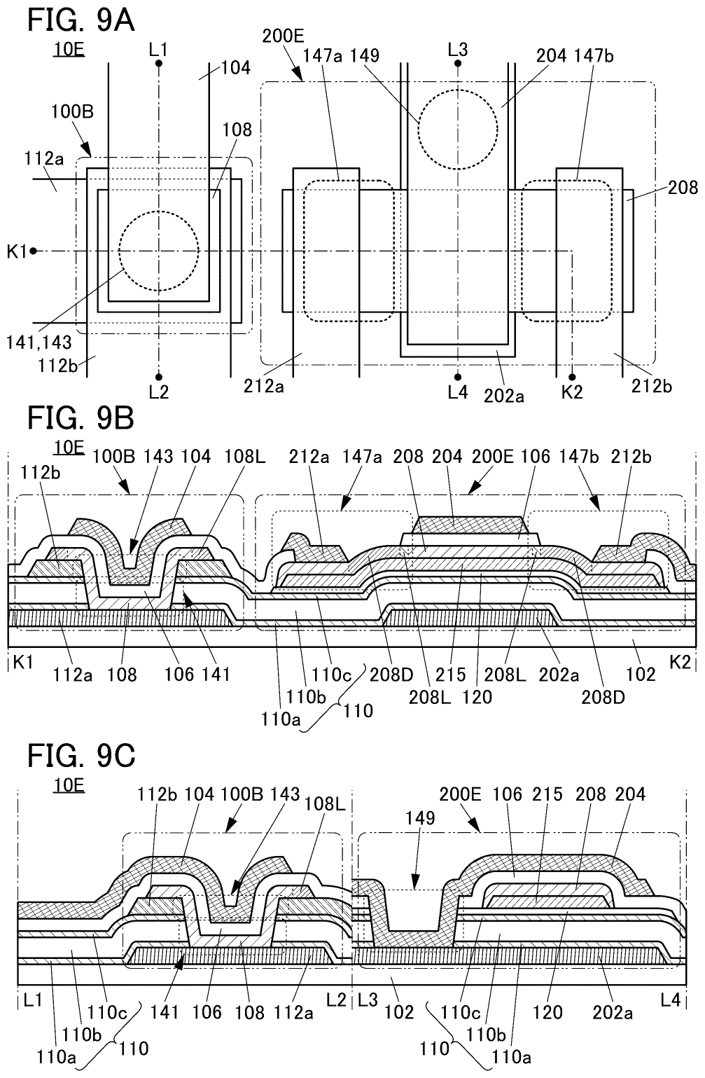

FIG. 9A is a plan view of a semiconductor device 10E. FIG. 9B is a cross-sectional view along the dashed-dotted line K1-K2 in FIG. 9A, and FIG. 9C is a cross-sectional view along the dashed-dotted line L1-L2 and the dashed-dotted line L3-L4 in FIG. 9A.

The semiconductor device 10E includes a transistor 100B and a transistor 200E. The transistor 100B is different from the transistor 100 in that only one semiconductor layer is included. The transistor 200E is different from the transistor 200 in including two semiconductor layers.

The transistor 100B includes only one semiconductor layer, the semiconductor layer 108. For other components, the description of the transistor 100 can be referred to.

The transistor 200E has a two-layer stacked structure of a semiconductor layer 215 and the semiconductor layer 208 over the semiconductor layer 215. For other components, the description of the transistor 200 can be referred to.

For the semiconductor layer 215, the same material as the material that can be used for the semiconductor layer 105 can be used, for example. For example, a material having a higher proportion of indium than that of the semiconductor layer 208 can be used for the semiconductor layer 215. The transistor 200 having the stacked-layer structure of the semiconductor layer 215 and the semiconductor layer 208 can achieve a higher on-state current than in the case where the transistor 200 includes only the semiconductor layer 208. Note that a material having a lower proportion of indium than that of the semiconductor layer 208 may be used for the semiconductor layer 215.

In the semiconductor device 10, the semiconductor layer of the vertical-channel transistor 100 has a two-layer stacked structure, and the semiconductor layer of the TGSA transistor 200 has a single-layer structure. In contrast, in the semiconductor device 10E, the semiconductor layer of the vertical-channel transistor 100B has a single-layer structure, and the semiconductor layer of the TGSA transistor 200E has a two-layer stacked structure. As described above, in the semiconductor device of one embodiment of the present invention, the structures of the semiconductor layers included in two transistors can be switched between the transistors.

### Structure Example 7

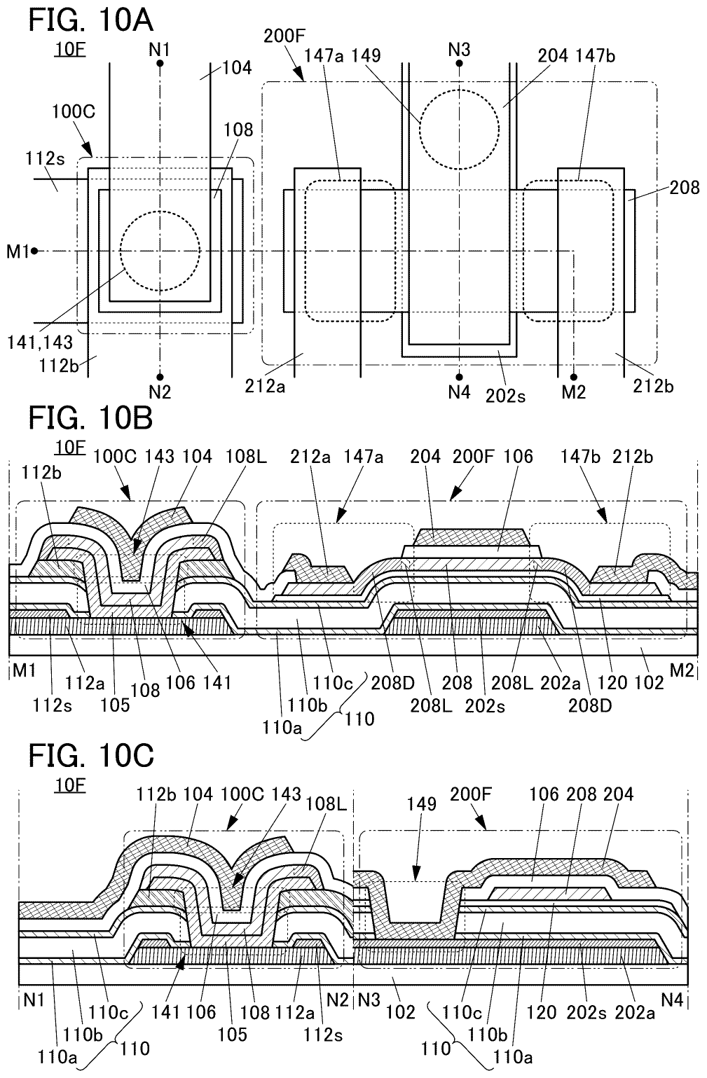

FIG. 10A is a plan view of a semiconductor device 10F. FIG. 10B is a cross-sectional view along the dashed-dotted line M1-M2 in FIG. 10A, and FIG. 10C is a cross-sectional view along the dashed-dotted line N1-N2 and the dashed-dotted line N3-N4 in FIG. 10A.

The semiconductor device 10F includes a transistor 100C and a transistor 200F. The transistor 100C is different from the transistor 100 in that a conductive layer 112s is provided over the conductive layer 112a. The transistor 200F is different from the transistor 200 in that a conductive layer 202s is provided over the conductive layer 202a.

The conductive layer 112s is provided over the conductive layer 112a so as to have an opening in a position overlapping with the opening 141 and the opening 143. The conductive layer 202s is provided over the conductive layer 202a. The insulating layer 110 is provided to cover the conductive layer 112a and the conductive layer 112s and the conductive layer 202a and the conductive layer 202s.

The conductive layer 112s and the conductive layer 202s can be formed using the same material and in the same step.

The conductive layer 112s and the conductive layer 202s are preferably formed using a material having lower resistance than that of the conductive layer 112a and the conductive layer 202a. Thus, a stack of the conductive layer 112a and the conductive layer 112s and a stack of the conductive layer 202a and the conductive layer 202s can be extended to be used as wirings.

The description of the transistor 100 and the transistor 200 can be referred to for the components of the transistor 100C and the transistor 200F other than the above.

### Structure Example 8

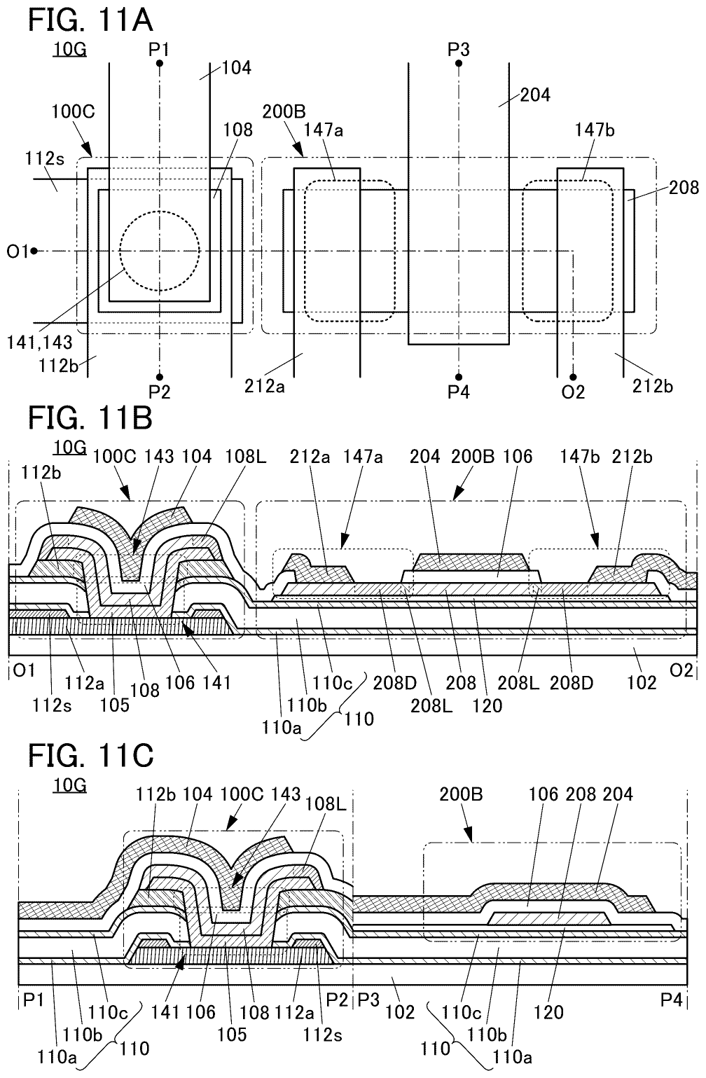

FIG. 11A is a plan view of a semiconductor device 10G. FIG. 11B is a cross-sectional view along the dashed-dotted line O1-O2 in FIG. 11A, and FIG. 11C is a cross-sectional view along the dashed-dotted line P1-P2 and the dashed-dotted line P3-P4 in FIG. 11A.

The semiconductor device 10G includes the transistor 100C described in <Structure example 7> and the transistor 200B described in <Structure example 3>.

The semiconductor device 10G including the transistor 100C and the transistor 200B can have both the effect obtained from the transistor 100C described in <Structure example 7> and the effect obtained from the transistor 200B described in <Structure example 3>.

### Structure Example 9

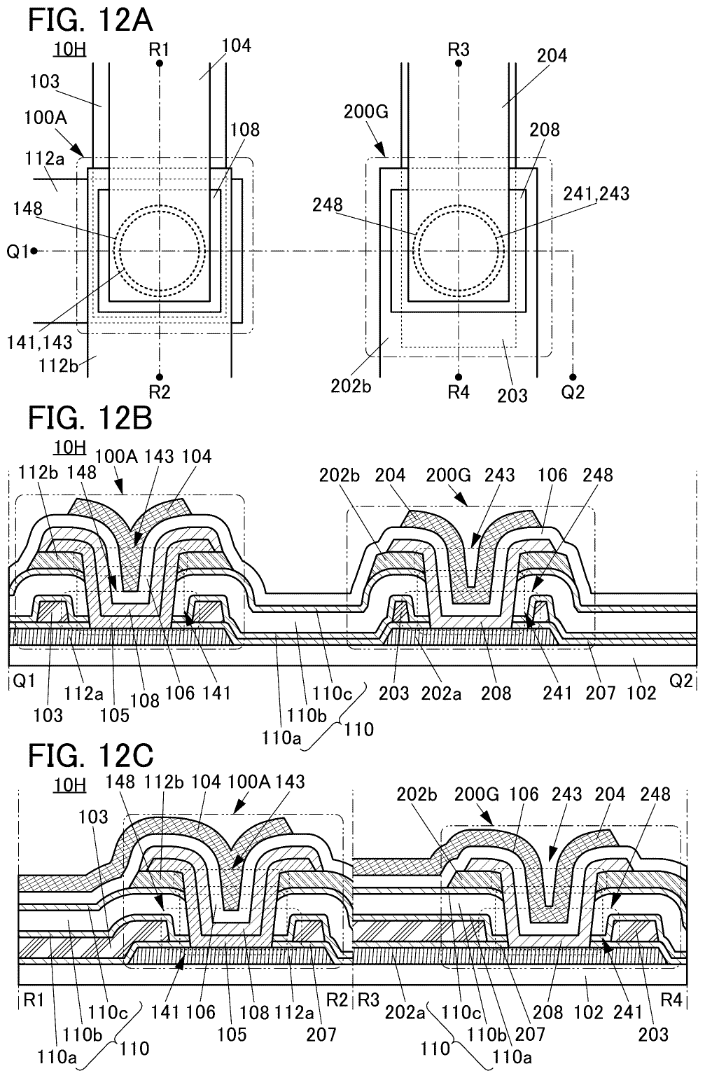

FIG. 12A is a plan view of a semiconductor device 10H. FIG. 12B is a cross-sectional view along the dashed-dotted line Q1-Q2 in FIG. 12A, and FIG. 12C is a cross-sectional view along the dashed-dotted line R1-R2 and the dashed-dotted line R3-R4 in FIG. 12A.

The semiconductor device 10H includes the transistor 100A described in <Structure example 4> and a transistor 200G. The transistor 200G is different from the transistor 200A described in <Structure example 2> in that the insulating layer 207 and a conductive layer 203 are provided between the conductive layer 202a and the insulating layer 110a.

The insulating layer 207 is provided to cover the top surface and the side surface of the conductive layer 112a, the top surface and the side surface of the conductive layer 202a, and the top surface of the substrate 102. The conductive layer 203 is provided in a region over the insulating layer 207 and overlapping with the conductive layer 202a. The conductive layer 203 and the conductive layer 103 can be formed using the same material and in the same step. In the conductive layer 203, an opening 248 is provided in a region overlapping with the opening 241 and the opening 243. The insulating layer 110 is provided to cover the conductive layer 112a, the conductive layer 103, the conductive layer 202a, the conductive layer 203, and the insulating layer 207.

In the transistor 200G, the conductive layer 203 has a function of a second gate electrode. Part of the insulating layer 110 (a region interposed between the semiconductor layer 208 and the conductive layer 203 in the plan view) functions as a second gate insulating layer. When the transistor 200G includes the conductive layer 203 having a function of the second gate electrode, an electric field can be applied to the semiconductor layer 208 from both the conductive layer 204 and the conductive layer 203, so that the controllability of carriers in the channel formation region can be increased. Thus, the transistor 200G can have higher saturation characteristics than the transistor 200A.

The semiconductor device 10H is similar to the semiconductor device 10A described in <Structure example 2> in that two transistors (the transistor 100A and the transistor 200G) included in the semiconductor device are vertical-channel transistors. However, the semiconductor device 10H is different from the semiconductor device 10A in that both the transistor 100A and the transistor 200G included in the semiconductor device 10H include the second gate electrode while either of two transistors (the transistor 100 and the transistor 200A) included in the semiconductor device 10A does not include the second gate electrode. Thus, the two transistors included in the semiconductor device 10H can have higher saturation characteristics than the two transistors included in the semiconductor device 10A.

### Structure Example 10

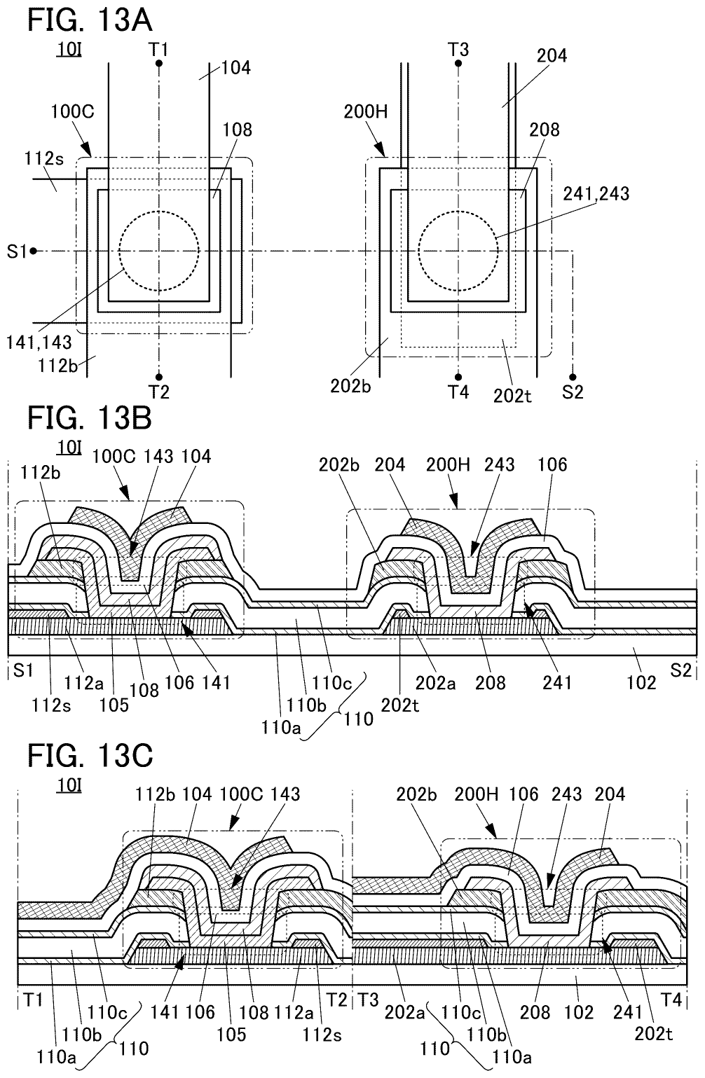

FIG. 13A is a plan view of a semiconductor device 10I. FIG. 13B is a cross-sectional view along the dashed-dotted line S1-S2 in FIG. 13A, and FIG. 13C is a cross-sectional view along the dashed-dotted line T1-T2 and the dashed-dotted line T3-T4 in FIG. 13A.

The semiconductor device 10I includes the transistor 100C described in <Structure example 7> and a transistor 200H. The transistor 200H is different from the transistor 200A described in <Structure example 2> in that a conductive layer 202t is provided over the conductive layer 202a.

The conductive layer 202t is provided over the conductive layer 202a so as to have an opening in a position overlapping with the opening 241 and the opening 243. The insulating layer 110 is provided to cover the conductive layer 112a and the conductive layer 112s and the conductive layer 202a and the conductive layer 202t.

The conductive layer 112s and the conductive layer 202t can be formed using the same material and in the same step.

The conductive layer 112s and the conductive layer 202t are preferably formed using a material having lower resistance than the conductive layer 112a and the conductive layer 202a. Thus, a stack of the conductive layer 112a and the conductive layer 112s and a stack of the conductive layer 202a and the conductive layer 202t can be extended to be used as wirings.

The semiconductor device 10I is similar to the semiconductor device 10A described in <Structure example 2> in that two transistors (the transistor 100C and the transistor 200H) included in the semiconductor device are each a vertical-channel transistor. However, the two transistors included in the semiconductor device 10I are different from the two transistors (the transistor 100 and the transistor 200A) included in the semiconductor device 10A in that the conductive layer 112s is provided over the conductive layer 112a functioning as one of the source electrode and the drain electrode of the transistor 100C and the conductive layer 202t is provided over the conductive layer 202a functioning as one of the source electrode and the drain electrode of the transistor 200H in the semiconductor device 10I. Thus, in the semiconductor device 10I, a stack of the conductive layer 112a and the conductive layer 112s and a stack of the conductive layer 202a and the conductive layer 202t can be extended to function as wirings.

This embodiment can be combined with any of the other embodiments or an example as appropriate. In this specification, in the case where a plurality of structure examples are shown in one embodiment, the structure examples can be combined as appropriate.

### Embodiment 2

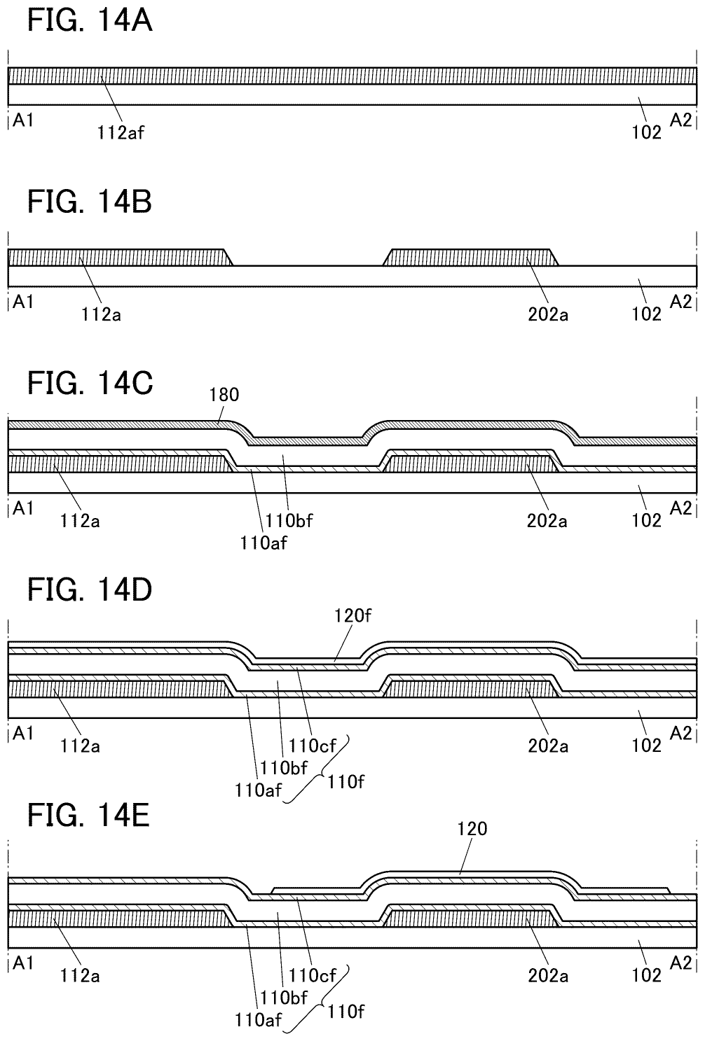

In this embodiment, a method for manufacturing a semiconductor device of one embodiment of the present invention will be described with reference to FIG. 14A to FIG. 22.

### Manufacturing Method Example 1

A method for manufacturing the semiconductor device of one embodiment of the present invention will be described below with reference to drawings. Here, for describing the manufacturing method, a structure in which an oxide semiconductor is used for each of the semiconductor layer 105, the semiconductor layer 108 and the semiconductor layer 208 of the semiconductor device 10 illustrated in FIG. 1B is used as an example.

Note that thin films that form the semiconductor device (insulating films, semiconductor films, conductive films, and the like) can be formed by a sputtering method, a chemical vapor deposition (CVD) method, a vacuum evaporation method, a pulse laser deposition (PLD) method, an ALD method, or the like. Examples of the CVD method include a plasma-enhanced chemical vapor deposition (PECVD) method and a thermal CVD method. An example of a thermal CVD method is a metal organic chemical vapor deposition (MOCVD) method.

The thin films that form the semiconductor device (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

When the thin films that form the semiconductor device are processed, a photolithography method or the like can be used. Alternatively, a nanoimprinting method, a sandblasting method, a lift-off method, or the like may be used for the processing of the thin films. Alternatively, island-shaped thin films may be directly formed by a film formation method using a blocking mask such as a metal mask.

There are the following two typical examples of a photolithography method. In one of the methods, a resist mask is formed over a thin film to be processed, the thin film is processed by etching or the like, and then the resist mask is removed. In the other method, a photosensitive thin film is formed and then processed into a desired shape by light exposure and development.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Ultraviolet rays, KrF laser light, ArF laser light, or the like can also be used. Light exposure may be performed by liquid immersion exposure technique. As the light used for light exposure, extreme ultraviolet (EUV) light or X-rays may also be used. Furthermore, instead of the light used for the light exposure, an electron beam can also be used. It is preferable to use extreme ultraviolet light, X-rays, or an electron beam because extremely minute processing is possible. Note that a photomask is not needed when light exposure is performed by scanning with a beam such as an electron beam. For etching of the thin film, a dry etching method, a wet etching method, or a sandblasting method can be used, for example.

Each of FIG. 14A to FIG. 18B is a diagram illustrating the method for manufacturing the semiconductor device 10. Each diagram is a cross-sectional view along the dashed-dotted line A1-A2.

[Formation of Conductive Layer 112a and Conductive Layer 202a]

A conductive film 112af to be the conductive layer 112a and the conductive layer 202a is formed over the substrate 102 (FIG. 14A). For the formation of the conductive film 112af, a sputtering method can be suitably used, for example.

Next, a resist mask (not illustrated) is formed over the conductive film 112af by a photolithography process, and then the conductive film 112af is processed, whereby the conductive layer 112a and the conductive layer 202a are formed (FIG. 14B). For processing of the conductive film 112af, one or both of a wet etching method and a dry etching method are used. Thus, the conductive layer 112a functioning as one of the source electrode and the drain electrode of the transistor 100 and the conductive layer 202a functioning as the second gate electrode of the transistor 200 are formed.

[Formation of Insulating Film 110af and Insulating Film 110bf]

Next, an insulating film 110af to be the insulating layer 110a and an insulating film 110bf to be the insulating layer 110b are formed in this order over the substrate 102, the conductive layer 112a, and the conductive layer 202a.

For the formation of the insulating film 110af and the insulating film 110bf, a PECVD method can be suitably used. It is preferable that the insulating film 110bf be formed in a vacuum successively after the formation of the insulating film 110af, without exposure of a surface of the insulating film 110af to the air. By forming the insulating film 110af and the insulating film 110bf successively, attachment of impurities derived from the air to the surface of the insulating film 110af can be inhibited. Examples of the impurities include water and organic substances.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af and the insulating film 110bf are in the above range, impurities (e.g., water and hydrogen) released from the insulating films themselves can be reduced, which inhibits diffusion of the impurities to the semiconductor layer formed later. Consequently, the transistor with favorable electrical characteristics and high reliability can be obtained.

Note that since the insulating film 110af and the insulating film 110bf are formed earlier than the semiconductor layer 105, the semiconductor layer 108, and the semiconductor layer 208, there is no need to consider the probability of oxygen release from the semiconductor layer 105, the semiconductor layer 108, and the semiconductor layer 208 due to heat applied thereto at the time of forming the insulating film 110af and the insulating film 110bf.

After the insulating film 110af and the insulating film 110bf are formed, heat treatment may be performed. By performing the heat treatment, water and hydrogen can be released from the surface and inside of each of the insulating film 110af and the insulating film 110bf.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating film 110af and the insulating film 110bf can be prevented as much as possible. An oven or a rapid thermal annealing (RTA) apparatus can be used for the heat treatment, for example. With the RTA apparatus, the heat treatment time can be shortened.

Next, a metal oxide layer 180 is formed over the insulating film 110bf (FIG. 14C).

The metal oxide layer 180 may be an insulating layer or a conductive layer. For the metal oxide layer 180, aluminum oxide, hafnium oxide, hafnium aluminate, indium oxide, indium tin oxide (ITO), or indium tin oxide containing silicon (ITSO) can be used, for example.

An oxide material containing one or more kinds of elements that are the same as those in the semiconductor layer 105, the semiconductor layer 108, or the semiconductor layer 208 is preferably used for the metal oxide layer 180. It is particularly preferable to use an oxide semiconductor material that can be used for the semiconductor layer 105, the semiconductor layer 108, or the semiconductor layer 208.

A metal oxide film formed using a sputtering target having the same composition as the semiconductor layer 105, the semiconductor layer 108, or the semiconductor layer 208 can be used as the metal oxide layer 180. The sputtering target having the same composition as the semiconductor layer 105, the semiconductor layer 108, or the semiconductor layer 208 is preferably used, in which case the same manufacturing apparatus and the same sputtering target can be used.

When a metal oxide material containing indium and gallium is used for each of the semiconductor layer 105, the semiconductor layer 108, the semiconductor layer 208, and the metal oxide layer 180, a material whose content percentage of gallium is higher than that in the semiconductor layer 105, the semiconductor layer 108, the semiconductor layer 208 can be used for the metal oxide layer 180. It is preferable to use a material whose content percentage of gallium is high for the metal oxide layer 180, in which case an oxygen blocking property can be further increased.

The metal oxide layer 180 is preferably formed in, for example, an oxygen-containing atmosphere. It is particularly preferable that the metal oxide layer 180 be formed by a sputtering method in an oxygen-containing atmosphere. In that case, oxygen can be suitably supplied to the insulating film 110bf at the time of forming the metal oxide layer 180.

For example, the metal oxide layer 180 may be formed by a reactive sputtering method using oxygen as a deposition gas and a metal target. When aluminum is used for the metal target, for example, an aluminum oxide film can be formed.

At the time of forming the metal oxide layer 180, the amount of oxygen supplied into the insulating film 110bf can be increased with a higher proportion of the oxygen flow rate to the total flow rate of the deposition gas introduced into a treatment chamber of a deposition apparatus (a higher oxygen flow rate ratio) or with a higher oxygen partial pressure in the treatment chamber. The oxygen flow rate ratio or the oxygen partial pressure is, for example, higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 180 is formed by a sputtering method in an oxygen-containing atmosphere in the above manner, oxygen can be supplied to the insulating film 110bf and release of oxygen from the insulating film 110bf can be prevented during the formation of the metal oxide layer 180. As a result, a large amount of oxygen can be enclosed in the insulating film 110bf. Moreover, a large amount of oxygen can be supplied to the semiconductor layer by heat treatment performed later. As a result, the amount of oxygen vacancies (Vo) and VoH in the semiconductor layer can be reduced, so that a highly reliable transistor exhibiting favorable electrical characteristics can be obtained.

After the metal oxide layer 180 is formed, heat treatment may be performed. The above description can be referred to for the heat treatment; thus, the detailed description thereof is omitted. By the heat treatment performed after the formation of the metal oxide layer 180, oxygen can be effectively supplied from the metal oxide layer 180 to the insulating film 110bf.

After the formation of the metal oxide layer 180 or after the above-described heat treatment, oxygen may be further supplied to the insulating film 110bf through the metal oxide layer 180. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of an apparatus in which a gas is made to be plasma by high-frequency power include a plasma etching apparatus and a plasma ashing apparatus.

Then, the metal oxide layer 180 is removed.

There is no particular limitation on a method for removing the metal oxide layer 180, and wet etching can be suitably used. With use of a wet etching method, the insulating film 110bf can be inhibited from being etched during the removal of the metal oxide layer 180. This can inhibit a reduction in the thickness of the insulating film 110bf and the thickness of the insulating layer 110b can be uniform.

The treatment for supplying oxygen to the insulating film 110bf is not necessarily performed in the above-described manner. For example, an oxygen radical, an oxygen atom, an oxygen atomic ion, an oxygen molecular ion, or the like is supplied to the insulating film 110bf by an ion doping method, an ion implantation method, plasma treatment, or the like. Alternatively, a film that inhibits oxygen release may be formed over the insulating film 110bf, and then oxygen may be supplied to the insulating film 110bf through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

[Formation of Insulating Film 110cf and Insulating Film 120f]

Next, an insulating film 110cf to be the insulating layer 110c and an insulating film 120f to be the insulating layer 120 are formed over the insulating film 110bf (FIG. 14D). The description related to the formation of the insulating film 110af and the insulating film 110bf can be referred to for the formation of the insulating film 110cf and the insulating film 120f; thus, the detailed description thereof is omitted.

Next, the insulating film 120f is processed to form the insulating layer 120 including a region overlapping with the conductive layer 202a (FIG. 14E). The insulating layer 120 is provided in a region where the semiconductor layer 208 is provided later. For the formation of the insulating layer 120, one or both of a wet etching method and a dry etching method can be used. In particular, a dry etching method can be suitably used.

[Formation of Conductive Film 112f]

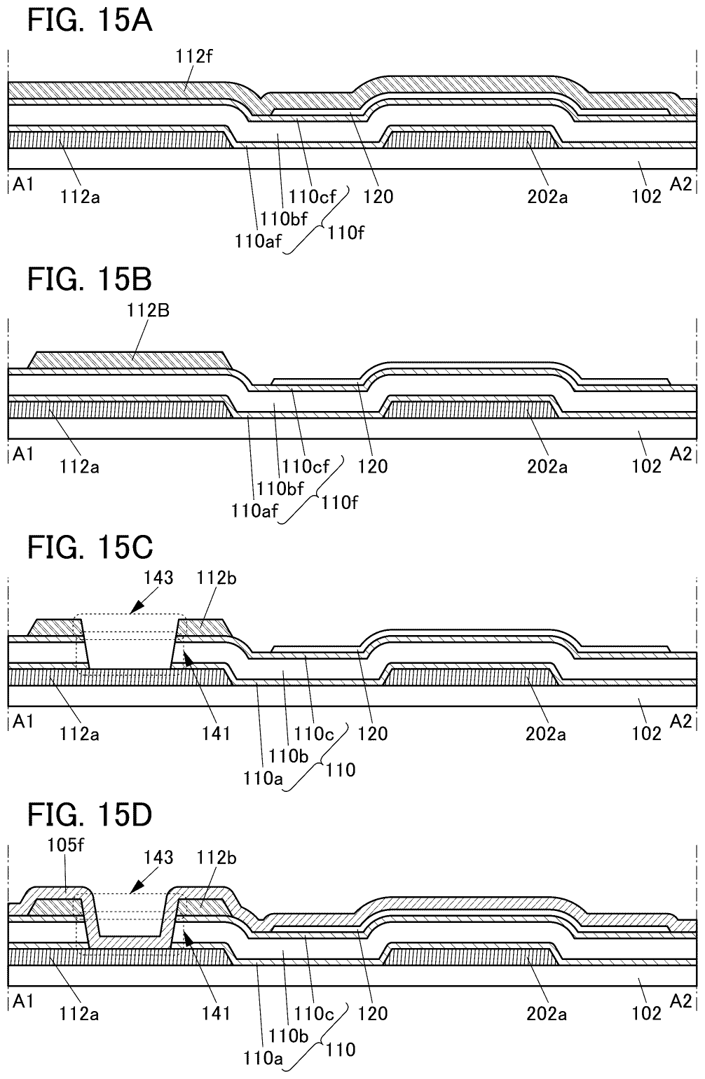

Then, a conductive film 112f to be the conductive layer 112b is formed over the insulating layer 120 and the insulating film 110cf (FIG. 15A). For the formation of the conductive film 112f, a sputtering method can be suitably used, for example.

### [Formation of Opening 141 and Opening 143]

Next, the conductive film 112f is processed to form a conductive layer 112B in a region overlapping with the conductive layer 112a (FIG. 15B). For the formation of the conductive layer 112B, one or both of a wet etching method and a dry etching method can be used. For the formation of the conductive layer 112B, a wet etching method can be suitably used, for example.

Next, the conductive layer 112B is partly removed to form the conductive layer 112b including the opening 143 (FIG. 15C). For the formation of the opening 143, one or both of a wet etching method and a dry etching method can be used. For the formation of the opening 143, a wet etching method can be suitably used, for example.

Next, an insulating film 110f (the insulating film 110af, the insulating film 110bf, and the insulating film 110cf) in the region overlapping with the opening 143 is removed to form the insulating layer 110 (the insulating layer 110a, the insulating layer 110b, and the insulating layer 110c) including the opening 141 (FIG. 15C). For the formation of the opening 141, one or both of a wet etching method and a dry etching method can be used. The opening 141 can be suitably formed by a dry etching method, for example. The conductive layer 112a is exposed in the opening 141.

The opening 141 can be formed using the resist mask (not illustrated) used for the formation of the opening 143, for example. Specifically, a resist mask is formed over the conductive layer 112B, the conductive layer 112B is partly removed with use of the resist mask to form the opening 143, and the insulating film 110f is partly removed with use of the resist mask, whereby the opening 141 can be formed. The opening 141 may be formed using a resist mask that is different from the resist mask used for the formation of the opening 143.

Note that in the formation of the opening 141 or after the formation of the opening 141, part of the conductive layer 112a in a region overlapping with the opening 141 may be removed. By removing part of the conductive layer 112a, the structure illustrated in FIG. 4A and FIG. 4B can be obtained.

### [Formation of Semiconductor Layer 105]

Subsequently, a metal oxide film 105f to be the semiconductor layer 105 is formed to cover the opening 141 and the opening 143 (FIG. 15D). The metal oxide film 105f is provided in contact with the top surface and the side surface of the insulating layer 120, the top surface and the side surface of the conductive layer 112b, the top surface and the side surface of the insulating layer 110, and the top surface of the conductive layer 112a.

The metal oxide film 105f is preferably formed by a sputtering method using a metal oxide target.

The metal oxide film 105f is preferably a dense film with as few defects as possible. The metal oxide film 105f is preferably a highly purified film in which impurities containing hydrogen elements are reduced as much as possible. It is particularly preferable to use a metal oxide film having crystallinity as the metal oxide film 105f.

In forming the metal oxide film 105f, an oxygen gas is preferably used. In the case of using an oxygen gas at the time of forming the metal oxide film 105f, oxygen can be suitably supplied into the insulating layer 120 and the insulating layer 110. For example, in the case of using an oxide for the insulating layer 120, oxygen can be suitably supplied into the insulating layer 120. Similarly, in the case where an oxide is used for the insulating layer 110b, oxygen can be suitably supplied into the insulating layer 110b.

By the supply of oxygen to the insulating layer 120 and the insulating layer 110b, oxygen is supplied to the semiconductor layer 105, the semiconductor layer 108, and the semiconductor layer 208 in a later step, so that oxygen vacancies (Vo) and VoH in the semiconductor layer 105, the semiconductor layer 108, and the semiconductor layer 208 can be reduced.

In forming the metal oxide film 105f, an oxygen gas and an inert gas (such as a helium gas, an argon gas, or a xenon gas) may be mixed. Note that when the proportion of an oxygen gas in the whole film formation gas (an oxygen flow rate ratio) at the time of forming the metal oxide film 105f is higher, the crystallinity of the metal oxide film 105f can be higher and a transistor with higher reliability can be obtained. By contrast, the lower the oxygen flow rate ratio is, the lower the crystallinity of the metal oxide film 105f is, offering the transistor with a high on-state current. For example, with the use of different oxygen flow rate ratios, a stacked-layer structure of two or more metal oxide layers having different crystallinities can be formed.

In forming the metal oxide film 105f, as the substrate temperature is higher, a denser metal oxide film having higher crystallinity can be formed. On the other hand, as the substrate temperature becomes lower, a metal oxide film having lower crystallinity and higher electric conductivity can be formed.

The metal oxide film 105f is formed at a substrate temperature higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than 140° C., high productivity is achieved, which is preferable. When the metal oxide film 105f is formed at a substrate temperature set to room temperature or without heating the substrate, the metal oxide film 105f can have low crystallinity.

In the case of employing an ALD method for the formation of the metal oxide film 105f, a film formation method such as a thermal ALD method or PEALD (plasma enhanced ALD) method is preferably employed. The thermal ALD method is preferable because of its capability of forming a film with extremely high step coverage. The PEALD method is preferable because of its capability of forming a film at low temperatures, in addition to its capability of forming a film with high step coverage.

For example, the metal oxide film can be formed by an ALD method using a precursor containing a metal element that is a component of the metal oxide film and an oxidizer.

For example, in the case where an In—Ga—Zn oxide is formed, three precursors of a precursor including indium, a precursor including gallium, and a precursor including zinc can be used. Alternatively, two precursors of a precursor containing indium and a precursor containing gallium and zinc may be used.

Examples of the precursor including indium include trimethylindium, tris(2,2,6,6-tetramethyl-3,5-heptanedionato)indium, cyclopentadienylindium, indium(III) chloride, and (3-(dimethylamino)propyl)dimethylindium.

As examples of the precursor containing gallium, trimethylgallium, triethylgallium, gallium trichloride, tris(dimethylamido)gallium, gallium(III) acetylacetonate, tris(2,2,6,6-tetramethyl-3,5-heptanedionato)gallium, dimethylchlorogallium, diethylchlorogallium, and gallium(III) chloride can be given.

Examples of the precursor including zinc include dimethylzinc, diethylzinc, bis(2,2,6,6-tetramethyl-3,5-heptanedionato)zinc, and zinc chloride.

As examples of the oxidizing agent, ozone, oxygen, and water can be given.

As a method for controlling the composition of a film to be obtained, adjusting one or more of the kinds of source gases, the flow rate ratio of source gases, the flowing time of the source gases, and the order in which the source gases flow is given. Moreover, by adjusting these, a film whose composition is continuously changed can be formed. Furthermore, films having different compositions can be formed successively.

In the case where the semiconductor layer 105 has a stacked-layer structure, an upper metal oxide film is preferably formed successively after the formation of a lower metal oxide film without exposure of a surface of the lower metal oxide film to the air.

It is preferable to perform at least one of treatment for desorbing impurities (e.g., water, hydrogen, an organic substance) adsorbed onto the surface of the insulating layer 120 and the surface of the insulating layer 110 and treatment for supplying oxygen into the insulating layer 120 and the insulating layer 110 before the formation of the metal oxide film 105f. For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 120 and the insulating layer 110 by plasma treatment in an atmosphere containing an oxidizing gas such as dinitrogen monoxide (N₂O). Performing plasma treatment containing a dinitrogen monoxide gas can supply oxygen while suitably removing the impurities on the surface of the insulating layer 120 and the surface of the insulating layer 110.

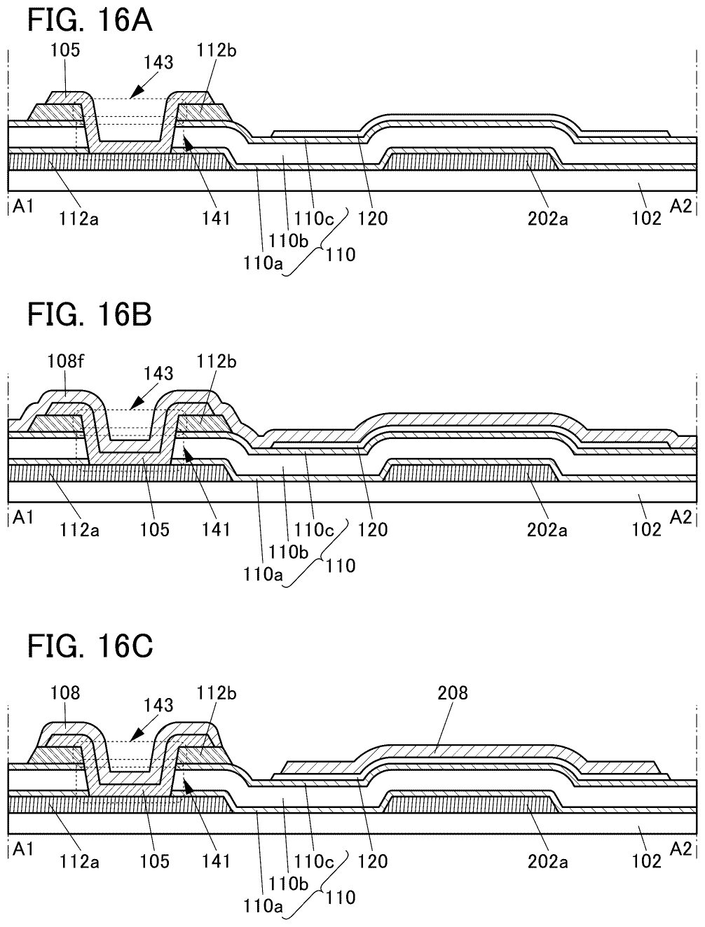

Next, the metal oxide film 105f is processed into an island shape to form the semiconductor layer 105 (FIG. 16A). The semiconductor layer 105 is formed to include a region in contact with the top surface of the conductive layer 112a, the side surface of the insulating layer 110, and the side surface and the top surface of the conductive layer 112b.

For the formation of the semiconductor layer 105, one or both of a wet etching method and a dry etching method can be used. For example, a wet etching method can be suitably used to form the semiconductor layer 105. At this time, part of the conductive layer 112b in the region that does not overlap with the semiconductor layer 105 is etched and thinned in some cases. Similarly, the insulating layer 120 is etched to have a small thickness in some cases. The insulating layer 110 (specifically, the insulating layer 110c) in a region not overlapping with the conductive layer 112b or the insulating layer 120 is partly etched and thinned in some cases. Note that in the etching of the metal oxide film 105f, the reduction in the thickness of the insulating layer 110c can be inhibited when a material having a high etching selectivity is used for the insulating layer 110c.

It is preferable that heat treatment be performed after the metal oxide film 105f is formed or the metal oxide film 105f is processed into the semiconductor layer 105. By the heat treatment, hydrogen and water contained in the metal oxide film 105f or the semiconductor layer 105 or adsorbed on a surface of the metal oxide film 105f or the semiconductor layer 105 can be removed. Furthermore, the film quality of the metal oxide film 105f or the semiconductor layer 105 is improved (e.g., the number of defects is reduced or crystallinity is increased) by the heat treatment in some cases.

Oxygen can be supplied from the insulating layer 110 to the metal oxide film 105f or the semiconductor layer 105 by the heat treatment. In this case, it is further preferable that the heat treatment be performed before the semiconductor film 105f is processed into the semiconductor layer 105. The above description can be referred to for the heat treatment; thus, the detailed description thereof is omitted.

Note that the heat treatment is not necessarily performed. The heat treatment is not necessarily performed in this step, and heat treatment performed in a later step may also serve as the heat treatment in this step. In some cases, treatment at a high temperature (e.g., film formation step) or the like in a later step can serve as the heat treatment in this step.

### [Formation of the Semiconductor Layer 108 and Semiconductor Layer 208]

Next, a metal oxide film 108f to be the semiconductor layer 108 and the semiconductor layer 208 is formed to cover the semiconductor layer 105, the conductive layer 112b, the insulating layer 120, and the insulating layer 110 (FIG. 16B). The metal oxide film 108f is provided in contact with the top surface and the side surface of the semiconductor layer 105, the top surface and the side surface of the conductive layer 112b, the top surface and the side surface of the insulating layer 120, and the top surface of the insulating layer 110.

The metal oxide film 108f is formed using a material with a composition, crystallinity, or the like which is different from that of the semiconductor layer 105. For the details of the method for forming the metal oxide film 108f and the heat treatment for the metal oxide film 108f, the above-described method for forming the metal oxide film 105f and the description that can be used for the heat treatment for the metal oxide film 105f can be referred to.

Next, the metal oxide film 108f is processed into an island shape to form the semiconductor layer 108 and the semiconductor layer 208 (FIG. 16C). The semiconductor layer 108 is formed to include a region overlapping with the semiconductor layer 105. The semiconductor layer 208 is provided to include a region overlapping with the conductive layer 202a and the insulating layer 120.

The above-described method for forming the semiconductor layer 105 and the description that can be used for the heat treatment for the semiconductor layer 105 can be used for the formation method of the semiconductor layer 108 and the semiconductor layer 208 and the details of the heat treatment for the semiconductor layer 108 and the semiconductor layer 208.

The semiconductor layer 108 is a semiconductor layer functioning the channel formation region of the transistor 100. The semiconductor layer 208 is a semiconductor layer functioning as the channel formation region of the transistor 200. When the metal oxide film 108f is processed into an island shape as described above, the semiconductor layer 108 and the semiconductor layer 208 functioning as channel formation regions of different transistors can be formed at the same time. Thus, the number of masks needed for processing the semiconductor layer can be smaller than that in the case where the semiconductor layer of the transistor 100 and the semiconductor layer of the transistor 200 are formed in different steps. Furthermore, the total number of steps can be reduced.

### [Formation of Insulating Layer 106]

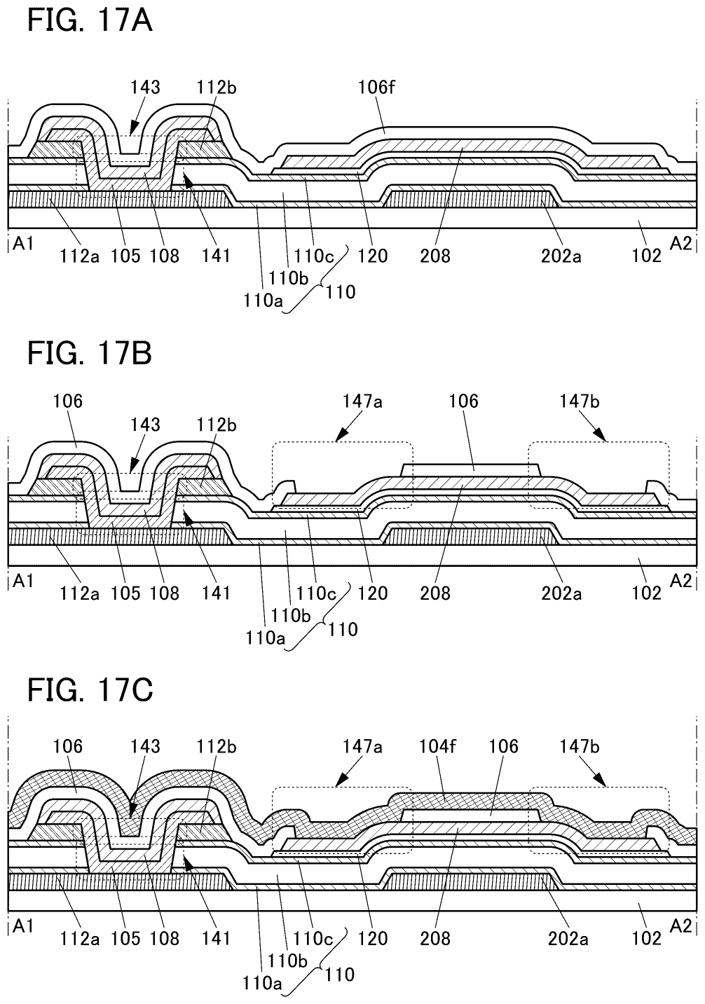

Next, an insulating film 106f to be the insulating layer 106 is formed to cover the semiconductor layer 105, the semiconductor layer 108, the conductive layer 112b, the semiconductor layer 208, the insulating layer 120, and the insulating layer 110 (FIG. 17A). For formation of the insulating film 106f, a PECVD method or an ALD method can be suitably used, for example.

In the case of using an oxide semiconductor for the insulating layer 108 and the semiconductor layer 208, the insulating layer 106 preferably functions as a barrier film that inhibits diffusion of oxygen. When the insulating layer 106 has a function of inhibiting diffusion of oxygen, oxygen contained in the semiconductor layer 108 and the semiconductor layer 208 is inhibited from diffusing into the conductive layer 104 and the conductive layer 204, respectively, through the insulating layer 106, so that oxidation of the conductive layer 104 and the conductive layer 204 can be inhibited. Consequently, the transistor 100 and the transistor 200 can have favorable electrical characteristics and high reliability.

Note that in this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

By increasing the temperature at the time of forming the insulating film 106f to be the gate insulating layer (the insulating layer 106) of each of the transistor 100 and the transistor 200, the insulating layer 106 including a small number of defects can be obtained. However, the high temperature at the time of forming the insulating film 106f sometimes allows release of oxygen from the semiconductor layer 105, the semiconductor layer 108, and the semiconductor layer 208, which increases the amount of oxygen vacancies (Vo) and VoH in the semiconductor layer 105, the semiconductor layer 108, and the semiconductor layer 208 in some cases. The substrate temperature at the time of forming the insulating film 106f is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating film 106f is in the above range, release of oxygen from the semiconductor layer 105, the semiconductor layer 108, and the semiconductor layer 208 can be inhibited while the defects in the insulating layer 106 can be reduced. Consequently, the transistor 100 and the transistor 200 can have favorable electrical characteristics and high reliability.

It is preferable to perform plasma treatment on the surface of the semiconductor layer 108 and the surface of the semiconductor layer 208 before the formation of the insulating film 106f. By the plasma treatment, impurities (e.g., water) adsorbed onto the surfaces of the semiconductor layer 108 and the semiconductor layer 208 can be reduced. Therefore, impurities at the interface between the semiconductor layer 108 and the insulating layer 106 and the interface between the semiconductor layer 208 and the insulating layer 106 can be reduced, achieving a highly reliable transistor. The plasma treatment is particularly suitable in the case where the surfaces of the semiconductor layer 108 and the semiconductor layer 208 are exposed to the air after the formation of the semiconductor layer 108 and the semiconductor layer 208 and before the formation of the insulating film 106f. For example, plasma treatment can be performed in an atmosphere containing one or more of oxygen, ozone, nitrogen, dinitrogen monoxide, and argon. The plasma treatment and the formation of the insulating film 106f are preferably performed successively without exposure to the air.

Next, the insulating film 106f is processed to form the insulating layer 106 (FIG. 17B). The insulating layer 106 is provided to include a region overlapping with the conductive layer 112a, the semiconductor layer 105, the semiconductor layer 108, and the conductive layer 112b. The insulating layer 106 is provided to include a region overlapping with the conductive layer 202a and the semiconductor layer 208. The opening 147a and the opening 147b reaching the semiconductor layer 208 are provided in the insulating layer 106. For the formation of the insulating layer 106, one or both of a wet etching method and a dry etching method can be used. In particular, a dry etching method can be suitably used.

[Formation of Conductive Layer 104, Conductive Layer 204, Conductive Layer 212a, and Conductive Layer 212b]

Next, a conductive film 104f to be the conductive layer 104, the conductive layer 204, the conductive layer 212a, and the conductive layer 212b is formed over the insulating layer 106, and the semiconductor layer 208 (FIG. 17C). For the formation of the conductive film 104f, a sputtering method can be suitably used, for example.

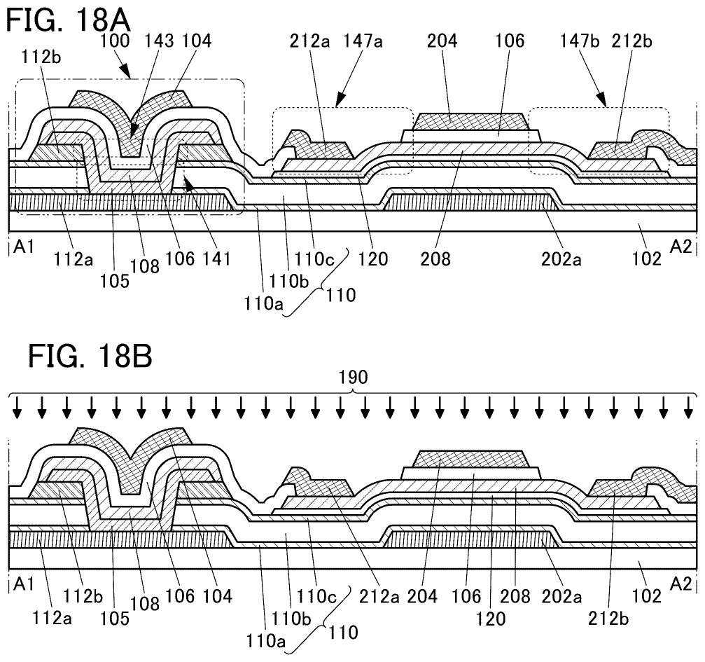

Next, after a resist mask (not illustrated) is formed over the conductive film 104f by a photolithography process, the conductive film 104f is processed, whereby the conductive layer 104 (functioning as the gate electrode of the transistor 100) overlapping with the semiconductor layer 105 and the semiconductor layer 108, the conductive layer 204 (functioning as the first gate electrode of the transistor 200) overlapping with the conductive layer 202a, and the conductive layer 212a (functioning as one of the source electrode and the drain electrode of the transistor 200) and the conductive layer 212b (functioning as the other of the source electrode and the drain electrode of the transistor 200) that are in contact with the top surface of the semiconductor layer 208 with the conductive layer 204 therebetween are formed (FIG. 18A). For processing of the conductive film 104f, one or both a wet etching method and a dry etching method can be used. Note that by the processing, the thickness of the insulating layer 106 in a portion not overlapping with the conductive layer 104, the conductive layer 212a, or the conductive layer 212b is sometimes smaller than the thickness of the other portion. Similarly, the thickness of the insulating layer 106 in a portion not overlapping with the conductive layer 204 is smaller than the thickness of the portion overlapping with the conductive layer 204 in some cases.

Through the above steps, the transistor 100 can be manufactured.

### [Formation of Region 208L and Region 208D]

Next, treatment for supplying (adding or injecting) an impurity 190 to the semiconductor layer 208 is performed with the use of the conductive layer 204 as a mask (FIG. 18B). Thus, the regions 208D are formed in regions of the semiconductor layer 208 that overlaps with none of the conductive layer 204, the conductive layer 212a, and the conductive layer 212b, and the insulating layer 106, and the regions 208L are formed in regions of the semiconductor layer 208 that overlaps with none of the conductive layer 204, the conductive layer 212a, and the conductive layer 212b and overlaps with the insulating layer 106 (FIG. 1B). At this time, the conditions for supplying the impurity 190 are preferably determined in consideration of the material and thickness of the conductive layer 204 serving as the mask so that the impurity 190 is supplied as little as possible to the region of the semiconductor layer 208 overlapping with the conductive layer 204. Thus, a channel formation region with a sufficiently reduced impurity concentration can be formed in the region of the semiconductor layer 208 overlapping with the conductive layer 204. Similarly, the semiconductor layer 108 may be supplied with an impurity using the conductive layer 104 as a mask. The regions 108L are formed in a region of the semiconductor layer 108 that does not overlap with the conductive layer 104 and overlaps with the insulating layer 106 (FIG. 1B).

A plasma ion doping method or an ion implantation method can be suitably used for the supply of the impurity 190. In these methods, the concentration profile in the depth direction can be controlled with high accuracy by the acceleration voltage and the dosage of ions, or the like. The use of a plasma ion doping method can increase productivity. In addition, the use of an ion implantation method with mass separation can increase the purity of the impurity 190 to be supplied.

The conditions for supplying the impurity 190 are preferably adjusted so that the impurity concentration at the surface or a portion closer to the surface of the semiconductor layer 208 is the highest.

As a source material of the impurity 190, the gas containing an impurity element described in Embodiment 1 can be used, for example. In the case where boron is supplied as the impurity 190, typically, one or more of a B₂H₆ gas and a BF₃ gas can be used. In the case where phosphorus is supplied as the impurity 190, typically, a PH₃ gas can be used. A mixed gas in which any of these source gases is diluted with a noble gas may be used.

For example, any of CH₄, N₂, NH₃, AlH₃, AlCl₃, SiH₄, Si₂H₆, F₂, HF, H₂, (C₅H₅)₂Mg, a noble gas, and the like can be used as the source material of the impurity 190. Note that the source material is not limited to a gas, and a solid or liquid may be heated and vaporized.

Addition of the impurity 190 can be controlled by setting the conditions such as the acceleration voltage and the dosage in consideration of the compositions, densities, thicknesses, and the like of the insulating layer 106 and the semiconductor layer 208.

For example, in the case where boron is added by an ion implantation method or a plasma ion doping method, the acceleration voltage can be, for example, higher than or equal to 5 kV and lower than or equal to 100 kV, preferably higher than or equal to 7 kV and lower than or equal to 70 kV, further preferably higher than or equal to 10 kV and lower than or equal to 50 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

In the case where phosphorus ions are added by an ion implantation method or a plasma ion doping method, the acceleration voltage can be, for example, higher than or equal to 10 kV and lower than or equal to 100 kV, preferably higher than or equal to 30 kV and lower than or equal to 90 kV, further preferably higher than or equal to 40 kV and lower than or equal to 80 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

Note that a method for supplying the impurity 190 is not limited thereto; plasma treatment, treatment using thermal diffusion by heating, or the like may be used, for example. In a plasma treatment method, plasma is generated in a gas atmosphere containing the impurity 190 to be added and plasma treatment is performed, so that the impurity 190 can be added. A dry etching apparatus, an ashing apparatus, a plasma CVD apparatus, a high-density plasma CVD apparatus, or the like can be used as an apparatus for generating the plasma.

Through the above process, the transistor 200 can be manufactured.

Through the above process, the semiconductor device 10 can be manufactured (FIG. 1B).

### Manufacturing Method Example 2

For describing the manufacturing method, a structure in which an oxide semiconductor is used for each of the semiconductor layer 105, the semiconductor layer 108, and the semiconductor layer 208 of the semiconductor device 10A illustrated in FIG. 5B is used as an example below.

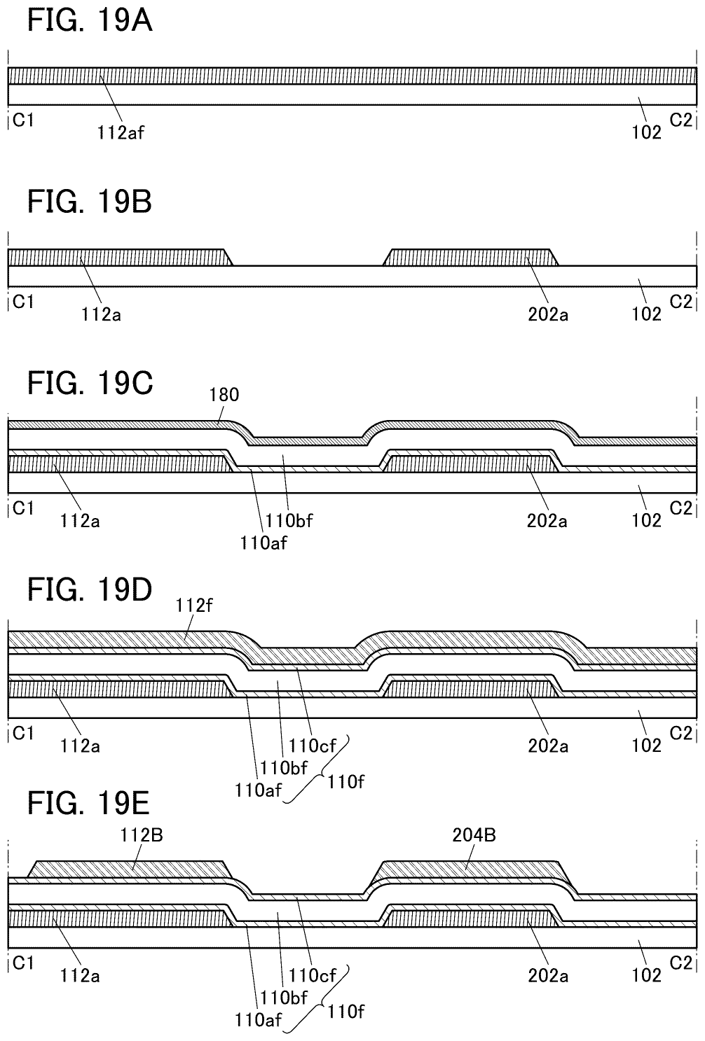

Each of FIG. 19A to FIG. 22 is a drawing illustrating the method for manufacturing the semiconductor device 10A. Each diagram is a cross-sectional view along the dashed-dotted line C1-C2.

The steps from the formation of the conductive film 112af to the formation and removal of the metal oxide layer 180 (FIG. 19A to FIG. 19C) are similar to the manufacturing method in <Manufacturing method example 1> described above. Thus, for this step, the description of the manufacturing method of the semiconductor device 10 related to FIG. 14A to FIG. 14C can be referred to.

[Formation of Insulating Film 110cf]

Next, the insulating film 110cf to be the insulating layer 110c is formed over the insulating film 110bf (FIG. 19D). For the formation of the insulating film 110cf, the description related to the formation of the insulating film 110cf (FIG. 14D) shown in <Manufacturing method example 1> can be referred to.

[Formation of Conductive Film 112f]

Then, the conductive film 112f to be the conductive layer 112b is formed over the insulating film 110cf (FIG. 19D). For the formation of the conductive film 112f, the description related to the formation of the conductive film 112f (FIG. 15A) shown in <Manufacturing method example 1> can be referred to.

### [Formation of Opening 141, Opening 143, Opening 241, the Opening 243]

Next, the conductive film 112f is processed to form the conductive layer 112B in a region overlapping with the conductive layer 112a and a conductive layer 204B in a region overlapping with the conductive layer 202a (FIG. 19E). For the formation of the conductive layer 112B, the description related to the formation of the conductive layer 112B (FIG. 15B) shown in <Manufacturing method example 1> can be referred to. The conductive layer 204B can be formed at the same time as the conductive layer 112B by employing the same formation conditions as those for the conductive layer 112B.

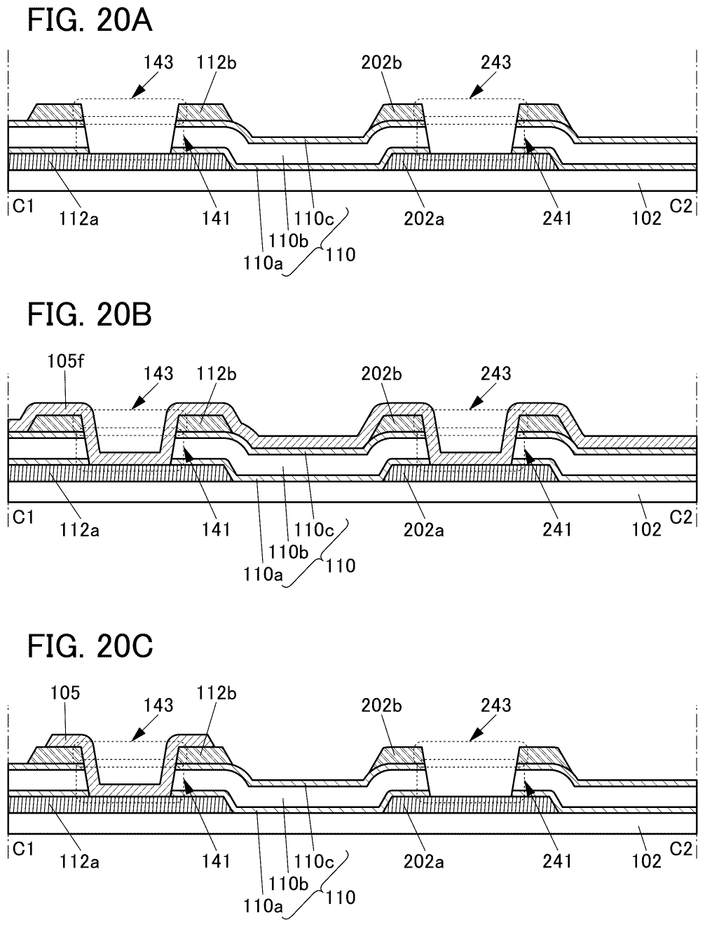

Next, the conductive layer 112B is partly removed to form the conductive layer 112b including the opening 143. Part of the conductive layer 204B is removed to form the conductive layer 202b including the opening 243 (FIG. 20A). For the formation of the opening 143, the description related to the formation of the opening 143 (FIG. 15C) shown in <Manufacturing method example 1> can be referred to. The opening 243 can be formed at the same time as the opening 143 by employing the same formation conditions as those for the opening 143.

Next, the insulating film 110f (the insulating film 110af, the insulating film 110bf, and the insulating film 110cf) in the region overlapping with the opening 143 and in the region overlapping with the opening 243 is removed to form the insulating layer 110 (the insulating layer 110a, the insulating layer 110b, and the insulating layer 110c) including the opening 141 and the opening 241 (FIG. 20A). For the formation of the opening 141, the description related to the formation of the opening 141 (FIG. 15C) shown in <Manufacturing method example 1> can be referred to. The opening 241 can be formed at the same time as the opening 141 by employing the same formation condition as those for the opening 141. The conductive layer 112a and the conductive layer 202a are exposed in the opening 141 and the opening 241, respectively.

### [Formation of Semiconductor Layer 105]

Next, the metal oxide film 105f to be the semiconductor layer 105 is formed to cover the opening 141 and the opening 143 and the opening 241 and the opening 243 (FIG. 20B). The metal oxide film 105f is provided in contact with the top surface and the side surface of the conductive layer 112b, the top surface of the conductive layer 112a, the top surface and the side surface of the conductive layer 202b, the top surface of the conductive layer 202a, and the top surface and the side surface of the insulating layer 110. For the formation of the metal oxide film 105f, the description related to the formation of the metal oxide film 105f (FIG. 15D) shown in <Manufacturing method example 1> can be referred to.

Next, the metal oxide film 105f is processed into an island shape to form the semiconductor layer 105 (FIG. 20C). The semiconductor layer 105 is formed to include a region in contact with the top surface of the conductive layer 112a, the side surface of the insulating layer 110, and the top surface and the side surface of the conductive layer 112b. For the formation of the semiconductor layer 105, the description related to the formation of the semiconductor layer 105 (FIG. 16A) shown in <Manufacturing method example 1> can be referred to.

It is preferable that heat treatment be performed after the metal oxide film 105f is formed or the metal oxide film 105f is processed into the semiconductor layer 105. The heat treatment can be performed using the same heat treatment condition as those for the heat treatment on the metal oxide film 105f or the semiconductor layer 105 described in <Manufacturing method example 1>.

### [Formation of Semiconductor Layer 108 and Semiconductor Layer 208]

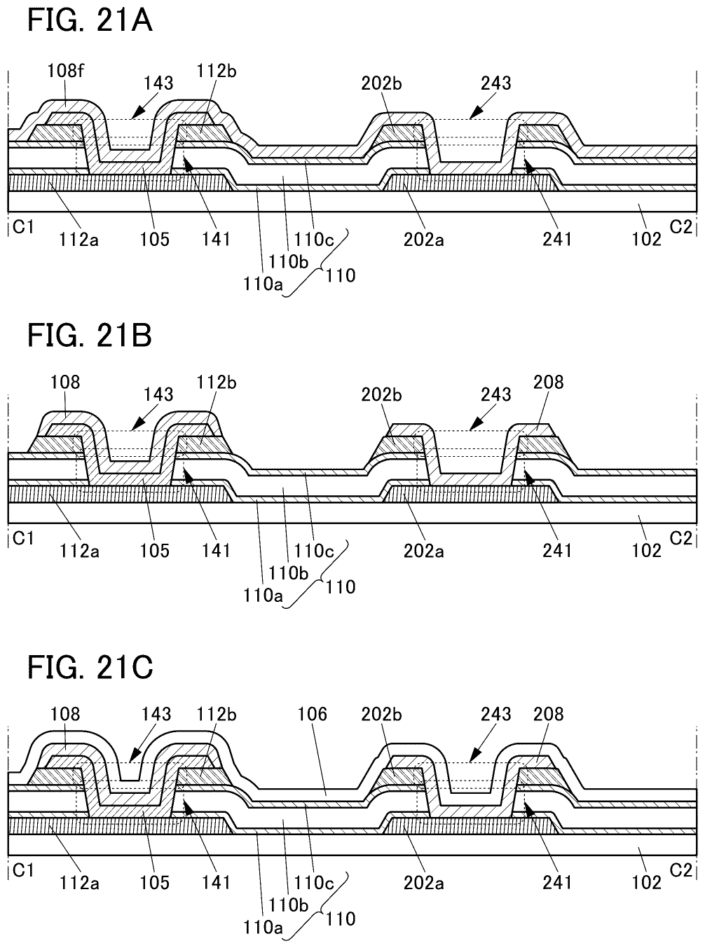

Next, the metal oxide film 108f to be the semiconductor layer 108 and the semiconductor layer 208 is formed to cover the semiconductor layer 105, the conductive layer 112b, the conductive layer 202b, the conductive layer 202a, and the insulating layer 110 (FIG. 21A). The metal oxide film 108f is provided in contact with the top surface and the side surface of the semiconductor layer 105, the top surface and the side surface of the conductive layer 112b, the top surface and the side surface of the conductive layer 202b, the top surface of the conductive layer 202a, and the top surface and the side surface of the insulating layer 110.

For the details of the method for forming the metal oxide film 108f and the heat treatment for the metal oxide film 108f, the method for forming the metal oxide film 108f and the description that can be used for the heat treatment for the metal oxide film 108f shown in <Manufacturing method example 1> can be referred to.

Next, the metal oxide film 108f is processed into an island shape to form the semiconductor layer 108 and the semiconductor layer 208 (FIG. 21B). The semiconductor layer 108 is formed to include a region overlapping with the semiconductor layer 105. The semiconductor layer 208 is formed to include a region in contact with the top surface of the conductive layer 202a, the side surface of the insulating layer 110, and the side surface and the top surface of the conductive layer 202b.

For the method for forming the semiconductor layer 108 and the semiconductor layer 208 and the details of the heat treatment for the semiconductor layer 108 and the semiconductor layer 208, the method for forming the semiconductor layer 108 and the semiconductor layer 208 and the description that can be used for the heat treatment for the semiconductor layer 108 and the semiconductor layer 208 shown in <Manufacturing method example 1> can be referred to.

The semiconductor layer 108 is a semiconductor layer functioning as the channel formation region of the transistor 100. The semiconductor layer 208 is a semiconductor layer functioning as a channel formation region of the transistor 200A. When the metal oxide film 108f is processed into an island shape as described above, the semiconductor layer 108 and the semiconductor layer 208 functioning as channel formation regions of different transistors can be formed at the same time. Thus, the number of masks needed for processing the semiconductor layer can be smaller than that in the case where the semiconductor layer of the transistor 100 and the semiconductor layer of the transistor 200A are formed in different steps. Furthermore, the total number of steps can be reduced.

### [Formation of Insulating Layer 106]

Next, the insulating layer 106 is formed to cover the semiconductor layer 105, the semiconductor layer 108, the conductive layer 112b, the semiconductor layer 208, the conductive layer 202b, and the insulating layer 110 (FIG. 21C). For the formation of the insulating layer 106, the description related to the formation of the insulating film 106f shown in <Manufacturing method example 1> (FIG. 17A) can be referred to.

### [Formation of Conductive Layer 104 and Conductive Layer 204]

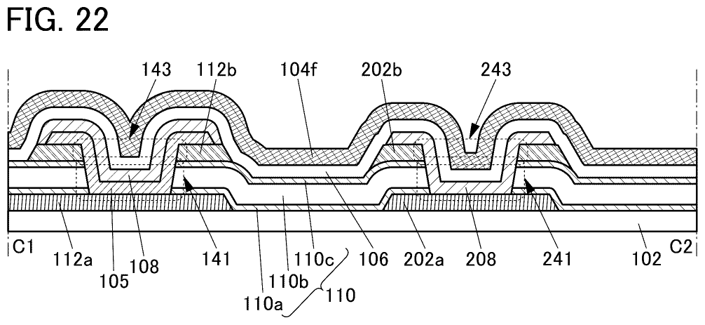

Next, the conductive film 104f to be the conductive layer 104 and the conductive layer 204 is formed over the insulating layer 106 (FIG. 22). For the formation of the conductive film 104f, the description related to the formation of the conductive film 104f (FIG. 17C) shown in <Manufacturing method example 1> can be referred to.

Next, a resist mask (not illustrated) is formed over the conductive film 104f by a photolithography process, and then the conductive film 104f is processed, whereby the conductive layer 104 functioning as the gate electrode of the transistor 100 and the conductive layer 204 functioning as the gate electrode of the transistor 200A are formed (FIG. 5B). For the formation of the conductive layer 104, the description related to the formation of the conductive layer 104 (FIG. 18A) shown in <Manufacturing method example 1> can be referred to. The conductive layer 204 can be formed at the same time as the conductive layer 104 by employing the same formation conditions as those for the conductive layer 104. Note that by the processing, the thickness of the insulating layer 106 in a portion not overlapping with the conductive layer 104 and the conductive layer 204 is sometimes smaller than the thickness of the portion overlapping with the conductive layer 104 and the conductive layer 204.

Through the above steps, the transistor 100 and the transistor 200A can be manufactured.

Through the above steps, the semiconductor device 10A can be manufactured (FIG. 5B).

This embodiment can be combined with any of the other embodiments or an example as appropriate. In this specification, in the case where a plurality of structure examples are shown in one embodiment, the structure examples can be combined as appropriate.

### Embodiment 3

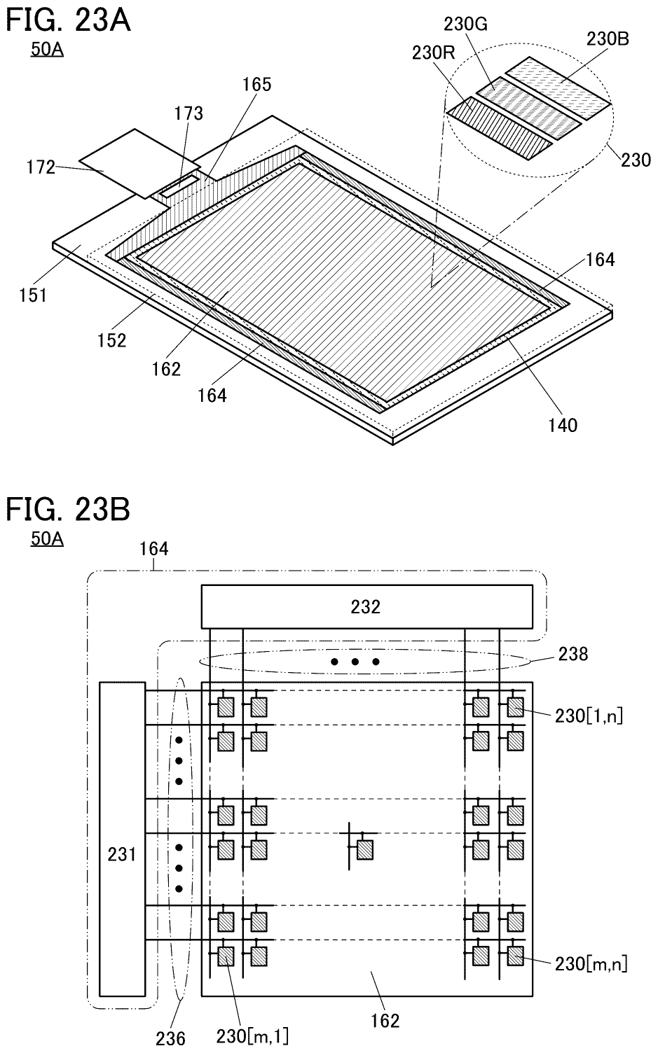

In this embodiment, a display apparatus for which the semiconductor device of one embodiment of the present invention can be used will be described with reference to FIG. 23A to FIG. 33F.

The display apparatus in this embodiment can be a high-resolution display apparatus or a large-sized display apparatus. Accordingly, the display apparatus in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

The display apparatus of this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display apparatus or a module including the display apparatus. Examples of the module including the display apparatus are a module in which a connector such as a flexible printed circuit board (hereinafter referred to as an FPC) or a TCP (Tape Carrier Package) is attached to the display apparatus, a module in which the display apparatus is mounted with an integrated circuit (IC) by a COG (Chip On Glass) method, a COF (Chip On Film) method, or the like.

FIG. 23A is a perspective view of a display apparatus 50A.

In the display apparatus 50A, a substrate 152 and a substrate 151 are bonded to each other. In FIG. 23A, the substrate 152 is denoted by a dashed line.

The display apparatus 50A includes a display portion 162, a connection portion 140, a peripheral circuit portion 164, a wiring 165, and the like. FIG. 23A illustrates an example where an IC 173 and an FPC 172 are mounted onto the display apparatus 50A. Thus, the structure illustrated in FIG. 23A can be regarded as a display module including the display apparatus 50A, the IC, and the FPC.

The connection portion 140 is provided outside the display portion 162. The connection portion 140 can be provided along one or more sides of the display portion 162. The number of connection portions 140 may be one or more. FIG. 23A illustrates an example where the connection portion 140 is provided to surround the four sides of the display portion. In the connection portion 140, a common electrode of a display element is electrically connected to a conductive layer so that a potential can be supplied to the common electrode.

The peripheral circuit portion 164 includes a scan line driver circuit (also referred to as a gate driver), for example. The peripheral circuit portion 164 may include both a scan line driver circuit and a signal line driver circuit (also referred to as a source driver).

The wiring 165 has a function of supplying a signal and power to the display portion 162 and the peripheral circuit portion 164. The signal and the power are input to the wiring 165 from the outside through the FPC 172 or input to the wiring 165 from the IC 173.

FIG. 23A illustrates an example in which the IC 173 is provided over the substrate 151 by a COG method, a COF (Chip On Film) method, or the like. An IC including one or both of a scan line driver circuit and a signal line driver circuit can be used as the IC 173, for example. Note that the display apparatus 50A and the display module are not necessarily provided with an IC. The IC may be mounted on the FPC by a COF method or the like.

The transistor of one embodiment of the present invention can be used for one or both of the display portion 162 and the peripheral circuit portion 164 of the display apparatus 50A, for example.

The display portion 162 of the display apparatus 50A is a region where an image is to be displayed, and includes a plurality of pixels 230 that are periodically arranged. FIG. 23A illustrates an enlarged view of one pixel 230.

There is no particular limitation on the arrangement of the pixels in the display apparatus of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 230 illustrated in FIG. 23A includes a pixel 230R that emits red light, a pixel 230G that emits green light, and a pixel 230B that emits blue light. The pixel 230R, the pixel 230G, and the pixel 230B each serve as a subpixel.

The pixel 230R, the pixel 230G, and the pixel 230B each include a display element and a circuit controlling the driving of the display element.

A variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

As examples of a display apparatus that includes a liquid crystal element, a transmissive liquid crystal display apparatus, a reflective liquid crystal display apparatus, and a transflective liquid crystal display apparatus can be given.

Examples of the light-emitting element include a self-luminous light-emitting element such as an LED (Light Emitting Diode), an OLED (Organic LED), and a semiconductor laser. Examples of the LED include a mini LED and a micro LED.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescent (TADF) material), and an inorganic compound (e.g., a quantum dot material).

The emission color of the light-emitting element can be infrared, red, green, blue, cyan, magenta, yellow, or white, for example. When the light-emitting element has a microcavity structure, higher color purity can be achieved.

One of a pair of electrodes of the light-emitting element functions as an anode, and the other electrode functions as a cathode.

In this embodiment, the case where a light-emitting element is used as the display element is mainly described as an example.

FIG. 23B is a block diagram illustrating the display apparatus 50A. The display apparatus 50A includes the display portion 162 and the peripheral circuit portion 164. The display portion 162 includes the plurality of pixels 230 arranged periodically. The peripheral circuit portion 164 includes a first driver circuit portion 231 and a second driver circuit portion 232.

Note that FIG. 23(B) illustrates an example in which the display portion 162 includes pixels 230 in m rows and n columns (m and n are each an integer greater than or equal to 1). In the drawing, the pixel 230[m,1] corresponds to the pixel 230 in the m-th row and the first column, the pixel 230[1,n] corresponds to the pixel 230 in the first row and the n-th column, and the pixel 230 [m,n] corresponds to the pixel 230 in the m-th row and the n-th column.

A circuit included in the first driver circuit portion 231 functions as, for example, a scan line driver circuit. A circuit included in the second driver circuit portion 232 functions as, for example, a signal line driver circuit. Some sort of circuit may be provided to face the first driver circuit portion 231 with the display portion 162 placed therebetween. Some sort of circuit may be provided to face the second driver circuit portion 232 with the display portion 162 placed therebetween.

Any of various circuits such as a shift register circuit, a level shifter circuit, an inverter circuit, a latch circuit, an analog switch circuit, a demultiplexer circuit, and a logic circuit can be used as a peripheral circuit portion 164. In the peripheral circuit portion 164, a transistor, a capacitor, and the like can be used. Transistors included in the peripheral circuit portion 164 may be formed in the same steps as the transistors included in the pixels 230.

The display apparatus 50A includes wirings 236 which are arranged substantially parallel to each other and whose potentials are controlled by the circuits included in the first driver circuit portion 231, and wirings 238 which are arranged substantially parallel to each other and whose potentials are controlled by the circuits included in the second driver circuit portion 232. FIG. 23B illustrates an example in which the wiring 236 and the wiring 238 are connected to the pixel 230. Note that the wiring 236 and the wiring 238 are examples, and the wirings connected to the pixel 230 are not limited to the wiring 236 and the wiring 238.

### <Structure Example of Peripheral Driver Circuit>

Using a latch circuit as an example, a structure example of a circuit that can be used as a peripheral driver circuit will be described.

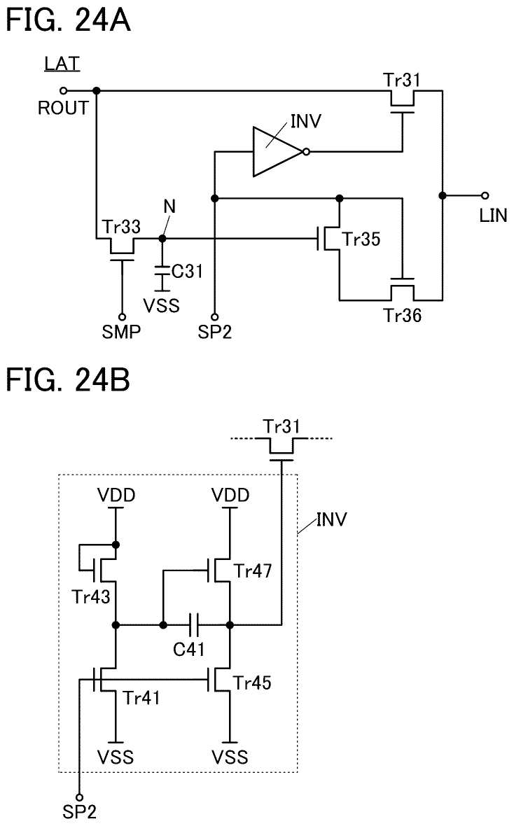

FIG. 24A is a circuit diagram illustrating a structure example of a latch circuit LAT. The latch circuit LAT illustrated in FIG. 24A includes a transistor Tr31, a transistor Tr33, a transistor Tr35, a transistor Tr36, a capacitor C31, and an inverter circuit INV. In FIG. 24A, a node that is electrically connected to one of a source and a drain of the transistor Tr33, a gate of the transistor Tr35, and one electrode of the capacitor C31 is referred to as a node N.

In the latch circuit LAT illustrated in FIG. 24A, when a high-potential signal is input to a terminal SMP, the transistor Tr33 is turned on. Thus, the potential of the node N becomes a potential corresponding to the potential of a terminal ROUT, and data corresponding to a signal input from the terminal ROUT to the latch circuit LAT is written to the latch circuit LAT. After data is written to the latch circuit LAT, the potential of the terminal SMP is set to a low potential, so that the transistor Tr33 is turned off. Thus, the potential of the node N is held and the data written to the latch circuit LAT is held. Specifically, when the potential of the node N is a low potential, data “0” is held in the latch circuit LAT and when the potential of the node N is a high potential, data “1” is held in the latch circuit LAT, for example.

A transistor with a low off-state current is preferably used as the transistor Tr33. An OS transistor can be suitably used as the transistor Tr33. Thus, the latch circuit LAT can hold data for a long period. Thus, the frequency of rewriting data in the latch circuit LAT can be lowered.

In this specification and the like, data that allows a signal input from a terminal SP2 to be output to a terminal LIN is written to the latch circuit LAT, which is referred to simply as “writing data to the latch circuit LAT” in some cases. That is, for example, data “1” is written to the latch circuit LAT, which is referred to simply as “writing data to the latch circuit LAT” in some cases.

The semiconductor device of one embodiment of the present invention can be suitably used for the latch circuit LAT. For example, the transistor 100 or the transistor 200 illustrated in FIG. 1B or the like can be used as one or more of the transistor Tr31, the transistor Tr33, the transistor Tr35, and the transistor Tr36.

FIG. 24B illustrates a structure example of the inverter circuit INV. The inverter circuit INV includes a transistor Tr41, a transistor Tr43, a transistor Tr45, a transistor Tr47, and a capacitor C41.

The latch circuit LAT has the structure illustrated in FIG. 24A and the inverter circuit INV has the structure illustrated in FIG. 24B, in which case all the transistors included in the latch circuit LAT can be transistors having the same polarity, for example, n-channel transistors. Thus, the transistor Tr31, the transistor Tr35, the transistor Tr36, the transistor Tr41, the transistor Tr43, the transistor Tr45, and the transistor Tr47 as well as the transistor Tr33 can be OS transistors, for example. Accordingly, all the transistors included in the latch circuit LAT can be formed in the same step.

The semiconductor device of one embodiment of the present invention can be suitably used for the inverter circuit INV. For example, the transistor 100 or the transistor 200 illustrated in FIG. 1B or the like can be used as one or more of the transistor Tr41, the transistor Tr43, the transistor Tr45, and the transistor Tr47.

With the use of one or more of the transistor 100, the transistor 100A to the transistor 100C, the transistor 200A, the transistor 200G, and the transistor 200H, which are vertical-channel transistors, the area occupied by the transistors can be reduced, whereby a display apparatus with a narrow bezel can be achieved. One or more of the above transistors can be suitably used as the transistor required to have a high on-state current. Furthermore, one or more of the transistor 200 and the transistor 200B to the transistor 200F, which are TGSA transistors, can be suitably used as the transistor required to have high saturation characteristics. Accordingly, a high-performance display apparatus can be obtained.

### <Structure Example of Pixel Circuit>

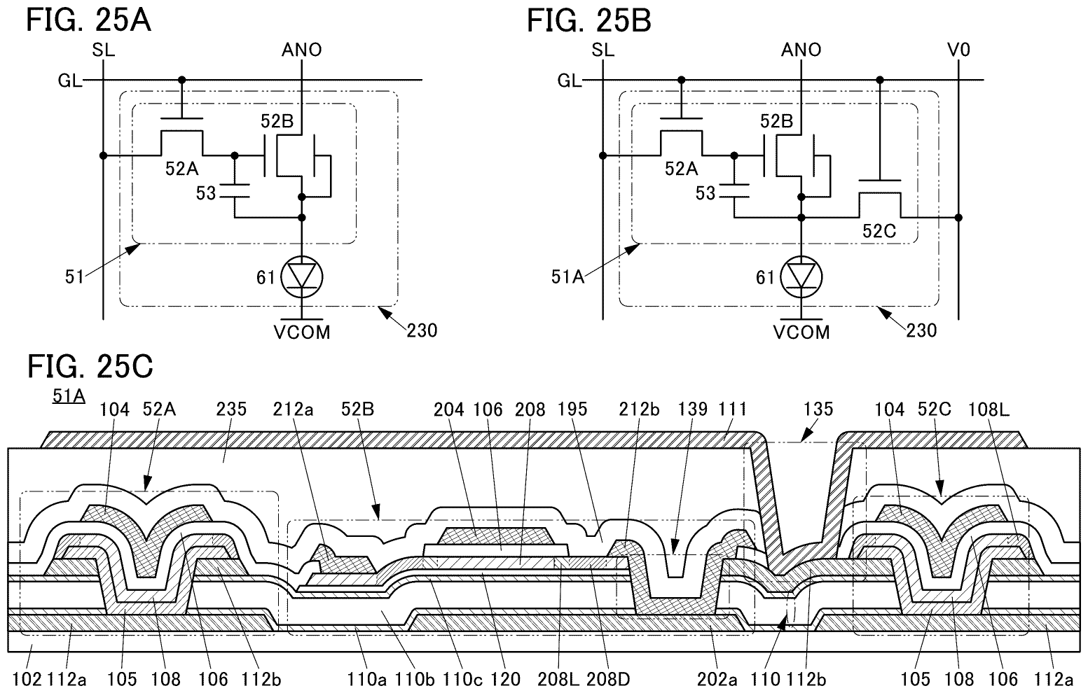

FIG. 25A illustrates a structure example of the pixel 230. The pixel 230 includes a pixel circuit 51 and a light-emitting device 61.

The pixel circuit 51 illustrated in FIG. 25A is a 2Tr1C-type pixel circuit including a transistor 52A, a transistor 52B, and a capacitor 53.

One of a source and a drain of the transistor 52A is electrically connected to a gate (first gate) of the transistor 52B and one terminal of the capacitor 53, and the other of the source and the drain of the transistor 52A is electrically connected to a wiring SL. A gate of the transistor 52A is electrically connected to a wiring GL. One of a source and a drain of the transistor 52B and the other terminal of the capacitor 53 are electrically connected to an anode of the light-emitting device 61. The other of the source and the drain of the transistor 52B is electrically connected to a wiring ANO. A cathode of the light-emitting device 61 is electrically connected to a wiring VCOM.

The wiring GL corresponds to the wiring 236, and the wiring SL corresponds to the wiring 238 (see FIG. 23B). The wiring VCOM supplies a potential for supplying a current to the light-emitting device 61. The transistor 52A has a function of controlling the conduction state or the non-conduction state between the wiring SL and the gate (first gate) of the transistor 52B on the basis of the potential of the wiring GL. For example, VDD is supplied to the wiring ANO, and VSS is supplied to the wiring VCOM.

The transistor 52B has a function of controlling the amount of a current flowing through the light-emitting device 61. The capacitor 53 has a function of retaining a gate (first gate) potential of the transistor 52B. The intensity of light emitted by the light-emitting device 61 can be controlled in accordance with an image signal supplied to the gate (first gate) of the transistor 52B.

Some or all of the transistors included in the pixel circuit 51 may be provided with a second gate. In the pixel circuit 51 illustrated in FIG. 25A, the transistor 52B includes the second gate, and the second gate is electrically connected to the one of the source and the drain of the transistor 52B. Note that the second gate of the transistor 52B may be electrically connected to the first gate of the transistor 52B.

The above-described semiconductor device can be suitably used for the pixel circuit 51. For example, the transistor 100 illustrated in FIG. 1B or the like can be used as the transistor 52A, and the transistor 200 can be used as the transistor 52B.

FIG. 25B illustrates a structure example of the pixel 230 different from that illustrated in FIG. 25A. The pixel 230 includes a pixel circuit 51A and the light-emitting device 61.

The pixel circuit 51A illustrated in FIG. 25B is different from the pixel circuit 51 illustrated in FIG. 25A mainly in including a transistor 52C. The pixel circuit 51A is a 3Tr1C-type pixel circuit including the transistor 52A, the transistor 52B, the transistor 52C, and the capacitor 53.

One of a source and a drain of the transistor 52C is electrically connected to one of a source and a drain of the transistor 52B. The other of the source and the drain of the transistor 52C is electrically connected to a wiring V0. For example, a reference potential is supplied to the wiring V0.

The transistor 52C has a function of controlling the conduction state or the non-conduction state between the one of the source or the drain of the transistor 52B and the wiring V0 on the basis of the potential of the wiring GL. Variations in the gate (first gate)-source potential of the transistor 52B can be inhibited by the reference potential of the wiring V0 supplied through the transistor 52C.

A current value that can be used for setting of pixel parameters can be obtained with the use of the wiring V0. Specifically, the wiring V0 can function as a monitor line for outputting a current flowing through the transistor 52B or a current flowing through the light-emitting device 61 to the outside. A current output to the wiring V0 is converted into a voltage by a source follower circuit and can be output to the outside. Alternatively, the current is converted into a digital signal by an A/D converter and can be output to the outside.

The above-described semiconductor device can be suitably used for the pixel circuit 51A. For example, the transistor 100 illustrated in FIG. 1B or the like can be used as each of the transistor 52A and the transistor 52C, and the transistor 200 can be used as the transistor 52B.

Note that there is no particular limitation on the pixel circuit that can be used for the display apparatus of one embodiment of the present invention.

A structure example of the pixel circuit 51A is illustrated in FIG. 25C. FIG. 25C is a cross-sectional view of the pixel circuit 51A.

FIG. 25C illustrates a structure where the pixel circuit 51A employs the semiconductor device 10 illustrated in FIG. 1B or the like. Specifically, the transistor 100 is used as each of the transistor 52A and the transistor 52C and the transistor 200 is used as the transistor 52B.

The transistor 52B functioning as a driving transistor that controls a current flowing through the light-emitting device 61 preferably has a higher saturation characteristics than the transistor 52A functioning as a selection transistor for controlling a selection state of the pixel 230. The use of the TGSA transistor 200 having a long channel length as the transistor 52B enables the display apparatus to have high reliability. Furthermore, when the vertical-channel transistor 100 having a short channel length is used as each of the transistor 52A and the transistor 52C, the area occupied by the pixel circuit 51A can be reduced, so that a high-definition display apparatus can be obtained.

Note that the transistor 100 may be used as the transistor 52B. The use of the vertical-channel transistor 100 having a short channel length as the transistor 52B enables the display apparatus to have high luminance. Furthermore, the area occupied by the pixel circuit 51A can be reduced, so that a high-definition display apparatus can be obtained.

The conductive layer 212b included in the transistor 52B is electrically connected to the conductive layer 202a through an opening 139 provided in the insulating layer 120 and the insulating layer 110. The conductive layer 212b is electrically connected to the conductive layer 112b included in the transistor 52C. Note that the electrical connection between the transistor 52A and the transistor 52B is omitted in FIG. 25C. For example, a first opening reaching the conductive layer 112b included in the transistor 52A and a second opening reaching the conductive layer 204 included in the transistor 52B are provided in an insulating layer 195. A first wiring is provided over the insulating layer 195 to cover the first opening and the second opening, whereby the conductive layer 112b included in the transistor 52A and the conductive layer 204 included in the transistor 52B can be electrically connected to each other through the first wiring.

In FIG. 25C, the capacitor 53 is omitted. The capacitor 53 can be formed in a region where the insulating layer 106 is interposed between the conductive layer 204 functioning as the gate electrode of the transistor 52B and the conductive layer 112b functioning as one of a source electrode and a drain electrode of the transistor 52C, for example. Note that there is no particular limitation on the structure of the capacitor 53.

The insulating layer 195 is provided to cover the transistor 52A, the transistor 52B, the transistor 52C, and the capacitor 53, and an insulating layer 235 is provided to cover the insulating layer 195. The light-emitting device 61 can be provided over the insulating layer 235. FIG. 25C illustrates a pixel electrode 111 functioning as one electrode of the light-emitting device 61. The pixel electrode 111 is electrically connected to the conductive layer 112b included in the transistor 52C through an opening 135 provided in the insulating layer 106, the insulating layer 195, and the insulating layer 235. The insulating layer 195 functions as a protective layer for the transistor 52A, the transistor 52B, and the transistor 52C. Providing the insulating layer 195 can effectively inhibit diffusion of impurities (e.g., water and hydrogen) from the outside into the transistors and increase the reliability of the display apparatus. The insulating layer 235 has a function of reducing unevenness due to the transistor 52A, the transistor 52B, and the transistor 52C and making the formation surface of the light-emitting device 61 flatter. Note that in this specification and the like, the insulating layer 235 is referred to as a planarization layer in some cases.

The insulating layer 195 can be an insulating layer containing an inorganic material or an insulating layer containing an organic material. For example, an inorganic material such as an oxide, an oxynitride, a nitride oxide, or a nitride can be suitably used for the insulating layer 195. Specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or more of acrylic resins and polyimide resins can be used. As an organic material, a photosensitive material may be used. A stack including two or more of the above insulating layers may also be used. The insulating layer 195 may have a stacked-layer structure of an insulating layer containing an inorganic material and an insulating layer containing an organic material.

An insulating layer containing an organic material can be suitably used as the insulating layer 235. As the organic material, a photosensitive organic resin is preferably used, and for example, a photosensitive resin composite including an acrylic resin is preferably used. Note that in this specification and the like, an acrylic resin refers to not only a polymethacrylic acid ester or a methacrylic resin, but also all the acrylic polymer in a broad sense in some cases.

The insulating layer 235 preferably has a function of a planarization layer, and an organic insulating film is suitable. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably has a function of an etching protective layer. In that case, the formation of a depressed portion in the insulating layer 235 can be inhibited in processing pixel electrode 111, for example. Alternatively, a depressed portion may be formed in the insulating layer 235 in processing the pixel electrode 111, for example.

The insulating layer 235 may have a stacked-layer structure of an organic insulating layer and an inorganic insulating layer. For example, the insulating layer 235 can have a stacked-layer structure of an organic insulating layer and an inorganic insulating layer over the organic insulating layer. An inorganic insulating layer provided on the outermost surface of the insulating layer 235 can function as an etching protective layer. This can inhibit a decrease in the flatness of the insulating layer 235, which is caused by etching of part of the insulating layer 235 in the formation of the pixel electrode 111.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

### Structure Example 1 of Display Apparatus

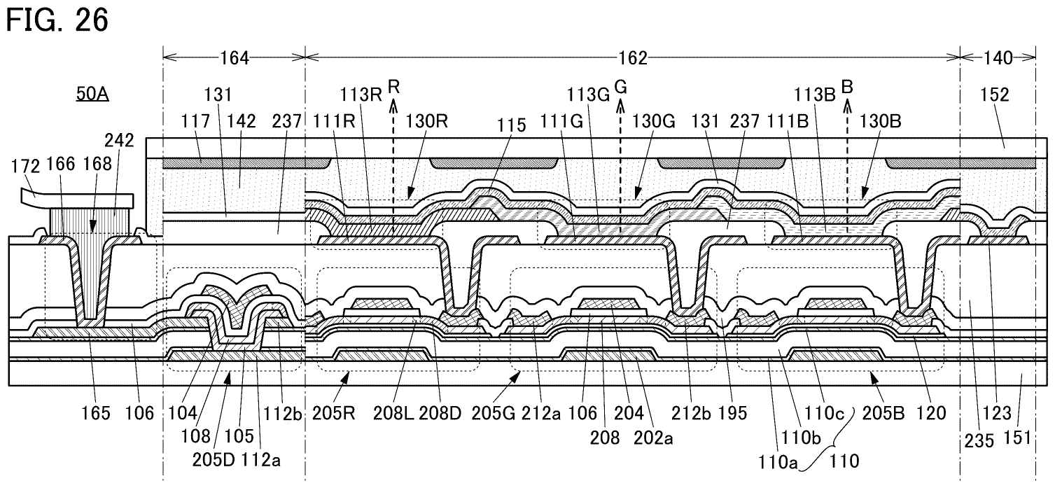

FIG. 26 illustrates an example of cross sections of part of a region including the FPC 172, part of the peripheral circuit portion 164, part of the display portion 162, part of the connection portion 140, and part of a region including the end portion of the display apparatus 50A.

The display apparatus 50A illustrated in FIG. 26 includes a transistor 205D, a transistor 205R, a transistor 205G, and a transistor 205B, a light-emitting element 130R, a light-emitting element 130G, a light-emitting element 130B, and the like between the substrate 151 and the substrate 152. The light-emitting element 130R, the light-emitting element 130G, and the light-emitting element 130B are display elements included in the pixel 230R that emits red light, the pixel 230G that emits green light, and the pixel 230B that emits blue light, respectively.

The display apparatus 50A employs an SBS structure. The SBS structure can optimize materials and structures of light-emitting elements and thus can increase the degree of freedom in selecting materials and structures, so that the luminance and the reliability can be easily improved.

The display apparatus 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

The transistor 205D, the transistor 205R, the transistor 205G, and the transistor 205B are each formed over the substrate 151. These transistors can be manufactured using the same material through the same process.

An OS transistor can be suitably used as each of the transistor 205D, the transistor 205R, the transistor 205G, and the transistor 205B. Any of the transistors of embodiments of the present invention can be used as the transistor 205D, the transistor 205R, the transistor 205G, and the transistor 205B. In other words, the display apparatus 50A includes any of the transistors of embodiments of the present invention in both the display portion 162 and the peripheral circuit portion 164. Although FIG. 26 illustrates an example in which TGSA transistors are used in the display portion 162 and a vertical-channel transistor is used in the peripheral circuit portion 164, one embodiment of the present invention is not limited thereto. In the display apparatus of one embodiment of the present invention, vertical-channel transistors may be used in the display portion 162, and a TGSA transistor may be used in the peripheral circuit portion 164. In the case where a semiconductor device including two vertical-channel transistors is used in the display apparatus 50A as in the semiconductor device 10A illustrated in FIG. 5A to FIG. 5C, a vertical-channel transistor can be used in both the display portion 162 and the peripheral circuit portion 164. When the vertical-channel transistor of one embodiment of the present invention is used in the display portion 162, the pixel size can be reduced and high definition can be achieved, for example. When the vertical-channel transistor of one embodiment of the present invention is used in the peripheral circuit portion 164, the area occupied by the peripheral circuit portion 164 can be reduced and a narrower bezel can be achieved. The description in the above embodiment can be referred to for the transistors of one embodiment of the present invention.

The transistor provided in the peripheral circuit portion 164 is sometimes required to have a higher on-state current than the transistor provided in the display portion 162. The peripheral circuit portion 164 preferably employs a transistor with a short channel length. For example, one or more kinds of the above-described transistor 100, the transistor 100A to the transistor 100C, the transistor 200A, the transistor 200G, and the transistor 200H can be suitably used in the peripheral circuit portion 164. When one or more kinds of the above-described transistors are used in the peripheral circuit portion 164, the area occupied by the transistors can be reduced and a display apparatus with a narrow bezel can be achieved. One or more kinds of the above-described transistor 200 and the transistor 200B to the transistor 200F can be suitably used for the transistor provided in the display portion 162. FIG. 26 illustrates the structure in which the above-described transistor 100 is used as the transistor 205D and the transistor 200 is used as each of the transistor 205R, the transistor 205G, and the transistor 205B. Note that one or more kinds of the transistor 100, the transistor 100A to the transistor 100C, the transistor 200A, the transistor 200G, and the transistor 200H may be used in the display portion 162, and one or more kinds of the transistor 200, the transistor 200B to the transistor 200F may be used in the peripheral circuit portion 164.

Note that the transistor included in the display apparatus of this embodiment is not limited to the transistor of one embodiment of the present invention. For example, the display apparatus of this embodiment may include the transistor of one embodiment of the present invention and a transistor having another structure in combination. The display apparatus of this embodiment may include one or more of a planar transistor, a staggered transistor, and an inverted staggered transistor, for example. A transistor included in the display apparatus of this embodiment may have a top-gate structure or a bottom-gate structure. Alternatively, gate electrodes may be provided above and below the semiconductor layer where a channel is formed.

A transistor containing silicon in its channel formation region (a Si transistor) may be included in the display apparatus of this embodiment. Examples of silicon include single crystal silicon, polycrystalline silicon, and amorphous silicon. In particular, a transistor containing LTPS in a semiconductor layer (hereinafter also referred to as an LTPS transistor) can be used. The LTPS transistor has high field-effect mobility and favorable frequency characteristics.

To increase the emission luminance of the light-emitting element included in the pixel circuit, it is necessary to increase the amount of a current flowing through the light-emitting element. To increase the current amount, the source-drain voltage of a driving transistor included in the pixel circuit needs to be increased. Since an OS transistor has a higher withstand voltage between the source and the drain than a Si transistor, a high voltage can be applied between the source and the drain of the OS transistor. Thus, with the use of an OS transistor as a driving transistor included in the pixel circuit, the amount of current flowing through the light-emitting element can be increased, resulting in an increase in emission luminance of the light-emitting element.

When a transistor operates in a saturation region, a change in a source-drain current relative to a change in a gate-source voltage can be smaller in an OS transistor than in a Si transistor. Accordingly, when an OS transistor is used as the driving transistor included in the pixel circuit, a current flowing between the source and the drain can be set minutely by a change in a gate-source voltage; hence, the amount of a current flowing through the light-emitting element can be controlled. Therefore, the number of gray levels in the pixel circuit can be increased.

Regarding saturation characteristics of a current flowing when a transistor operates in a saturation region, even in the case where the source-drain voltage of an OS transistor increases gradually, a more stable current (saturation current) can be made flow through the OS transistor than through a Si transistor. Thus, with the use of an OS transistor as a driving transistor, a current can be made to flow stably through the light-emitting element, for example, even when a variation in current-voltage characteristics of the EL element occurs. In other words, when the OS transistor operates in the saturation region, the source-drain current hardly changes with a change in the source-drain voltage; hence, the emission luminance of the light-emitting element can be stable.

The transistor included in the peripheral circuit portion 164 and the transistor included in the display portion 162 may have the same structure or different structures. The same structure or two or more kinds of structures may be employed for a plurality of transistors included in the peripheral circuit portion 164. Similarly, the same structure or two or more kinds of structures may be employed for a plurality of transistors included in the display portion 162. All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus with low power consumption and high drive capability can be achieved. Note that a structure in which the LTPS transistor and the OS transistor are combined is referred to as LTPO in some cases.

The insulating layer 195 is provided to cover the transistor 205D, the transistor 205R, the transistor 205G, and the transistor 205B, and the insulating layer 235 is provided over the insulating layer 195.

The light-emitting element 130R, the light-emitting element 130G, and the light-emitting element 130B are provided over the insulating layer 235.

The light-emitting element 130R includes a pixel electrode 111R over the insulating layer 235, an EL layer 113R over the pixel electrode 111R, and a common electrode 115 over the EL layer 113R. The light-emitting element 130R illustrated in FIG. 26 emits red light (R). The EL layer 113R includes a light-emitting layer that emits red light.

The light-emitting element 130G includes a pixel electrode 111G over the insulating layer 235, an EL layer 113G over the pixel electrode 111G, and the common electrode 115 over the EL layer 113G. The light-emitting element 130G illustrated in FIG. 26 emits green light (G). The EL layer 113G includes a light-emitting layer that emits green light.

The light-emitting element 130B includes a pixel electrode 111B over the insulating layer 235, an EL layer 113B over the pixel electrode 111B, and the common electrode 115 over the EL layer 113B. The light-emitting element 130B illustrated in FIG. 26 emits blue light (B). The EL layer 113B includes a light-emitting layer that emits blue light.

Although the EL layer 113R, the EL layer 113G, and the EL layer 113B have the same thickness in FIG. 26, the present invention is not limited thereto. The EL layer 113R, the EL layer 113G, and the EL layer 113B may have different thicknesses. For example, the thicknesses of the EL layer 113R, the EL layer 113G, and the EL layer 113B are preferably set to match an optical path length that intensifies light emitted from each EL layer. In that case, a microcavity structure is obtained, and the color purity of light emitted from each light-emitting element can be improved.

The pixel electrode 111R is electrically connected to the conductive layer 212b included in the transistor 205R through an opening provided in the insulating layer 195 and the insulating layer 235. In a similar manner, the pixel electrode 111G is electrically connected to the conductive layer 212b included in the transistor 205G and the pixel electrode 111B is electrically connected to the conductive layer 212b included in the transistor 205B.

End portions of the pixel electrode 111R, the pixel electrode 111G, and the pixel electrode 111B are covered with an insulating layer 237. The insulating layer 237 functions as a partition (also referred to as a bank or a spacer). The insulating layer 237 can have a single-layer structure or a stacked-layer structure including one or both of an inorganic insulating material and an organic insulating material. For the insulating layer 237, a material that can be used for the insulating layer 235 can be used, for example. With the insulating layer 237, the pixel electrode and the common electrode can be electrically insulated from each other. Furthermore, with the insulating layer 237, adjacent light-emitting elements can be electrically insulated from each other.

The common electrode 115 is one continuous film shared by the light-emitting element 130R, the light-emitting element 130G, and the light-emitting element 130B. The common electrode 115 shared by the light-emitting elements is electrically connected to a conductive layer 123 provided in the connection portion 140. As the conductive layer 123, a conductive layer formed using the same material and the same process as the pixel electrode 111R, the pixel electrode 111G, and the pixel electrode 111B are preferably used.

In the display apparatus of one embodiment of the present invention, a conductive film transmitting visible light is used for the electrode through which light is extracted, which is either the pixel electrode or the common electrode. A conductive film reflecting visible light is preferably used for the electrode through which light is not extracted.

A conductive film transmitting visible light may be used also for the electrode through which light is not extracted. In that case, this electrode is preferably provided between a reflective layer and the EL layer. In other words, light emitted by the EL layer may be reflected by the reflective layer to be extracted from the display apparatus.

As a material that forms the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other example of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The visible light reflectance of the transflective is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. In addition, these electrodes preferably have a resistivity lower than or equal to 1×10⁻² Ωcm.

The EL layer 113R, the EL layer 113G, and the EL layer 113B are each provided to have an island shape. In FIG. 26, end portions of the EL layer 113R and the EL layer 113G adjacent to each other overlap with each other, and end portions of the EL layer 113G and the EL layer 113B adjacent to each other overlap with each other. Although not illustrated, end portions of the EL layer 113R and the EL layer 113B adjacent to each other overlap with each other. When island-shaped EL layers are formed using a fine metal mask, end portions of the EL layers adjacent to each other may overlap with each other as illustrated in FIG. 26; however, the present invention is not limited thereto. That is, it is also possible that the EL layers adjacent to each other do not overlap with each other and are apart from each other. It is also possible that the display apparatus includes both a portion where the EL layers adjacent to each other overlap with each other and a portion where the EL layers adjacent to each other do not overlap with each other and are apart from each other.

Each of the EL layer 113R, the EL layer 113G, and the EL layer 113B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be smoothly transferred and light emission can be efficiently obtained. With this structure, high efficiency, low-voltage driving, and a long lifetime of the light-emitting element can be achieved at the same time.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a bipolar material and a TADF material.

Either a low molecular compound or a high molecular compound can be used in the light-emitting element, and an inorganic compound may also be included. Each layer included in the light-emitting element can be formed by an evaporation method (including a vacuum evaporation method), a transfer method, a printing method, an inkjet method, a coating method, or the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high luminance. Furthermore, the tandem structure can reduce the amount of a current needed for obtaining the same luminance as compared with a single structure, and thus can improve the reliability. Note that the tandem structure may be referred to as a stack structure.

In the case of using a tandem light-emitting element in FIG. 26, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting element 130R, the light-emitting element 130G, and the light-emitting element 130B. The protective layer 131 and the substrate 152 are bonded to each other with an adhesive layer 142. The substrate 152 is provided with a light-blocking layer 117. A solid sealing structure or a hollow sealing structure can be employed to seal the light-emitting elements, for example. In FIG. 26, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting element. Alternatively, the space may be filled with a resin other than the frame-shaped adhesive layer 142.

The protective layer 131 is provided at least in the display portion 162, and preferably provided to cover the entire display portion 162. The protective layer 131 is preferably provided to cover not only the display portion 162 but also the connection portion 140 and the peripheral circuit portion 164. It is further preferable that the protective layer 131 be provided to extend to the end portion of the display apparatus 50A. Meanwhile, a connection portion 168 has a portion not provided with the protective layer 131 so that the FPC 172 and a conductive layer 166 are electrically connected to each other.

By providing the protective layer 131 over the light-emitting element 130R, the light-emitting element 130G, and the light-emitting element 130B, the reliability of the light-emitting elements can be increased.

The protective layer 131 may have a single-layer structure or a stacked-layer structure of two or more layers. There is no limitation on the conductivity of the protective layer 131. As the protective layer 131, at least one type of insulating films, semiconductor films, and conductive films can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. In particular, the protective layer 131 preferably includes a nitride insulating film or a nitride oxide insulating film, and further preferably includes a nitride insulating film.

An inorganic film containing ITO, In—Zn oxide, Ga—Zn oxide, Al—Zn oxide, IGZO, or the like can be used as the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high visible-light-transmitting property. For example, ITO, IGZO, and aluminum oxide are preferable because they are each an inorganic material having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) to the EL layer side.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 168 is provided in a region of the substrate 151 not overlapping with the substrate 152. In the connection portion 168, the wiring 165 is electrically connected to the FPC 172 through the conductive layer 166 and a connection layer 242. An example in which the conductive layer 166 is a single conductive layer obtained by processing the same conductive film as the pixel electrode 111R, the pixel electrode 111G, and the pixel electrode 111B is shown. On the top surface of the connection portion 168, the conductive layer 166 is exposed. Thus, the connection portion 168 and the FPC 172 can be electrically connected to each other through the connection layer 242.

The wiring 165 is electrically connected to a transistor included in the peripheral circuit portion 164. FIG. 26 illustrates a structure in which the conductive layer 112b included in the transistor 205D extends and functions as the wiring 165. Note that the structure of the wiring 165 is not limited thereto.

The display apparatus 50A has a top-emission structure. Light emitted from the light-emitting element is emitted toward the substrate 152 side. For the substrate 152, a material having a high visible-light-transmitting property is preferably used. The pixel electrode 111R, the pixel electrode 111G, and the pixel electrode 111B contain a material that reflects visible light, and the counter electrode (the common electrode 115) contains a material that transmits visible light.

The light-blocking layer 117 is preferably provided on the surface of the substrate 152 on the substrate 151 side. The light-blocking layer 117 can be provided between adjacent light-emitting elements, in the connection portion 140, and in the peripheral circuit portion 164, for example.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

A variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, it is preferable to provide, as the surface protective layer, a glass layer or a silica layer (SiOₓ layer) because the surface contamination and generation of a scratch can be inhibited. The surface protective layer may be formed using diamond-like carbon (DLC), aluminum oxide (AlOₓ), a polyester-based material, a polycarbonate-based material, or the like. For the surface protective layer, a material having a high visible light transmittance is preferably used. The surface protective layer is preferably formed using a material with high hardness.

For each of the substrate 151 and the substrate 152, glass, quartz, ceramics, sapphire, a resin, a metal, an alloy, a semiconductor, or the like can be used. For the substrate on the side where light from the light-emitting element is extracted, a material that transmits the light is used. When a flexible material is used for the substrate 151 and the substrate 152, the display apparatus can have increased flexibility and a flexible display can be obtained. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used as at least one of the substrate 151 and the substrate 152.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence). Examples of a highly optically isotropic film include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

As the connection layer 242, an anisotropic conductive film (ACF), an anisotropic conductive paste (ACP), or the like can be used.

### Structure Example 2 of Display Apparatus

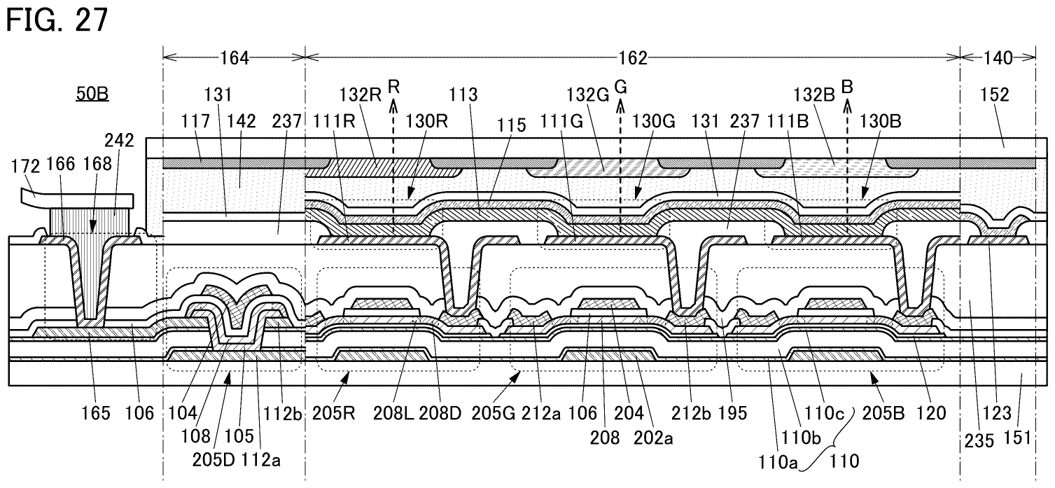

A display apparatus 50B illustrated in FIG. 27 is different from the display apparatus 50A mainly in that the subpixels of different colors include respective coloring layers (color filters or the like) and the light-emitting elements that include a common EL layer 113. Note that in the following description of display apparatuses, the description of portions similar to those of the above-described display apparatus may be omitted.

In the display apparatus 50B illustrated in FIG. 27, the transistor 205D, the transistor 205R, the transistor 205G, and the transistor 205B, the light-emitting element 130R, the light-emitting element 130G, and light-emitting element 130B, a coloring layer 132R transmitting red light, a coloring layer 132G transmitting green light, a coloring layer 132B transmitting blue light, and the like are provided between the substrate 151 and the substrate 152.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display apparatus 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display apparatus 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display apparatus 50B through the coloring layer 132B.

The EL layer 113 and the common electrode 115 are shared between the light-emitting element 130R, the light-emitting element 130G, and light-emitting element 130B. The number of manufacturing steps can be smaller in the case where the EL layer 113 is shared between the subpixels of different colors than the case where the subpixels of different colors include different EL layers.

The light-emitting element 130R, the light-emitting element 130G, and light-emitting element 130B illustrated in FIG. 27 emit white light, for example. When white light emitted from the light-emitting element 130R, the light-emitting element 130G, and light-emitting element 130B passes through the coloring layer 132R, the coloring layer 132G, and the coloring layer 132B, light of intended colors can be obtained.

In the light-emitting element that emits white light, two or more light-emitting layers are preferably included. In the case where two light-emitting layers are used to obtain white light emission, the two light-emitting layers are selected so that emission colors of the two light-emitting layers have a relationship of complementary colors. For example, when the emission color of the first light-emitting layer and the emission color of the second light-emitting layer are made complementary, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer containing a light-emitting substance that emits blue light and a light-emitting layer containing a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are stacked in this order; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. In addition, another layer may be provided between two light-emitting layers.

Alternatively, the light-emitting element 130R, the light-emitting element 130G, and light-emitting element 130B illustrated in FIG. 27 emit blue light, for example. In this case, the EL layer 113 includes one or more light-emitting layers that emit blue light. In the pixel 230B that emits blue light, blue light emitted from the light-emitting element 130B can be extracted. In each of the pixel 230R that emits red light and the pixel 230G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

### Structure Example 3 of Display Apparatus

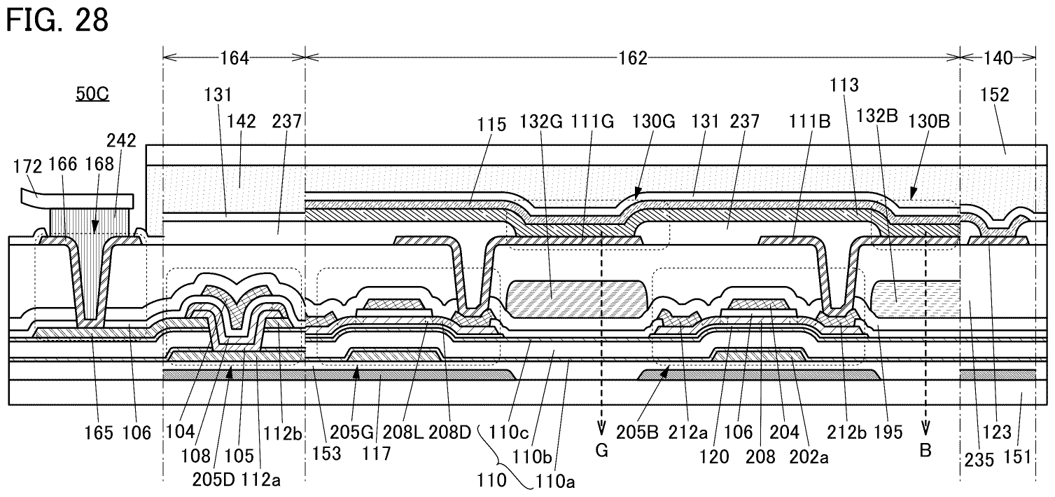

A display apparatus 50C illustrated in FIG. 28 is different from the display apparatus 50B mainly in having a bottom-emission structure.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 28 illustrates an example where the light-blocking layers 117 are provided over the substrate 151, an insulating layer 153 is provided over the light-blocking layers 117, and the transistor 205D, the transistor 205R (not illustrated), the transistor 205G, and the transistor 205B, and the like are provided over the insulating layer 153. In addition, the coloring layer 132R (not illustrated), the coloring layer 132G, and the coloring layer 132B are provided over the insulating layer 195, and the insulating layer 235 is provided over the coloring layer 132R, the coloring layer 132G, and the coloring layer 132B.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

Although not illustrated, the light-emitting element 130R overlapping with the coloring layer 132R includes the pixel electrode 111R, the EL layer 113, and the common electrode 115.

A material having a high visible-light-transmitting property is used for each of the pixel electrode 111R (not illustrated), the pixel electrode 111G, and the pixel electrode 111B. A material that reflects visible light is preferably used for the common electrode 115. In the display apparatus having a bottom-emission structure, a metal or the like having low resistance can be used for the common electrode 115; thus, a voltage drop due to the resistance of the common electrode 115 can be inhibited and a high display quality can be achieved.

Although FIG. 28 illustrates an example in which TGSA transistors are used in the display portion 162 and a vertical-channel transistor is used in the peripheral circuit portion 164, one embodiment of the present invention is not limited thereto. As described above, the display apparatus of one embodiment of the present invention can use a vertical-channel transistor in both the display portion 162 and the peripheral circuit portion 164. Thus, for example, when the vertical-channel transistor of one embodiment of the present invention is used in the display portion 162, the aperture ratio of the pixel can be increased or the pixel size can be reduced in the display apparatus having a bottom-emission structure.

### Structure Example 4 of Display Apparatus

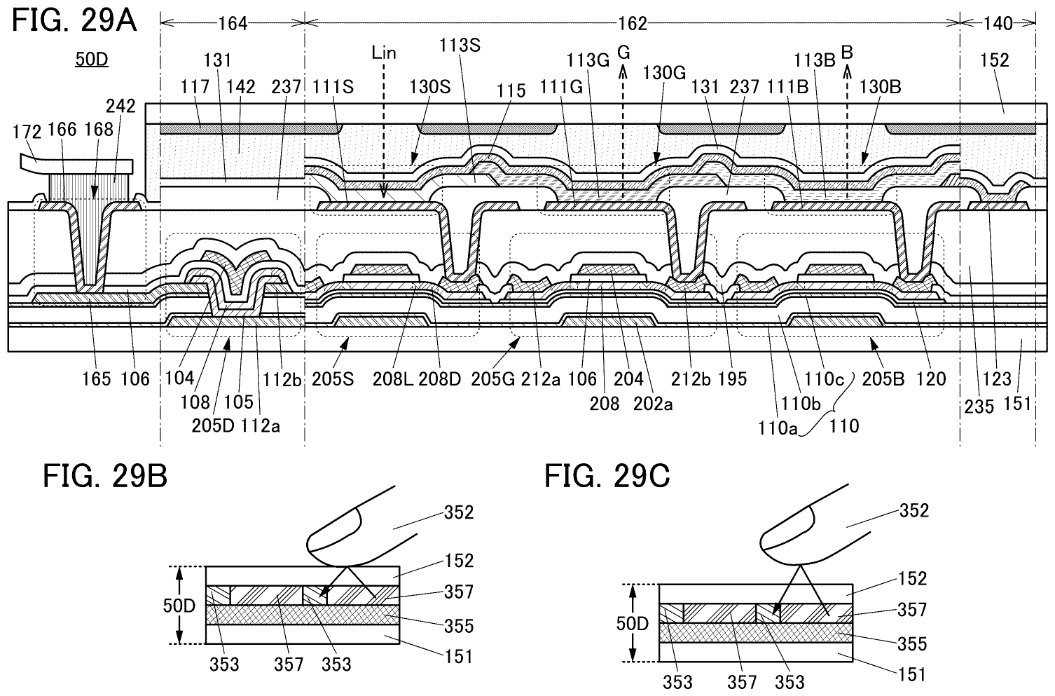

A display apparatus 50D illustrated in FIG. 29A is different from the display apparatus 50A mainly in including a light-receiving element 130S.

The display apparatus 50D includes light-emitting elements and a light-receiving element in a pixel. In the display apparatus 50D, organic EL elements are preferably used as the light-emitting elements and an organic photodiode is preferably used as the light-receiving element. The organic EL elements and the organic photodiode can be formed over the same substrate. Thus, the organic photodiode can be incorporated in the display apparatus including the organic EL element.

The display apparatus 50D can detect the touch or approach of an object while displaying an image because the pixel includes the light-emitting elements and the light-receiving element and thus has a light-receiving function. Accordingly, the display portion 162 has one or both of an image capturing function and a sensing function in addition to a function of displaying an image. For example, all the subpixels included in the display apparatus 50D can display an image; alternatively, some of the subpixels can emit light as a light source, some of the rest of the subpixels can detect light, and the other subpixels can display an image.

Accordingly, a light-receiving portion and a light source do not need to be provided separately from the display apparatus 50D; hence, the number of components of an electronic device can be reduced. For example, a biometric authentication device provided in the electronic device, a capacitive touch panel for scroll operation, or the like is not necessarily provided separately. Thus, with the use of the display apparatus 50D, the electronic device can be provided at lower manufacturing costs.

When the light-receiving elements are used as an image sensor, the display apparatus 50D can capture an image using the light-receiving elements. For example, image capturing for personal authentication with the use of a fingerprint, a palm print, the iris, the shape of a blood vessel (including the shape of a vein and the shape of an artery), a face, or the like can be performed using the image sensor.

The light-receiving element can be used for a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display apparatus and the object come in direct contact with each other. Furthermore, the contactless sensor can detect the object even when the object is not in contact with the display apparatus.

The light-receiving element 130S includes a pixel electrode 111S over the insulating layer 235, a functional layer 113S over the pixel electrode 111S, and the common electrode 115 over the functional layer 113S. Light Lin enters the functional layer 113S from the outside of the display apparatus 50D.

The pixel electrode 111S is electrically connected to the conductive layer 212b included in a transistor 205S through an opening provided in the insulating layer 195 and the insulating layer 235.

An end portion of the pixel electrode 111S is covered with the insulating layer 237.

The common electrode 115 is one continuous film provided to be shared by the light-receiving element 130S, the light-emitting element 130R (not illustrated), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment illustrates an example where an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

In addition to the active layer, the functional layer 113S may further include a layer containing a substance having a high hole-transport property, a substance having a high electron-transport property, a substance having a bipolar property (a substance having a high electron-transport property and a high hole-transport property), and the like. Without limitation to the above, the functional layer 113S may further include a layer containing a substance with a high hole-injection property, a hole-blocking material, a substance with a high electron-injection property, an electron-blocking material, or the like. Layers other than the active layer included in the light-receiving element can be formed using a material that can be used for the light-emitting element, for example.

Either a low molecular compound or a high molecular compound can be used for the light-receiving element, and an inorganic compound may also be contained. Each layer included in the light-receiving element can be formed by an evaporation method (including a vacuum evaporation method), a transfer method, a printing method, an inkjet method, a coating method, or the like.

The display apparatus 50D illustrated in FIG. 29B and FIG. 29C includes, between the substrate 151 and the substrate 152, a layer 353 including a light-receiving element, a circuit layer 355, and a layer 357 including light-emitting elements.

The layer 353 includes the light-receiving element 130S, for example. The layer 357 includes the light-emitting element 130R, the light-emitting element 130G, and light-emitting element 130B, for example.

The circuit layer 355 includes a circuit for driving a light-receiving element and a circuit for driving a light-emitting element. The circuit layer 355 includes the transistor 205R, the transistor 205G, and the transistor 205B. The circuit layer 355 can further include one or more of a switch, a capacitor, a resistor, a wiring, a terminal, and the like.

FIG. 29B illustrates an example where the light-receiving element 130S is used as a touch sensor. Light emitted from the light-emitting element in the layer 357 is reflected by a finger 352 that touches the display apparatus 50D as illustrated in FIG. 29B, and the light-receiving element in the layer 353 detects the reflected light. Thus, the touch of the finger 352 on the display apparatus 50D can be detected.

FIG. 29C is an example where the light-receiving element 130S is used as a contactless sensor. Light emitted from the light-emitting element in the layer 357 is reflected by the finger 352 that is approaching (i.e., that is not in contact with) the display apparatus 50D as illustrated in FIG. 29C, and the light-receiving element in the layer 353 detects the reflected light.

### Structure Example 5 of Display Apparatus

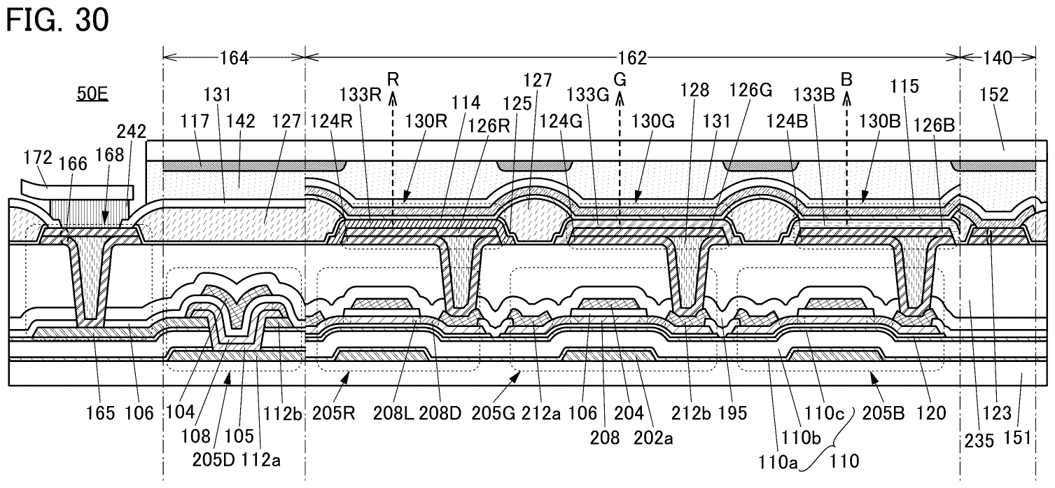

A display apparatus 50E illustrated in FIG. 30 is an example of a display apparatus having an MML structure. In other words, the display apparatus 50E includes a light-emitting element that is formed without using a fine metal mask. The stacked-layer structure from the substrate 151 to the insulating layer 235 and the stacked-layer structure from the protective layer 131 to the substrate 152 are similar to those in the display apparatus 50A; therefore, description thereof is omitted.

In FIG. 30, the light-emitting element 130R, the light-emitting element 130G, and light-emitting element 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 30 emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 30 emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 30 emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the light-emitting elements is referred to as the common layer 114. Note that in this specification and the like, the layer 133R, the layer 133G, and the layer 133B are sometimes referred to as island-shaped EL layers, EL layers formed in an island shape, or the like, in which case the common layer 114 is not included.

The layer 133R, the layer 133G, and the layer 133B are isolated from each other. When the EL layer is provided to have an island shape for each light-emitting element, a leakage current between adjacent light-emitting elements can be inhibited. This can prevent crosstalk due to unintended light emission, so that a display apparatus with extremely high contrast can be obtained.

Although the layer 133R, the layer 133G, and the layer 133B have the same thickness in FIG. 30, the present invention is not limited thereto. The layer 133R, the layer 133G, and the layer 133B may have different thicknesses.

The conductive layer 124R is electrically connected to the conductive layer 212b included in the transistor 205R through an opening provided in the insulating layer 195 and the insulating layer 235. In a similar manner, the conductive layer 124G is electrically connected to the conductive layer 212b included in the transistor 205G and the conductive layer 124B is electrically connected to the conductive layer 212b included in the transistor 205B.

The conductive layer 124R, the conductive layer 124G, and the conductive layer 124B are formed to cover the openings provided in the insulating layer 195 and the insulating layer 235. A layer 128 is embedded in the depressed portion of each of the conductive layer 124R, the conductive layer 124G, and the conductive layer 124B.

The layer 128 has a planarization function for the depressed portions of the conductive layer 124R, the conductive layer 124G, and the conductive layer 124B. The conductive layer 126R, the conductive layer 126G, and the conductive layer 126B electrically connected to the conductive layer 124R, the conductive layer 124G, and the conductive layer 124B, respectively, are provided over the conductive layer 124R, the conductive layer 124G, the conductive layer 124B, and the layer 128. Thus, regions overlapping with the depressed portions of the conductive layer 124R, the conductive layer 124G, and the conductive layer 124B can also be used as light-emitting regions, increasing the aperture ratio of the pixels. A conductive layer functioning as a reflective electrode is preferably used as each of the conductive layer 124R and the conductive layer 126R, the conductive layer 124G and the conductive layer 126G, and the conductive layer 124B and the conductive layer 126B.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 30 illustrates an example where the top surface of the layer 128 includes a flat portion, the shape of the layer 128 is not particularly limited. The top surface of the layer 128 may include at least one of a convex surface, a concave surface, and a flat surface. The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle less than 90°. In the case where the end portion of the pixel electrode has a tapered shape, the layer 133R provided along the side surface of the pixel electrode has a tapered shape. When the side surface of the pixel electrode has a tapered shape, coverage with an EL layer provided along the side surface of the pixel electrode can be improved.

Since the conductive layer 124G and the conductive layer 126G and the conductive layer 124B and the conductive layer 126B are similar to the conductive layer 124R and the conductive layer 126R, the detailed description thereof is omitted.

The top surface and the side surface of the conductive layer 126R are covered with the layer 133R. Similarly, the top surface and the side surface of the conductive layer 126G are covered with the layer 133G, and the top surface and the side surface of the conductive layer 126B are covered with the layer 133B. Accordingly, regions provided with the conductive layer 126R, the conductive layer 126G, and the conductive layer 126B can be entirely used as the light-emitting regions of the light-emitting element 130R, the light-emitting element 130G, and the light-emitting element 130B, increasing the aperture ratio of the pixels.

The side surface and part of the top surface of each of the layer 133R, the layer 133G, and the layer 133B are covered with an insulating layer 125 and an insulating layer 127. The common layer 114 is provided over the layer 133R, the layer 133G, the layer 133B, the insulating layer 125, and the insulating layer 127, and the common electrode 115 is provided over the common layer 114. The common layer 114 and the common electrode 115 are each one continuous film shared by a plurality of light-emitting elements.

In FIG. 30, the insulating layer 237 illustrated in FIG. 26 or the like is not provided between the conductive layer 126R and the layer 133R. That is, an insulating layer (also referred to as a partition wall, a bank, a spacer, or the like) in contact with the pixel electrode and covering an upper end portion of the pixel electrode is not provided in the display apparatus 50E. Thus, the distance between adjacent light-emitting elements can be extremely shortened. As a result, a display apparatus with high definition or high resolution can be obtained. In addition, a mask for forming the insulating layer is not needed, which leads to a reduction in manufacturing cost of the display apparatus.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may be a stack of an electron-transport layer and an electron-injection layer, or may be a stack of a hole-transport layer and a hole-injection layer. The common layer 114 is shared by the light-emitting element 130R, the light-emitting element 130G, and the light-emitting element 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the layer 133R, the layer 133G, and the layer 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, a step is generated due to a level difference between a region where the pixel electrode and the island-shaped EL layer are provided and a region where neither the pixel electrode nor the island-shaped EL layer is provided (a region between the light-emitting elements). In the display apparatus of one embodiment of the present invention, the step can be reduced with the insulating layer 125 and the insulating layer 127, and the coverage with the common layer 114 and the common electrode 115 can be improved. Thus, connection defects caused by step disconnection of the common layer 114 and the common electrode 115 can be inhibited. In addition, an increase in electric resistance, which is caused by local thinning of the common electrode 115 due to the step, can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a smooth shape with high flatness.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. In particular, aluminum oxide is preferable because it has high selectivity with respect to the EL layer in etching and has a function of protecting the EL layer in forming the insulating layer 127 which is to be described later. In particular, an inorganic insulating film such as an aluminum oxide film, a hafnium oxide film, or a silicon oxide film formed by an ALD method is used as the insulating layer 125, whereby the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of a barrier insulating layer or a gettering function, entry of impurities (typically, at least one of water and oxygen) that might diffuse into the light-emitting element from the outside can be inhibited. With this structure, a highly reliable light-emitting element and a highly reliable display apparatus can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 115.

As the insulating layer 127, an insulating layer containing an organic material can be suitably used. As the organic material, a photosensitive organic resin is preferably used, and for example, a photosensitive resin composite including an acrylic resin is preferably used.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. Alternatively, the insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display apparatus can be improved. Furthermore, since the display quality can be increased even when a polarizing plate is not used in the display apparatus, a lightweight and thin display apparatus can be achieved.

Examples of the material absorbing visible light include materials containing pigment of black or the like, materials containing dye, light-absorbing resin materials (e.g., polyimide), and resin materials that can be used for color filters (color filter materials). Using the resin material obtained by stacking or mixing color filter materials of two or three or more colors is particularly preferable, in which case the effect of blocking visible light is enhanced. In particular, mixing color filter materials of three or more colors enables the formation of a black or nearly black resin layer.

### Structure Example 6 of Display Apparatus

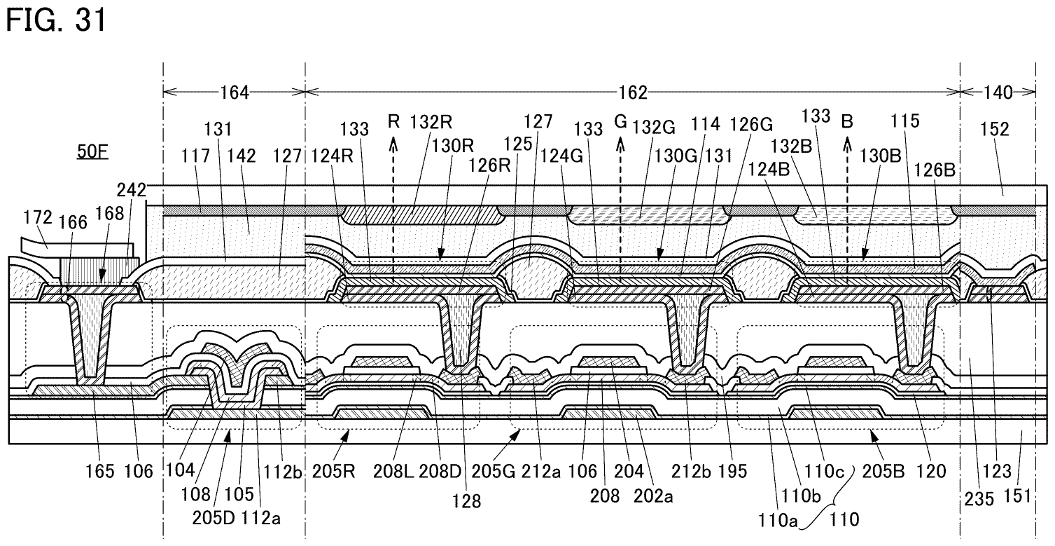

A display apparatus 50F illustrated in FIG. 31 is different from the display apparatus 50E mainly in that the light-emitting elements including the layers 133 and coloring layers (color filters or the like) are used for the subpixels of different colors.

The display apparatus 50F illustrated in FIG. 31 includes, between the substrate 151 and the substrate 152, the transistor 205D, the transistor 205R, the transistor 205G, and the transistor 205B, the light-emitting element 130R, the light-emitting element 130G, and light-emitting element 130B, the coloring layer 132R transmitting red light, the coloring layer 132G transmitting green light, the coloring layer 132B transmitting blue light, and the like.

Light emitted from the light-emitting element 130R is extracted as red light to the outside of the display apparatus 50F through the coloring layer 132R. Similarly, light emitted from the light-emitting element 130G is extracted as green light to the outside of the display apparatus 50F through the coloring layer 132G. Light emitted from the light-emitting element 130B is extracted as blue light to the outside of the display apparatus 50F through the coloring layer 132B.

The light-emitting element 130R, the light-emitting element 130G, and light-emitting element 130B each include the layer 133. The three layers 133 are formed using the same process and the same material. The three layers 133 are isolated from each other. When the EL layer is provided to have an island shape for each light-emitting element, a leakage current between adjacent light-emitting elements can be inhibited. This can prevent crosstalk due to unintended light emission, so that a display apparatus with extremely high contrast can be obtained.

The light-emitting element 130R, the light-emitting element 130G, and light-emitting element 130B illustrated in FIG. 31 emit white light, for example. When white light emitted from the light-emitting element 130R, the light-emitting element 130G, and light-emitting element 130B passes through the coloring layer 132R, the coloring layer 132G, and the coloring layer 132B, light of intended colors can be obtained.

Alternatively, the light-emitting element 130R, the light-emitting element 130G, and light-emitting element 130B illustrated in FIG. 31 emit blue light, for example. In this case, the layer 133 includes one or more light-emitting layers that emit blue light. In the pixel 230B that emits blue light, blue light emitted from the light-emitting element 130B can be extracted. In each of the pixel 230R that emits red light and the pixel 230G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the intended color can be absorbed by the coloring layer, and color purity of light exhibited by a subpixel can be improved.

### Structure Example 7 of Display Apparatus

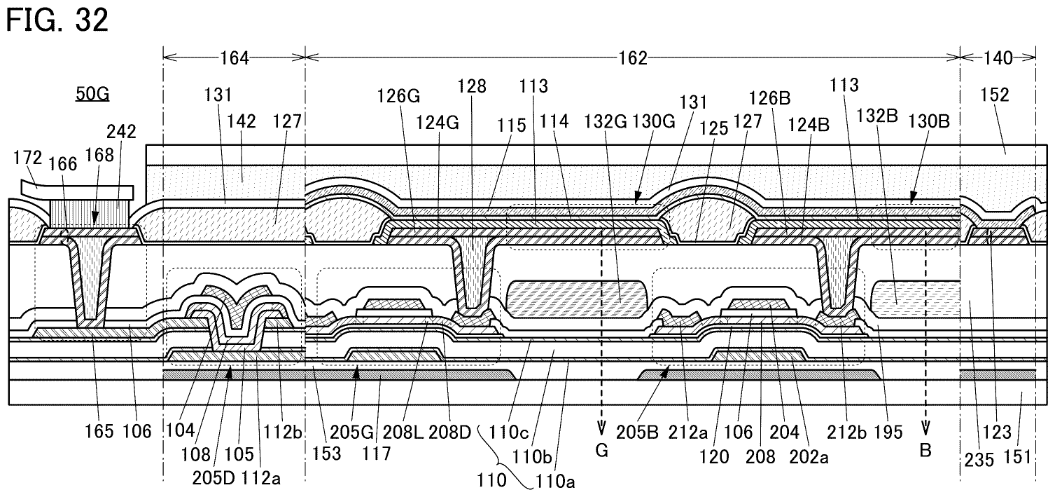

A display apparatus 50G illustrated in FIG. 32 is different from the display apparatus 50F mainly in having a bottom-emission structure.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 32 illustrates an example where the light-blocking layers 117 are provided over the substrate 151, the insulating layer 153 is provided over the light-blocking layers 117, and the transistor 205D, the transistor 205R (not illustrated), the transistor 205G, and the transistor 205B, and the like are provided over the insulating layer 153. In addition, the coloring layer 132R (not illustrated), the coloring layer 132G, and the coloring layer 132B are provided over the insulating layer 195, and the insulating layer 235 is provided over the coloring layer 132R, the coloring layer 132G, and the coloring layer 132B.

The light-emitting element 130G overlapping with the coloring layer 132G includes the conductive layer 124G, the conductive layer 126G, the EL layer 113, the common layer 114, and the common electrode 115.

The light-emitting element 130B overlapping with the coloring layer 132B includes the conductive layer 124B, the conductive layer 126B, the EL layer 113, the common layer 114, and the common electrode 115.

Although not illustrated, the light-emitting element 130R overlapping with the coloring layer 132R includes the conductive layer 124R, the conductive layer 126R, the EL layer 113, the common layer 114, and the common electrode 115.

A material having a high visible-light-transmitting property is used for each of the conductive layer 124R (not illustrated), the conductive layer 124G, the conductive layer 124B, the conductive layer 126R (not illustrated), the conductive layer 126G, and the conductive layer 126B. A material that reflects visible light is preferably used for the common electrode 115. In the display apparatus having a bottom-emission structure, a metal or the like having low resistance can be used for the common electrode 115; thus, a voltage drop due to the resistance of the common electrode 115 can be inhibited and a high display quality can be achieved.

Although FIG. 32 illustrates an example in which TGSA transistors are used in the display portion 162 and a vertical-channel transistor is used in the peripheral circuit portion 164, one embodiment of the present invention is not limited thereto. As described above, the display apparatus of one embodiment of the present invention can use a vertical-channel transistor in both the display portion 162 and the peripheral circuit portion 164. Thus, for example, when the vertical-channel transistor of one embodiment of the present invention is used in the display portion 162, the aperture ratio of the pixel can be increased or the pixel size can be reduced in the display apparatus having a bottom-emission structure.

### <Structure Example of Display Apparatus>

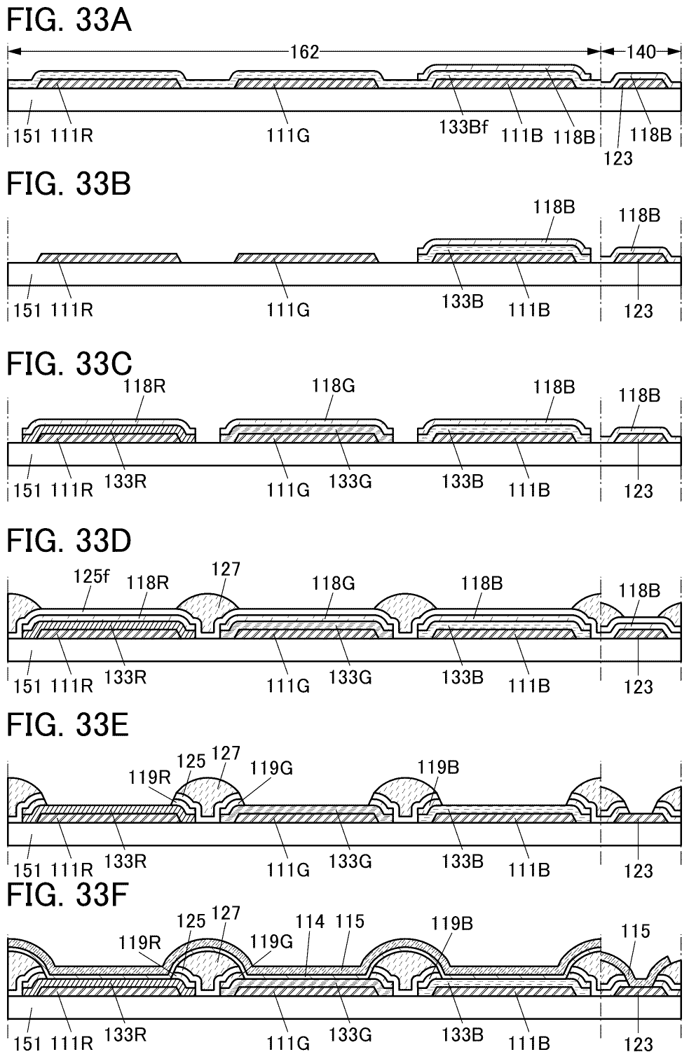

A method for manufacturing a display apparatus having an MML structure will be described below with reference to FIG. 33A to FIG. 33F. Here, steps of manufacturing light-emitting elements without using a fine metal mask will be described in detail. FIG. 33A to FIG. 33F illustrate cross-sectional views of three light-emitting elements included in the display portion 162 and the connection portion 140 in the manufacturing steps.

For manufacture of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

In the method described below for manufacturing the display apparatus, the island-shaped layer (the layer including the light-emitting layer) is formed not by using a fine metal mask but by forming a light-emitting layer on the entire surface and then processing the light-emitting layer by a photolithography method. Accordingly, a high-definition display apparatus or a display apparatus with a high aperture ratio, which has been difficult to achieve so far, can be provided. Moreover, light-emitting layers can be formed separately for each color, enabling the display apparatus to perform extremely clear display with high contrast and high display quality. Moreover, providing a sacrificial layer over the light-emitting layer can reduce damage to the light-emitting layer in the manufacturing process of the display apparatus, resulting in an increase in reliability of the light-emitting element.

For example, in the case where the display apparatus includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

First, the pixel electrode 111R, the pixel electrode 111G, and the pixel electrode 111B and the conductive layer 123 are formed over the substrate 151 provided with the transistor 205R, the transistor 205G, and the transistor 205B and the like (each of which is not illustrated) (FIG. 33A).

The conductive film to be the pixel electrodes can be formed by a sputtering method or a vacuum evaporation method, for example. A resist mask is formed over the conductive film by a photolithography process, and then the conductive film is processed, whereby the pixel electrode 111R, the pixel electrode 111G, and the pixel electrode 111B and the conductive layer 123 can be formed. The conductive film can be processed by one or both of a wet etching method and a dry etching method.

Next, a film 133Bf to be the layer 133B later is formed over the pixel electrode 111R, the pixel electrode 111G, and the pixel electrode 111B (FIG. 33A). The film 133Bf (to be the layer 133B later) includes a light-emitting layer that emits blue light.

In an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding step. In this case, the driving voltage of the light-emitting element of the color formed second or later might be high.

In view of this, in manufacture of the display apparatus of one embodiment of the present invention, it is preferable that an island-shaped EL layer of a light-emitting element that emits light with the shortest wavelength (e.g., the blue-light-emitting element) be formed first. For example, it is preferable that the island-shaped EL layers be formed in the order of blue, green, and red or in the order of blue, red, and green.

This enables the blue-light-emitting element to keep the favorable state of the interface between the pixel electrode and the EL layer and to be inhibited from having an increased driving voltage. In addition, the blue-light-emitting element can have a longer lifetime and higher reliability. Note that the red-light-emitting element and the green-light-emitting element have a smaller increase in driving voltage or the like than the blue-light-emitting element, resulting in a lower driving voltage and higher reliability of the whole display apparatus.

Note that the formation order of the island-shaped EL layers is not limited to the above; for example, the island-shaped EL layers may be formed in the order of red, green, and blue.

As illustrated in FIG. 33A, the film 133Bf is not formed over the conductive layer 123. The film 133Bf can be formed only in a desired region using an area mask, for example. Employing a film formation step using an area mask and a processing step using a resist mask enables a light-emitting element to be manufactured by a relatively easy process.

The heat resistance temperature of the compounds contained in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display apparatus can be increased. Therefore, the range of choices of the materials and the formation method of the display apparatus can be widened, thereby improving the yield and the reliability.

Examples of the heat resistance temperature include the glass transition point, the softening point, the melting point, the thermal decomposition temperature, and the 5% weight loss temperature, and the lowest one among the temperatures is preferable.

The film 133Bf can be formed by an evaporation method, specifically a vacuum evaporation method, for example. The film 133Bf may be formed by a transfer method, a printing method, an inkjet method, a coating method, or the like.

Next, a sacrificial layer 118B is formed over the film 133Bf and the conductive layer 123 (FIG. 33A). A resist mask is formed over a film to be the sacrificial layer 118B by a photolithography process, and then the film is processed, whereby the sacrificial layer 118B can be formed.

Providing the sacrificial layer 118B over the film 133Bf can reduce damage to the film 133Bf in the manufacturing process of the display apparatus, resulting in an increase in reliability of the light-emitting element.

The sacrificial layer 118B is preferably provided to cover the end portions of the pixel electrode 111B. Accordingly, the end portion of the layer 133B formed in a later step is positioned outward from the end portion of the pixel electrode 111B. The entire top surface of the pixel electrode 111B can be used as a light-emitting region, so that the aperture ratio of the pixel can be increased. The end portion of the layer 133B positioned outward from the end portion of the pixel electrode 111B is preferably not used as the light-emitting region because the end portion might be damaged at the time of forming the layer 133B. This can inhibit a variation in the characteristics of the light-emitting elements and can improve reliability.

When the layer 133B covers the top surface and the side surface of the pixel electrode 111B, the steps after the formation of the layer 133B can be performed in a state where the pixel electrode 111B is not exposed. When the end portion of the pixel electrode 111B is exposed, corrosion might occur in the etching step or the like. When corrosion of the pixel electrode 111B is inhibited, the yield and characteristics of the light-emitting element can be improved. The sacrificial layer 118B is preferably provided also at a position overlapping with the conductive layer 123. This can inhibit the conductive layer 123 from being damaged during the manufacturing process of the display apparatus.

As the sacrificial layer 118B, a film that is highly resistant to the process conditions for the film 133Bf, specifically, a film having high etching selectivity with respect to the film 133Bf is used.

The sacrificial layer 118B is formed at a temperature lower than the heat resistance temperature of each compound contained in the film 133Bf. The typical substrate temperature in the formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The heat resistance temperature of the compound contained in the film 133Bf is preferably high, in which case the film formation temperature of the sacrificial layer 118B can be high. For example, the substrate temperature in formation of the sacrificial layer 118B can be higher than or equal to 100° C., higher than or equal to 120° C., or higher than or equal to 140° C. In the case where an inorganic insulating film is used as the sacrificial layer 118B, the higher the film formation temperature of the inorganic insulating film is, the denser and the higher barrier property can be obtained. Therefore, forming the sacrificial layer 118B at such a temperature can further reduce damage to the film 133Bf and improve the reliability of the light-emitting element. Note that the same can be applied to the film formation temperature of another layer formed over the film 133Bf (e.g., an insulating film 125f).

The sacrificial layer 118B can be formed by a sputtering method, an ALD method (including thermal ALD method and a PEALD method), a CVD method, or a vacuum evaporation method, for example. Alternatively, the above-described wet film formation method may be used for the formation.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

In the case of employing a wet etching method, damage to the film 133Bf in processing of the sacrificial layer 118B can be reduced as compared to the case of employing a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a mixed solution containing two or more of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

As the sacrificial layer 118B, one or more kinds of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

The sacrificial layer 118B can be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

Note that the element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above.

For example, a semiconductor material such as silicon or germanium can be used as a material with a high affinity for the semiconductor manufacturing process. Alternatively, an oxide or a nitride of the semiconductor material can be used. Alternatively, a non-metallic material such as carbon or a compound thereof can be used. Alternatively, a metal, such as titanium, tantalum, tungsten, chromium, or aluminum, or an alloy containing one or more of them can be used. Alternatively, an oxide containing the above-described metal, such as titanium oxide or chromium oxide, or a nitride such as titanium nitride, chromium nitride, or tantalum nitride can be used.

As the sacrificial layer 118B, a variety of inorganic insulating films that can be used as the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. As the sacrificial layer 118B, an aluminum oxide film can be formed by an ALD method, for example. An ALD method is preferably used, in which case damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used as both the sacrificial layer 118B and the insulating layer 125. Here, for the sacrificial layer 118B and the insulating layer 125, the same film formation condition may be used or different film formation conditions may be used. For example, when the sacrificial layer 118B is formed under conditions similar to those of the insulating layer 125, the sacrificial layer 118B can be an insulating layer having a high barrier property against at least one of water and oxygen. Meanwhile, the sacrificial layer 118B is a layer a large part or the whole of which is to be removed in a later step, and thus is preferably easy to process. Therefore, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In film formation of a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer.

For example, a stacked-layer structure of an organic film (e.g., a PVA film) formed by an evaporation method or any of the above-described wet film formation methods and an inorganic film (e.g., a silicon nitride film) formed by a sputtering method can be employed for the sacrificial layer 118B.

Note that in the display apparatus of one embodiment of the present invention, part of the film to be the sacrificial layer remains as the sacrificial layer in some cases.

Then, the film 133Bf is processed using the sacrificial layer 118B as a hard mask, so that the layer 133B is formed (FIG. 33B).

Accordingly, as illustrated in FIG. 33B, the stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching may be used.

After that, steps similar to the formation step of the film 133Bf, the formation step of the sacrificial layer 118B, and the formation step of the layer 133B are repeated twice under the condition where at least light-emitting materials are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 33C). Specifically, the layer 133R and the layer 133G are formed to include a light-emitting layer that emits red light and a light-emitting layer that emits green light, respectively. The sacrificial layer 118R and the sacrificial layer 118G can be formed using a material that can be used for the sacrificial layer 118B, and the sacrificial layer 118R and the sacrificial layer 118G may be formed using the same material or different materials.

Note that the side surfaces of the layer 133B, the layer 133G, and the layer 133R are preferably perpendicular or substantially perpendicular to their formation surfaces. For example, the angle formed by the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between opposite end portions of two adjacent layers among the layer 133B, the layer 133G, and the layer 133R. When the distance between the island-shaped EL layers is shortened in this manner, a high-definition display apparatus with a high aperture ratio can be provided.

Next, the insulating film 125f to be the insulating layer 125 later is formed to cover the pixel electrodes, the layer 133B, the layer 133G, and the layer 133R, and the sacrificial layer 118B, the sacrificial layer 118G, and the sacrificial layer 118R, and then the insulating layer 127 is formed over the insulating film 125f (FIG. 33D).

As the insulating film 125f, an insulating film is preferably formed to have a thickness larger than or equal to 3 nm and larger than or equal to 200 nm, or larger than or equal to 5 nm and smaller than or equal to 150 nm, larger than or equal to 10 nm and smaller than or equal to 100 nm, or larger than or equal to 10 nm and smaller than or equal to 50 nm.

The insulating film 125f is preferably formed by an ALD method, for example. An ALD method is preferably used, in which case damage during deposition is reduced and a film with high coverage can be deposited. As the insulating film 125f, an aluminum oxide film is preferably formed by an ALD method, for example.

Alternatively, the insulating film 125f may be formed by a sputtering method, a CVD method, or a PECVD method that provides a higher deposition speed than an ALD method. In this case, a highly reliable display apparatus can be manufactured with high productivity.

For example, an insulating film to be the insulating layer 127 is preferably formed by the above-described wet film formation method (e.g., spin coating) using a photosensitive resin composite containing an acrylic resin. After the formation, heat treatment (also referred to as pre-baking) is preferably performed to eliminate a solvent contained in the insulating film. Next, part of the insulating film is exposed to light by irradiation with visible light or ultraviolet rays. Next, the region of the insulating film exposed to light is removed by development. After that, heat treatment (also referred to as post-baking) is performed. Accordingly, the insulating layer 127 illustrated in FIG. 33D can be formed. Note that the shape of the insulating layer 127 is not limited to the shape illustrated in FIG. 33D. For example, the top surface of the insulating layer 127 can include one or more of a convex surface, a concave surface, and a flat surface. The insulating layer 127 may cover the side surface of an end portion of at least one of the sacrificial layer 118B, the sacrificial layer 118G, and the sacrificial layer 118R.

Next, as illustrated in FIG. 33E, etching treatment is performed using the insulating layer 127 as a mask to remove parts of the insulating film 125f, the sacrificial layer 118B, the sacrificial layer 118G, and the sacrificial layer 118R. Consequently, openings are formed in the insulating film 125f, the sacrificial layer 118B, the sacrificial layer 118G, and the sacrificial layer 118R, and the top surfaces of the layer 133B, the layer 133G, the layer 133R, and the conductive layer 123 are exposed. Note that parts of the insulating film 125f, the sacrificial layer 118B, the sacrificial layer 118G, and the sacrificial layer 118R remain (the insulating layer 125, a sacrificial layer 119B, a sacrificial layer 119G, and a sacrificial layer 119R) in a position overlapping with the insulating layer 127.

The etching treatment can be performed by dry etching or wet etching. Note that the insulating film 125f is preferably formed using a material similar to that for the sacrificial layer 118B, the sacrificial layer 118G, and the sacrificial layer 118R, in which case etching treatment can be performed collectively.

As described above, by providing the insulating layer 127, the insulating layer 125, the sacrificial layer 119B, the sacrificial layer 119G, and the sacrificial layer 119R, connection defects due to a disconnected portion and an increase in electric resistance due to a locally thinned portion can be inhibited from occurring in the common layer 114 and the common electrode 115, which are formed later, between the light-emitting elements. Thus, the display apparatus of one embodiment of the present invention can have improved display quality.

Next, the common layer 114 and the common electrode 115 are formed in this order over the insulating layer 127, the layer 133B, the layer 133G, and the layer 133R (FIG. 33F).

The common layer 114 can be formed by a method such as an evaporation method (including a vacuum evaporation method), a transfer method, a printing method, an inkjet method, or a coating method.

The common electrode 115 can be formed by a sputtering method or a vacuum evaporation method, for example. Alternatively, a film formed by an evaporation method and a film formed by a sputtering method may be stacked.

As described above, in the method for manufacturing the display apparatus of one embodiment of the present invention, the island-shaped layer 133B, the island-shaped layer 133G, and the island-shaped layer 133R are formed not by using a fine metal mask but by forming a film on the entire surface and processing the film; thus, the island-shaped layers can be formed to have a uniform thickness. Consequently, a high-definition display apparatus or a display apparatus with a high aperture ratio can be obtained. Furthermore, even when the definition or the aperture ratio is high and the distance between subpixels is extremely short, contact between the layer 133B, the layer 133G, and the layer 133R can be inhibited in adjacent subpixels. As a result, generation of a leakage current between the subpixels can be inhibited. This can prevent crosstalk due to unintended light emission, so that a display apparatus with extremely high contrast can be obtained.

The insulating layer 127 having a tapered end portion and being provided between adjacent island-shaped EL layers can prevent step disconnection and a locally thinned portion to be formed in the common electrode 115 at the time of forming the common electrode 115. This can inhibit the common layer 114 and the common electrode 115 from having connection defects due to the disconnected portion and an increased electric resistance due to the locally thinned portion. Hence, the display apparatus of one embodiment of the present invention achieves both high definition and high display quality.

This embodiment can be combined with any of the other embodiments or an example as appropriate.

### Embodiment 4

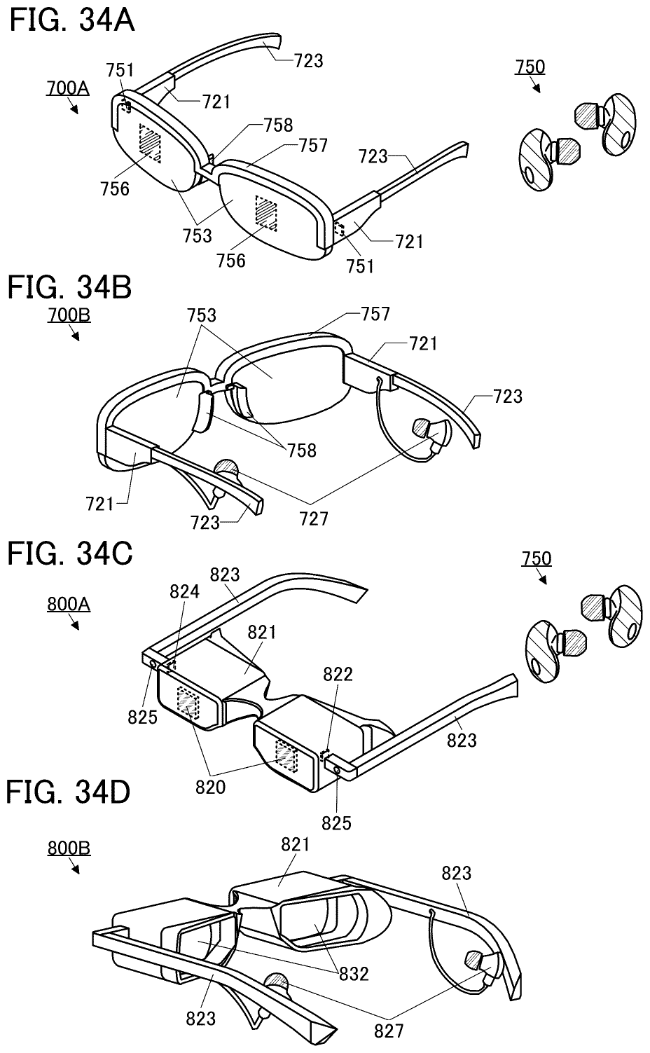

In this embodiment, electronic devices of one embodiment of the present invention will be described using FIG. 34A to FIG. 36G.

Electronic devices in this embodiment are each provided with the display apparatus of one embodiment of the present invention in a display portion. The display apparatus of one embodiment of the present invention can be easily increased in definition and resolution. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have a high definition, and thus can be suitably used for an electronic device having a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The resolution of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. The pixel density (definition) of the display apparatus of one embodiment of the present invention is preferably 100 ppi or higher, further preferably 300 ppi or higher, still further preferably 500 ppi or higher, yet still further preferably 1000 ppi or higher, yet still further preferably 2000 ppi or higher, yet still further preferably 3000 ppi or higher, yet still further preferably 5000 ppi or higher, yet still further preferably 7000 ppi or higher. With the use of such a display apparatus with one or both of high resolution and high definition, an electronic device for portable use or home use can have higher realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head are described using FIG. 34A to FIG. 34D. These wearable devices have at least one of a function of displaying AR content, a function of displaying VR content, a function of displaying SR content, and a function of displaying MR content. The electronic device having a function of displaying contents of at least one of AR, VR, SR, MR, and the like enables the user to feel a higher level of immersion.

An electronic device 700A illustrated in FIG. 34A and an electronic device 700B illustrated in FIG. 34B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic devices are capable of performing ultrahigh-definition display.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are each provided with a battery so that they can be charged wirelessly and/or by wire.

A touch sensor module may be provided in the housing 721. The touch sensor module has a function of detecting a touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 34C and an electronic device 800B illustrated in FIG. 34D each include a pair of display portions 820, a housing 821, a communication portion 822, a pair of wearing portions 823, a control portion 824, a pair of imaging portions 825, and a pair of lenses 832.

The display apparatus of one embodiment of the present invention can be used in the display portions 820. Thus, the electronic devices are capable of performing ultrahigh-definition display. This enables a user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be worn on the user's head with the wearing portions 823. FIG. 34C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. In other words, the image capturing portion 825 is one embodiment of the sensing portion. As the sensing portion, an image sensor or a distance image sensor such as LIDAR (Light Detection And Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as a bone-conduction earphone. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 34A has a function of transmitting information to the earphones 750 with the wireless communication function. As another example, the electronic device 800A illustrated in FIG. 34C has a function of transmitting information to the earphones 750 with the wireless communication function.

The electronic device may include an earphone portion. The electronic device 700B illustrated in FIG. 34B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B illustrated in FIG. 34D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

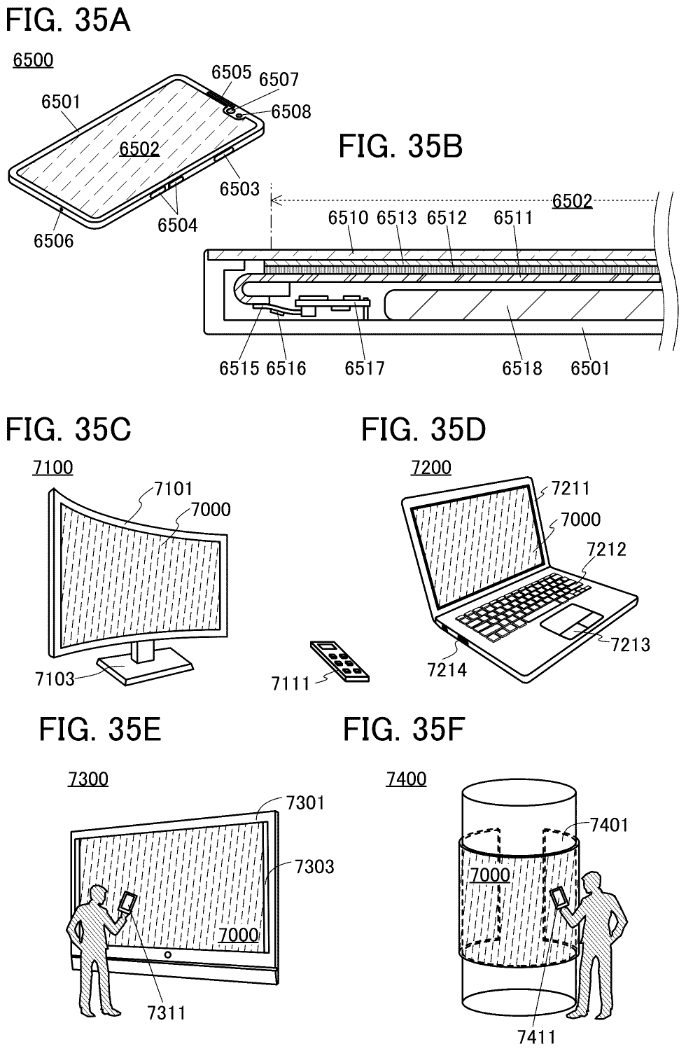

Next, FIG. 35A illustrates a perspective view of an electronic device 6500.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502.

FIG. 35B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display apparatus of one embodiment of the present invention can be used for the display panel 6511. Thus, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the display portion 6502, whereby an electronic device with a narrow bezel can be obtained. FIG. 35C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operations of the television device 7100 illustrated in FIG. 35C can be performed with an operation switch provided in the housing 7101 and a separate remote controller 7111.

Alternatively, the display portion 7000 may include a touch sensor, and the television device 7100 may be operated by a touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 35D illustrates an example of a laptop personal computer. The notebook personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used for the display portion 7000.

FIG. 35E and FIG. 35F illustrate examples of digital signage.

Digital signage 7300 illustrated in FIG. 35E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 35F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 35E and FIG. 35F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 35E and FIG. 35F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

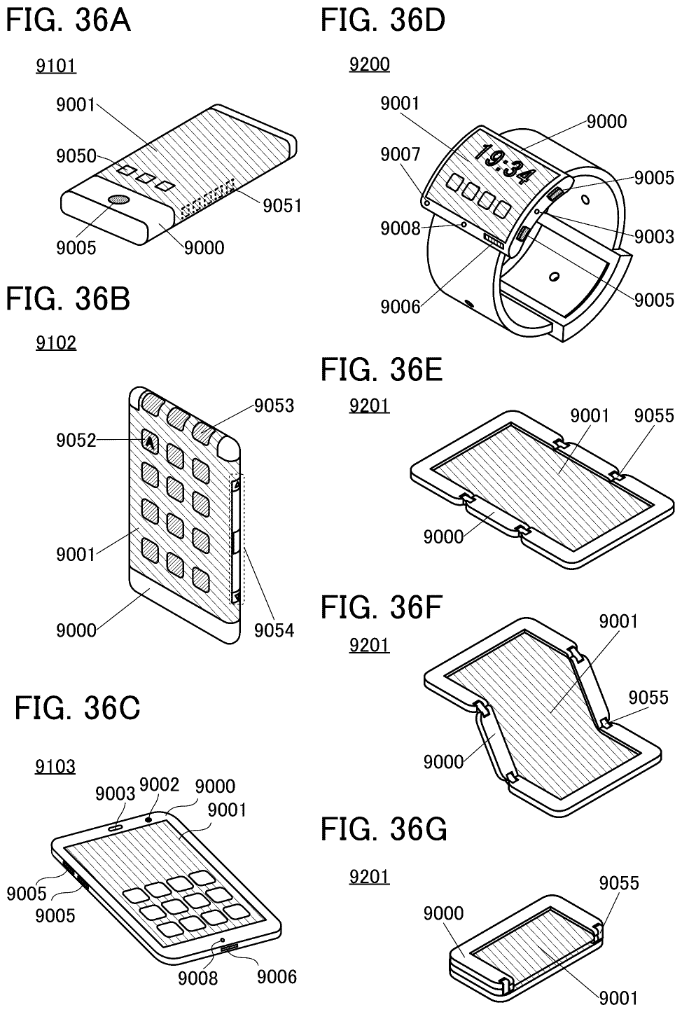

Electronic devices illustrated in FIG. 36A to FIG. 36G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display apparatus of one embodiment of the present invention can be used for the display portion 9001 in FIG. 36A to FIG. 36G.

The electronic devices illustrated in FIG. 36A to FIG. 36G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may each be provided with a camera or the like and have a function of capturing a still image or a moving image, a function of storing the captured image in a recording medium (an external recording medium or a recording medium incorporated in the camera), a function of displaying the captured image on the display portion, and the like.

The electronic devices illustrated in FIG. 36A to FIG. 36G are described in detail below.

FIG. 36A is a perspective view illustrating a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 36A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 36B is a perspective view illustrating a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 36C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 36D is a perspective view illustrating a wristwatch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 36E to FIG. 36G are perspective views illustrating a foldable portable information terminal 9201. In addition, FIG. 36E is a perspective view of an opened state of the portable information terminal 9201, FIG. 36G is a perspective view of a folded state thereof, and FIG. 36F is a perspective view of a state in the middle of change from one of FIG. 36E and FIG. 36G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments or an example as appropriate.

### Example

In this example, a sample which is the semiconductor device of one embodiment of the present invention was fabricated. The description of the semiconductor device 10 in FIG. 1A to FIG. 1C can be referred to for the structure of the sample. For the fabrication method of the sample, the description of the manufacturing method of the semiconductor device 10 illustrated in FIG. 14A to FIG. 18B can be referred to.

### <Fabrication of Sample>

First, a 300-nm-thick copper film was formed over the substrate 102 by a sputtering method, and then a 100-nm-thick In—Sn—Si oxide (ITSO) film was formed thereover by a sputtering method. By processing these films, the conductive layer 112a and the conductive layer 202a each having a stacked-layer structure of copper and ITSO were obtained. Note that a glass substrate was used as the substrate 102.

Then, a 170-nm-thick silicon nitride film was formed over the substrate 102, the conductive layer 112a, and the conductive layer 202a by a PECVD method to obtain the insulating film 110af. Note that the insulating film 110af had a stacked-layer structure of a 70-nm-thick silicon nitride film (a first silicon nitride film) and a 100-nm-thick silicon nitride film (a second silicon nitride film) over the first silicon nitride film. The first silicon nitride film was formed in a deposition gas where NH₃ was mixed, and the second silicon nitride film was formed in a deposition gas where NH₃ was not mixed.

Then, a 500-nm-thick silicon oxynitride film was formed over the insulating film 110af by a PECVD method to obtain the insulating film 110bf.

Next, treatment for supplying oxygen to the insulating film 110bf was performed.

First, a 20-nm-thick first metal oxide layer was formed over the insulating film 110bf by a sputtering method using a sputtering target with In:Ga:Zn=1:1:1 in an atomic ratio of metal elements with room temperature as a substrate temperature in an oxygen atmosphere of 100%.

Next, a treatment where oxygen is supplied from the first metal oxide layer to the insulating film 110bf by heat treatment was performed. The heat treatment was performed at 250° C. in a dry air atmosphere for one hour. An oven apparatus was used for the heat treatment.

Then, the first metal oxide layer was removed.

Next, in an oxygen atmosphere of 100% and at a substrate temperature of 130° C., a 5-nm-thick second metal oxide layer was formed over the insulating film 110bf by a sputtering method using a sputtering target with metal elements in an atomic ratio of In:Ga:Zn=4:2:3.

Then, oxygen plasma treatment was performed on the insulating film 110bf through the second metal oxide layer for 300 seconds with a plasma ashing apparatus.

Then, the second metal oxide layer was removed.

Note that the first metal oxide layer and the second metal oxide layer in this example correspond to the metal oxide layer 180 illustrated in FIG. 14C.

Through the above series of steps, the treatment for supplying oxygen to the insulating film 110bf was performed.

Then, a 200-nm-thick silicon nitride film was formed over the insulating film 110bf by a PECVD method to obtain the insulating film 110cf. Note that the insulating film 110cf had a stacked-layer structure of a 50-nm-thick silicon nitride film (a third silicon nitride film) and a 150-nm-thick silicon nitride film (a fourth silicon nitride film) over the third silicon nitride film. The third silicon nitride film was formed in a state where NH₃ was not mixed in a deposition gas, and the fourth silicon nitride film was formed in a state where NH₃ was mixed in a deposition gas.

Next, over the insulating film 110cf, a 60-nm-thick silicon nitride film and a 50-nm-thick silicon oxynitride film were formed and stacked by a PECVD method to obtain the insulating film 120f.

Then, the insulating film 120f was processed to obtain the insulating layer 120.

Next, a 100-nm-thick ITSO film was formed over the insulating layer 120 and the insulating film 110cf by a sputtering method to obtain the conductive film 112f.

Then, the conductive film 112f was processed to obtain the conductive layer 112B.

Then, the conductive layer 112B was processed to form the opening 143, and the conductive layer 112b was obtained. The opening 143 was formed by a wet etching method.

Next, the insulating film 110f (the insulating film 110cf, the insulating film 110bf, and the insulating film 110af) was processed to form the opening 141, whereby the insulating layer 110 (the insulating layer 110c, the insulating layer 110b, and the insulating layer 110a) was obtained. The opening 141 was formed by a dry etching method.

Note that the planar shapes of the opening 143 and the opening 141 were circle.

Next, the 10-nm-thick the metal oxide film 105f was formed over the conductive layer 112a, the insulating layer 110, the conductive layer 112b, and the insulating layer 120 to cover the opening 143 and the opening 141. The metal oxide film 105f was formed by a sputtering method using a sputtering target with metal elements in an atomic ratio of In:Zn=4:1. Note that in the formation, the substrate temperature was room temperature and the oxygen flow rate ratio was 10%.

Then, the metal oxide film 105f was processed to obtain the semiconductor layer 105.

Next, the 10-nm-thick the metal oxide film 108f was formed over the semiconductor layer 105, the conductive layer 112b, the insulating layer 120, and the insulating layer 110. The metal oxide film 108f was formed by a sputtering method using a sputtering target with metal elements in an atomic ratio of In:Ga:Zn=1:1:1. Note that in the formation, the substrate temperature was room temperature and the oxygen flow rate ratio was 20%.

Next, heat treatment was performed at 340° C. in a dry air atmosphere for two hours. An oven apparatus was used for the heat treatment.

Then, the metal oxide film 108f was processed to obtain the semiconductor layer 108 and the semiconductor layer 208.

Then, a 50-nm-thick silicon oxynitride film was formed over the semiconductor layer 108, the conductive layer 112b, the semiconductor layer 208, the insulating layer 120, and the insulating layer 110 by a PECVD method to obtain the insulating film 106f.

Next, heat treatment was performed at 340° C. in a dry air atmosphere for one hour. An oven apparatus was used for the heat treatment.

Then, the insulating film 106f was processed and the opening 147a and the opening 147b were formed to obtain the insulating layer 106. The opening 147a and the opening 147b were formed by a dry etching method.

Then, over the insulating layer 106 and the semiconductor layer 208, a 50-nm-thick titanium film, a 200-nm-thick aluminum film, and a 50-nm-thick titanium film were formed and stacked by a sputtering method, so that the conductive film 104f was formed.

Then, the conductive film 104f was processed to obtain the conductive layer 104, the conductive layer 204, the conductive layer 212a, and the conductive layer 212b. A dry etching method was used for the processing.

Next, treatment for supplying the impurity 190 to the semiconductor layer 208 was performed using the conductive layer 204 as a mask. As the impurity 190, boron was used and supplied to the semiconductor layer 208 by a plasma ion doping method. Note that the acceleration voltage was 15 kV and the dosage was 1×10¹⁵ ions/cm² in plasma ion doping.

In this manner, the region 208D and the region 208L were formed in the semiconductor layer 208.

Through the above process, the transistor 100 and the transistor 200 were formed.

Next, as a protective layer, a 300-nm-thick silicon nitride oxide film was formed over the transistor 100 and the transistor 200 by a PECVD method.

Then, as a planarization layer, a polyimide resin was formed over the protective layer to have a thickness of 1.5 μm.

Next, heat treatment was performed at 250° C. in a nitrogen atmosphere for one hour. An oven apparatus was used for the heat treatment.

Next, a measurement PAD for measurement of electrical characteristics of the transistor 100 and the transistor 200 described later was formed over the planarization layer.

Next, heat treatment was performed at 250° C. in a nitrogen atmosphere for one hour. An oven apparatus was used for the heat treatment.

Through the above steps, the sample which is the semiconductor device of one embodiment of the present invention was obtained.

### <Id-Vg Characteristics>

Next, drain current (Id)-gate voltage (Vg) characteristics of the transistor 100 and the transistor 200 in the sample fabricated above were measured.

For measuring the Id-Vg characteristics of the transistors, a voltage applied to the gate electrode (hereinafter also referred to as a gate voltage (Vg)) was applied from −10 V to +10 V in increments of 0.1 V. A voltage applied to the source electrode (hereinafter also referred to as a source voltage (Vs)) was 0 V (common), and a voltage applied to the drain electrode (hereinafter also referred to as a drain voltage (Vd)) was 0.1 V and 5.1 V.

The transistor 100, in which the width (diameter) of the opening 143 in FIG. 1A is 2.0 μm (with a channel width of 6.3 μm and a channel length of 0.5 μm), was used for the measurement. The transistor 200 with a channel length of 3.0 μm and a channel width of 3.0 μm was used for the measurement. The numbers of transistors 100 and transistors 100 subjected to the measurement were each 10.

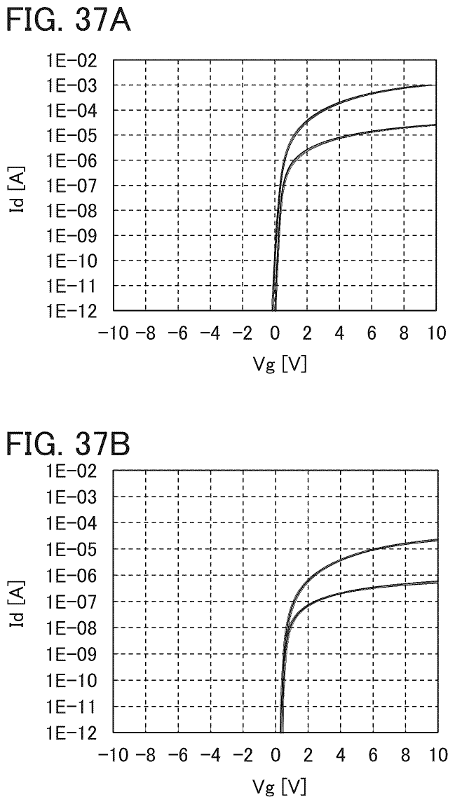

FIG. 37A shows Id-Vg characteristics of the transistor 100, and FIG. 37B show Id-Vg characteristics of the transistor 200. In FIG. 37A and FIG. 37B, the horizontal axis represents the gate voltage (Vg) and the vertical axis represents the drain current (Id). FIG. 37A and FIG. 37B each show superimposed Id-Vg characteristics of the 10 transistors.

FIG. 37A and FIG. 37B reveal that the transistor 100 and the transistor 200 each have switching characteristics with a high on/off ratio. It is also confirmed that the on-state current of the transistor 100 is higher than that of the transistor 200.

At least part of the structure, the method, and the like described in this example can be implemented in appropriate combination with any of the embodiments described in this specification.

### REFERENCE NUMERALS

10A: semiconductor device, 10B: semiconductor device, 10C: semiconductor device, 10D: semiconductor device, 10E: semiconductor device, 10F: semiconductor device, 10G: semiconductor device, 10H: semiconductor device, 101: semiconductor device, 10: semiconductor device, 50A: display apparatus, 50B: display apparatus, 50C: display apparatus, 50D: display apparatus, 50E: display apparatus, 50F: display apparatus, 50G: display apparatus, 51A: pixel circuit, 51: pixel circuit, 52A: transistor, 52B: transistor, 52C: transistor, 53: capacitor, 61: light-emitting device, 100A: transistor, 100B: transistor, 100C: transistor, 100: transistor, 102: substrate, 103: conductive layer, 104f: conductive film, 104: conductive layer, 105f: metal oxide film, 105: semiconductor layer, 106f: insulating film, 106: insulating layer, 108f: metal oxide film, 108L: region, 108: semiconductor layer, 110a: insulating layer, 110af: insulating film, 110b: insulating layer, 110bf: insulating film, 110c: insulating layer, 110cf: insulating film, 110f: insulating film, 110: insulating layer, 111B: pixel electrode, 111G: pixel electrode, 111R: pixel electrode, 111S: pixel electrode, 111: pixel electrode, 112a: conductive layer, 112af: conductive film, 112B: conductive layer, 112b: conductive layer, 112f: conductive film, 112s: conductive layer, 113B: EL layer, 113G: EL layer, 113R: EL layer, 113S: functional layer, 113: EL layer, 114: common layer, 115: common electrode, 117: light-blocking layer, 118B: sacrificial layer, 118G: sacrificial layer, 118R: sacrificial layer, 119B: sacrificial layer, 119G: sacrificial layer, 119R: sacrificial layer, 120f: insulating film, 120: insulating layer, 123: conductive layer, 124B: conductive layer, 124G: conductive layer, 124R: conductive layer, 125f: insulating film, 125: insulating layer, 126B: conductive layer, 126G: conductive layer, 126R: conductive layer, 127: insulating layer, 128: layer, 130B: light-emitting element, 130G: light-emitting element, 130R: light-emitting element, 130S: light-receiving element, 131: protective layer, 132B: coloring layer, 132G: coloring layer, 132R: coloring layer, 133Bf: film, 133B: layer, 133G: layer, 133R: layer, 133: layer, 135: opening, 139: opening, 140: connection portion, 141: opening, 142: adhesive layer, 143: opening, 147a: opening, 147b: opening, 148: opening, 149: opening, 151: substrate, 152: substrate, 153: insulating layer, 162: display portion, 164: peripheral circuit portion, 165: wiring, 166: conductive layer, 168: connection portion, 172: FPC, 173: IC, 180: metal oxide layer, 190: impurity, 195: insulating layer, 200A: transistor, 200B: transistor, 200C: transistor, 200D: transistor, 200E: transistor, 200F: transistor, 200G: transistor, 200H: transistor, 200: transistor, 202a: conductive layer, 202b: conductive layer, 202s: conductive layer, 202t: conductive layer, 203: conductive layer, 204B: conductive layer, 204: conductive layer, 205B: transistor, 205G: transistor, 205R: transistor, 205S: transistor, 207: insulating layer, 208D: region, 208L: region, 208: semiconductor layer, 212a: conductive layer, 212b: conductive layer, 215: semiconductor layer, 230B: pixel, 230G: pixel, 230R: pixel, 230: pixel, 231: first driver circuit portion, 232: second driver circuit portion, 235: insulating layer, 236: wiring, 237: insulating layer, 238: wiring, 241: opening, 242: connection layer, 243: opening, 248: opening, 352: finger, 353: layer, 355: circuit layer, 357: layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a first transistor and a second transistor,
wherein the first transistor comprises a first conductive layer, a second conductive layer, a third conductive layer, a first insulating layer, a first semiconductor layer, and a second semiconductor layer,
wherein the second conductive layer is provided over the first conductive layer and comprises an opening in a region overlapping with the first conductive layer,
wherein the first semiconductor layer is provided in contact with a top surface of the first conductive layer and a top surface and a side surface of the second conductive layer to cover the opening,
wherein the second semiconductor layer is provided in contact with a top surface of the first semiconductor layer,
wherein a first region of the first insulating layer is provided in contact with a top surface of the second semiconductor layer,
wherein the third conductive layer is provided in the opening to overlap with the first semiconductor layer and the second semiconductor layer with the first region therebetween,
wherein the second transistor comprises the first insulating layer, a third semiconductor layer, a fourth conductive layer, a fifth conductive layer, and a sixth conductive layer,
wherein the fourth conductive layer is provided in contact with a top surface of a first part of the third semiconductor layer,
wherein the fifth conductive layer is provided in contact with a top surface of a second part of the third semiconductor layer,
wherein, a second region of the first insulating layer is provided in contact with a top surface of a third part of the third semiconductor layer between the fourth conductive layer and the fifth conductive layer,
wherein the sixth conductive layer is provided in contact with a top surface of the second region,
wherein the first semiconductor layer and the second semiconductor layer comprise different materials, and
wherein the second semiconductor layer and the third semiconductor layer comprise a same material.

2. A semiconductor device comprising:
a first transistor and a second transistor,
wherein the first transistor comprises a first conductive layer, a second conductive layer, a third conductive layer, a first insulating layer, a first semiconductor layer, and a second semiconductor layer,
wherein the second transistor comprises a fourth conductive layer, a fifth conductive layer, a sixth conductive layer, the first insulating layer, and a third semiconductor layer,
wherein the second conductive layer is provided over the first conductive layer and comprises a first opening in a region overlapping with the first conductive layer,
wherein the first semiconductor layer is provided in contact with a top surface of the first conductive layer and a top surface and a side surface of the second conductive layer to cover the first opening,
wherein the second semiconductor layer is provided in contact with a top surface of the first semiconductor layer,
wherein a first region of the first insulating layer is provided in contact with a top surface of the second semiconductor layer,
wherein the third conductive layer is provided in the first opening to overlap with the first semiconductor layer and the second semiconductor layer with the first region therebetween,
wherein the fifth conductive layer is provided over the fourth conductive layer and comprises a second opening in a region overlapping with the fourth conductive layer,
wherein the third semiconductor layer is provided in contact with a top surface of the fourth conductive layer and a top surface and a side surface of the fifth conductive layer to cover the second opening,
wherein a second region of the first insulating layer is provided in contact with a top surface of the third semiconductor layer,
wherein the sixth conductive layer is provided in the second opening to overlap with the third semiconductor layer with the second region therebetween,
wherein the first semiconductor layer and the second semiconductor layer comprise different materials, and
wherein the second semiconductor layer and the third semiconductor layer comprise a same material.

3. The semiconductor device according to claim 1,
wherein the first semiconductor layer, the second semiconductor layer, and the third semiconductor layer each comprise a metal oxide.

4. The semiconductor device according to claim 1,
wherein a second insulating layer is provided over the first conductive layer,
wherein the second insulating layer comprises a first layer, a second layer over the first layer, and a third layer over the second layer,
wherein the first layer comprises a region having a higher film density than the second layer, and
wherein the third layer comprises a region having a higher film density than the second layer.

5. The semiconductor device according to claim 1,
wherein a second insulating layer is provided over the first conductive layer,
wherein the second insulating layer comprises a first layer, a second layer over the first layer, and a third layer over the second layer,
wherein the first layer comprises a region having a higher nitrogen content than the second layer, and
wherein the third layer comprises a region having a higher nitrogen content than the second layer.

6. The semiconductor device according to claim 1,
wherein the second transistor comprises a third insulating layer, and
wherein the third semiconductor layer is provided over the third insulating layer.

7. The semiconductor device according to claim 1,
wherein the second transistor comprises a seventh conductive layer and a second insulating layer over the seventh conductive layer, and
wherein the seventh conductive layer is provided to overlap with the sixth conductive layer with the second insulating layer and the third semiconductor layer therebetween.

8. The semiconductor device according to claim 1,
wherein the third semiconductor layer comprises a fourth part interposed between the second region of the first insulating layer and the fourth conductive layer and a fifth part interposed between the second region of the first insulating layer and the fifth conductive layer in a plan view, and
wherein the fourth part and the fifth part have lower resistance than a region of the third semiconductor layer overlapping with the sixth conductive layer.

9. The semiconductor device according to claim 2,
wherein a second insulating layer is provided over the first conductive layer and the fourth conductive layer,
wherein the second insulating layer comprises a first layer, a second layer over the first layer, and a third layer over the second layer,
wherein the first layer comprises a region having a higher film density than the second layer, and
wherein the third layer comprises a region having a higher film density than the second layer.

10. The semiconductor device according to claim 2,
wherein a second insulating layer is provided over the first conductive layer and the fourth conductive layer,
wherein the second insulating layer comprises a first layer, a second layer over the first layer, and a third layer over the second layer,
wherein the first layer comprises a region having a higher nitrogen content than the second layer, and
wherein the third layer comprises a region having a higher nitrogen content than the second layer.

11. A method for manufacturing a semiconductor device comprising:
forming a first conductive film;
processing the first conductive film to form a first conductive layer and a second conductive layer;
forming a first insulating film over the first conductive layer and the second conductive layer;
forming a second insulating film over the first insulating film;
processing the second insulating film to form a first insulating layer overlapping with the second conductive layer;
forming a second conductive film over the first insulating layer and the first insulating film;
processing the first insulating film and the second conductive film to form a second insulating layer and a third conductive layer each comprising an opening in a region overlapping with the first conductive layer;
forming a first metal oxide film over the first conductive layer, the second insulating layer, the third conductive layer, and the first insulating layer to cover the opening;
processing the first metal oxide film to form a first semiconductor layer in contact with a top surface of the first conductive layer, a side surface of the second insulating layer, and a top surface and a side surface of the third conductive layer;
forming a second metal oxide film over the first semiconductor layer, the third conductive layer, the first insulating layer, and the second insulating layer;
processing the second metal oxide film to form a second semiconductor layer overlapping with the first semiconductor layer and a third semiconductor layer overlapping with the second conductive layer and the first insulating layer;
forming a third insulating film over the first semiconductor layer, the second semiconductor layer, the third conductive layer, the third semiconductor layer, the first insulating layer, and the second insulating layer;
processing the third insulating film to form a third insulating layer comprising a region overlapping with the first conductive layer, the first semiconductor layer, the second semiconductor layer, and the third conductive layer, and a fourth insulating layer comprising a region overlapping with the second conductive layer and the third semiconductor layer;
forming a third conductive film over the third insulating layer and the fourth insulating layer;
processing the third conductive film to form a fourth conductive layer overlapping with the first semiconductor layer and the second semiconductor layer, a fifth conductive layer overlapping with the second conductive layer and the third semiconductor layer, and a sixth conductive layer and a seventh conductive layer that are in contact with a top surface of the third semiconductor layer and between which the fifth conductive layer is interposed in a plan view; and
supplying an impurity to the third semiconductor layer with the use of the fifth conductive layer as a mask.

12. The method for manufacturing the semiconductor device according to claim 11,
wherein the impurity comprises one or more selected from boron, phosphorus, aluminum, magnesium, and silicon.

13. (canceled)

14. The semiconductor device according to claim 2,
wherein the first semiconductor layer, the second semiconductor layer, and the third semiconductor layer each comprise a metal oxide.
